(19) United States
(12) Patent Application Publication
(10) Pub. No.: US 2022/0262832 A1
(43) Pub. Date: Aug. 18, 2022

(54) SEMICONDUCTOR DEVICE AND IMAGING DEVICE

(71) Applicant: SONY SEMICONDUCTOR SOLUTIONS CORPORATION, Kanagawa (JP)

(72) Inventor: Shintaro OKAMOTO, Kanagawa (JP)

(73) Assignee: SONY SEMICONDUCTOR SOLUTIONS CORPORATION, Kanagawa (JP)

(21) Appl. No.: 17/618,569

(22) PCT Filed: Jun. 18, 2020
(86) PCT No.: PCT/JP2020/024008

§ 371 Date: Dec. 13, 2021

(30) Foreign Application Priority Data
Jun. 26, 2019 (JP) 2019-119123

(51) Int. Cl. H01L 27/146; H01L 25/065

(52) U.S. Cl. CPC H01L 27/14605; H01L 27/14612; H01L 25/0657; H01L 27/14636; H01L 27/14634

(57) ABSTRACT

A semiconductor device according to the present disclosure includes a plurality of stacked substrates, a semiconductor element that is formed in at least one of a plurality of the substrates, and a protection element that is formed to have PN junction in at least one of a plurality of the substrates and protects the semiconductor element.

### FIELD

The present disclosure relates to a semiconductor device and an imaging device.

### BACKGROUND

There is a three-dimensional packaging technology for stacking a plurality of semiconductor substrates. For example, in an imaging device, a configuration in which a first semiconductor substrate on which a pixel region is formed and a second semiconductor substrate on which a logic circuit is formed are stacked is known (refer to, for example, Patent Literature 1).

### CITATION LIST

### Patent Literature

Patent Literature 1: JP 2010-245506 A

### SUMMARY

### Technical Problem

In the imaging device described above, a sufficient space for arranging a pixel transistor cannot be secured. Therefore, for example, it is conceivable to further divide and stack a substrate on which a photoelectric conversion element is formed and a substrate on which the pixel transistor is formed.

However, in such a configuration, for example, when the number of the photoelectric conversion elements is different from the number of the pixel transistors, an area required for each of the substrates may be different. In a case where a plurality of the substrates are stacked, it is necessary to make the area of each of the substrates the same. Therefore, there is a problem that a chip area of the device increases depending on the substrate having a large required area.

Accordingly, the present disclosure proposes a semiconductor device and an imaging device which are capable of suppressing an increase in a chip area.

### Solution to Problem

A semiconductor device according to the present disclosure includes a plurality of stacked substrates, a semiconductor element that is formed in at least one of a plurality of the substrates, and a protection element that is formed to have PN junction in at least one of a plurality of the substrates and protects the semiconductor element.

### BRIEF DESCRIPTION OF DRAWINGS

FIG. 1 is a block diagram illustrating an example of a functional configuration of an imaging device according to an embodiment of the present disclosure.

FIG. 2 is a schematic plan view illustrating a schematic configuration of the imaging device illustrated in FIG. 1.

FIG. 3 is a schematic view illustrating a cross-sectional configuration taken along line III-III′ illustrated in FIG. 2.

FIG. 4 is an equivalent circuit diagram of a pixel sharing unit illustrated in FIG. 1.

FIG. 5 is a diagram illustrating an example of a connection state of a plurality of pixel sharing units and a plurality of vertical signal lines.

FIG. 6 is a schematic cross-sectional view illustrating an example of a specific configuration of an imaging device illustrated in FIG. 3.

FIG. 7A is a schematic view illustrating an example of a plane configuration of a main portion of a first substrate illustrated in FIG. 6.

FIG. 7B is a schematic view illustrating a plane configuration of a pad portion together with the main portion of the first substrate illustrated in FIG. 7A.

FIG. 8 is a schematic view illustrating an example of a plane configuration of a second substrate (semiconductor layer) illustrated in FIG. 6.

FIG. 9 is a schematic view illustrating an example of a plane configuration of a main portion of a pixel circuit and a first substrate together with a first wiring layer illustrated in FIG. 6.

FIG. 10 is a schematic view illustrating an example of a plane configuration of a first wiring layer and a second wiring layer which are illustrated in FIG. 6.

FIG. 11 is a schematic view illustrating an example of a plane configuration of a second wiring layer and a third wiring layer which are illustrated in FIG. 6.

FIG. 12 is a schematic view illustrating an example of a plane configuration of a third wiring layer and a fourth wiring layer which are illustrated in FIG. 6.

FIG. 13 is a schematic view for describing a path of an input signal to an imaging device illustrated in FIG. 3.

FIG. 14 is a schematic view for describing a signal path of a pixel signal of an imaging device illustrated in FIG. 3.

FIG. 15 is a schematic view illustrating a modified example of the plane configuration of the second substrate (semiconductor layer) illustrated in FIG. 8.

FIG. 16 is a schematic view illustrating a plane configuration of a first wiring layer and a main portion of a first substrate together with a pixel circuit illustrated in FIG. 15.

FIG. 17 is a schematic view illustrating an example of a plane configuration of a second wiring layer together with the first wiring layer illustrated in FIG. 16.

FIG. 18 is a schematic view illustrating an example of a plane configuration of a third wiring layer together with the second wiring layer illustrated in FIG. 17.

FIG. 19 is a schematic view illustrating an example of a plane configuration of a fourth wiring layer together with the third wiring layer illustrated in FIG. 18.

FIG. 20 is a schematic view illustrating a modified example of the plane configuration of the first substrate illustrated in FIG. 7A.

FIG. 21 is a schematic view illustrating an example of a plane configuration of a second substrate (semiconductor layer) stacked on the first substrate illustrated in FIG. 20.

FIG. 22 is a schematic view illustrating an example of a plane configuration of a first wiring layer together with a pixel circuit illustrated in FIG. 21.

FIG. 23 is a schematic view illustrating an example of a plane configuration of a second wiring layer together with the first wiring layer illustrated in FIG. 22.

FIG. 24 is a schematic view illustrating an example of a plane configuration of a third wiring layer together with the second wiring layer illustrated in FIG. 23.

FIG. 25 is a schematic view illustrating an example of a plane configuration of a fourth wiring layer together with the third wiring layer illustrated in FIG. 24.

FIG. 26 is a schematic view illustrating another example of the plane configuration of the first substrate illustrated in FIG. 20.

FIG. 27 is a schematic view illustrating an example of a plane configuration of a second substrate (semiconductor layer) stacked on the first substrate illustrated in FIG. 26.

FIG. 28 is a schematic view illustrating an example of a plane configuration of a first wiring layer together with a pixel circuit illustrated in FIG. 27.

FIG. 29 is a schematic view illustrating an example of a plane configuration of a second wiring layer together with the first wiring layer illustrated in FIG. 28.

FIG. 30 is a schematic view illustrating an example of a plane configuration of a third wiring layer together with the second wiring layer illustrated in FIG. 29.

FIG. 31 is a schematic view illustrating an example of a plane configuration of a fourth wiring layer together with the third wiring layer illustrated in FIG. 30.

FIG. 32 is a schematic cross-sectional view illustrating another example of an imaging device illustrated in FIG. 3.

FIG. 33 is a schematic view for describing a path of an input signal to the imaging device illustrated in FIG. 32.

FIG. 34 is a schematic view for describing a signal path of a pixel signal of the imaging device illustrated in FIG. 32.

FIG. 35 is a schematic cross-sectional view illustrating another example of the imaging device illustrated in FIG. 6.

FIG. 36 is a diagram illustrating another example of the equivalent circuit illustrated in FIG. 4.

FIG. 37 is a schematic plan view illustrating another example of a pixel separation portion illustrated in FIG. 7A, and the like.

FIG. 38 is a cross-sectional view in a thickness direction, which illustrates a configuration example of an imaging device according to Modified Example 8 of a first embodiment of the present disclosure.

FIG. 39 is a cross-sectional view in a thickness direction (part 1), which illustrates a configuration example of an imaging device according to Modified Example 8 of a first embodiment of the present disclosure.

FIG. 40 is a cross-sectional view in a thickness direction (part 2), which illustrates a configuration example of an imaging device according to Modified Example 8 of a first embodiment of the present disclosure.

FIG. 41 is a horizontal cross-sectional view (part 1) illustrating a layout example of a plurality of pixel units according to Modified Example 8 of a first embodiment of the present disclosure.

FIG. 42 is a horizontal cross-sectional view (part 2) illustrating a layout example of a plurality of pixel units according to Modified Example 8 of a first embodiment of the present disclosure.

FIG. 43 is a horizontal cross-sectional view (part 3) illustrating a layout example of a plurality of pixel units according to Modified Example 8 of a first embodiment of the present disclosure.

FIG. 44 is a diagram illustrating a circuit configuration example of an imaging device according to a second embodiment of the present disclosure.

FIG. 45 is a schematic longitudinal sectional view of an imaging device.

FIG. 46 is a view illustrating a schematic structure example of a first substrate.

FIG. 47 is a view illustrating a schematic structure example of a second substrate.

FIG. 48 is a view for describing an example of a cross-sectional configuration of an imaging device.

FIG. 49 is a view for describing an example of a plane configuration of a first substrate and a second substrate.

FIG. 50 is a flow diagram for describing an example of a procedure of a manufacturing process of an imaging device according to a second embodiment of the present disclosure.

FIG. 51 is a flow diagram for describing an example of a procedure of a manufacturing process of an imaging device according to a second embodiment of the present disclosure.

FIG. 52 is a flow diagram for describing an example of a procedure of a manufacturing process of an imaging device according to a second embodiment of the present disclosure.

FIG. 53 is a flow diagram for describing an example of a procedure of a manufacturing process of an imaging device according to a second embodiment of the present disclosure.

FIG. 54 is a flow diagram for describing an example of a procedure of a manufacturing process of an imaging device according to a second embodiment of the present disclosure.

FIG. 55 is a flow diagram for describing an example of a procedure of a manufacturing process of an imaging device according to a second embodiment of the present disclosure.

FIG. 56 is a view illustrating an imaging device according to a comparative example.

FIG. 57 is a view illustrating an imaging device according to a comparative example.

FIG. 58 is a schematic view for describing a modified example of a PID protection element.

FIG. 59 is a schematic view for describing a modified example of a PID protection element.

FIG. 60 is a schematic view for describing a modified example of a PID protection element.

FIG. 61 is a schematic view for describing a modified example of a PID protection element.

FIG. 62 is a schematic view for describing a modified example of a PID protection element.

FIG. 63 is a schematic view for describing a modified example of a PID protection element.

FIG. 64 is a schematic view for describing a modified example of a PID protection element.

FIG. 65 is a schematic view for describing a modified example of a PID protection element.

FIG. 66 is a schematic view for describing a modified example of an imaging device.

FIG. 67 is a schematic view for describing a modified example of an imaging device.

FIG. 68 is a diagram for describing an example of application to a semiconductor memory (DRAM).

FIG. 69 is a diagram for describing an example of application to SoC.

FIG. 70 is a diagram illustrating an example of a schematic configuration of an imaging system including an imaging device according to the embodiment and the modified examples thereof.

FIG. 71 is a flowchart illustrating an example of an imaging procedure of the imaging system illustrated in FIG. 70.

FIG. 72 is a block diagram illustrating an example of a schematic configuration of a vehicle control system.

FIG. 73 is an explanatory view illustrating an example of installation positions of a vehicle exterior information detection unit and an imaging unit.

FIG. 74 is a diagram illustrating an example of a schematic configuration of an endoscopic surgery system.

FIG. 75 is a block diagram illustrating an example of functional configurations of a camera head and a CCU.

### DESCRIPTION OF EMBODIMENTS

Hereinafter, modes for carrying out the present disclosure will be described in detail with reference to the drawings. Note that, the description will be given in the following order.

1. First Embodiment (Imaging Device Having Stacked Structure of Three Substrates)

1.1. Functional Configuration of Imaging Device 1

1.2. Schematic Configuration of Imaging Device 1

1.3. Specific Configuration of Imaging Device 1

1.4. Operation of Imaging Device 1

1.5. Effects

2. Modified Example (Modified Example of First Embodiment)

2.1. Modified Example 1-1 (Example 1 of Plane Configuration)

2.2. Modified Example 1-2 (Example 2 of Plane Configuration)

2.3. Modified Example 1-3 (Example 3 of Plane Configuration)

2.4. Modified Example 1-4 (Example in which Contact Portion between Substrates is Provided in Center Portion of Pixel Array Unit)

2.5. Modified Example 1-5 (Example of Including Planar Transfer Transistor)

2.6. Modified Example 1-6 (Example in which One Pixel is Connected to One Pixel Circuit)

2.7. Modified Example 1-7 (Configuration Example of Pixel Separation Portion)

2.8. Modified Example 1-8

3. Second Embodiment (Imaging Device Having PID Protection Element)

3.1. Functional Configuration Example of Imaging device 1A

3.2. Schematic Structure Example of Imaging Device 1A

3.3. Specific Configuration Example of Imaging Device 1A

3.4. Example of Manufacturing Process of Imaging Device 1A

3.5. Comparative Example

4. Modified Example (Modified Example of Second Embodiment)

4.1. Modified Example 2-1 (Example 1 of PID Protection Element)

4.2. Modified Example 2-2 (Example 2 of PID Protection Element)

4.3. Modified Example 2-3 (Example 3 of PID Protection Element)

4.4. Modified Example 2-4 (Example in which PID Protection Element is Provided in First and Second Substrates)

4.5. Modified Example 2-5 (Example in which PID Protection Element is Provided in First Substrate)

5. Applied Example (Example of Application to Semiconductor Device of Second Embodiment)

6. Application Example

6.1. Example of Application to Imaging System

6.2. Example of Application to Product System

6.2.1. Moving Body Control System

6.2.2. Endoscopic Surgery System

### 1. First Embodiment

[1.1. Functional Configuration of Imaging Device 1]

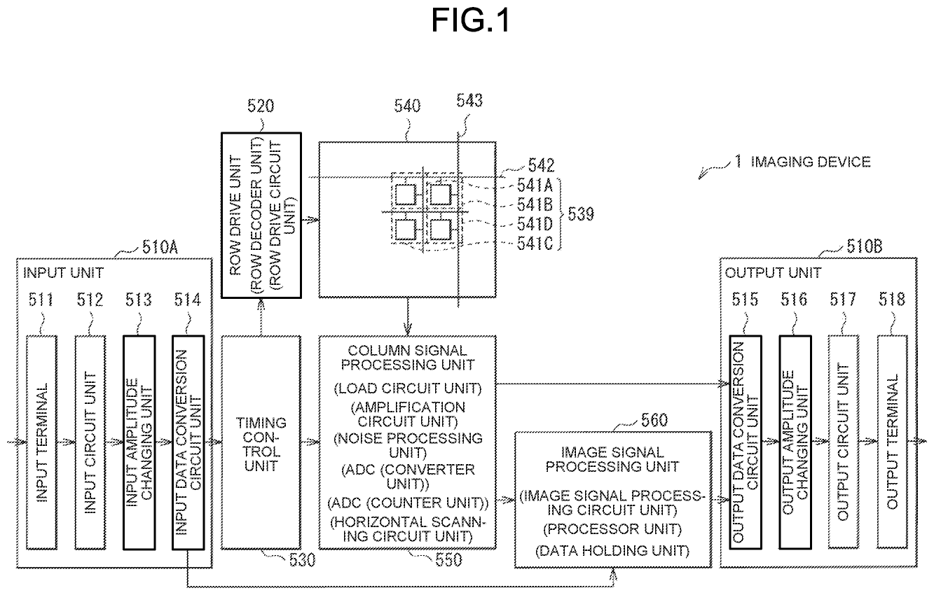

FIG. 1 is a block diagram illustrating an example of a functional configuration of an imaging device (imaging device 1) according to an embodiment of the present disclosure.

The imaging device 1 of FIG. 1 includes, for example, an input unit 510A, a row drive unit 520, a timing control unit 530, a pixel array unit 540, a column signal processing unit 550, an image signal processing unit 560, and an output unit 510B.

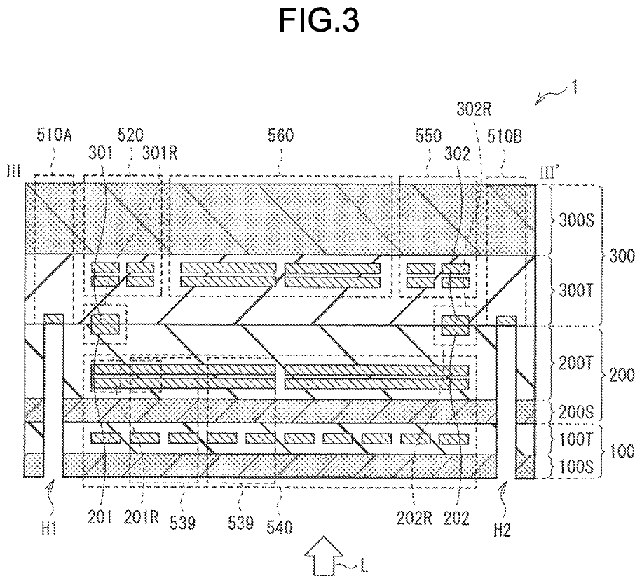

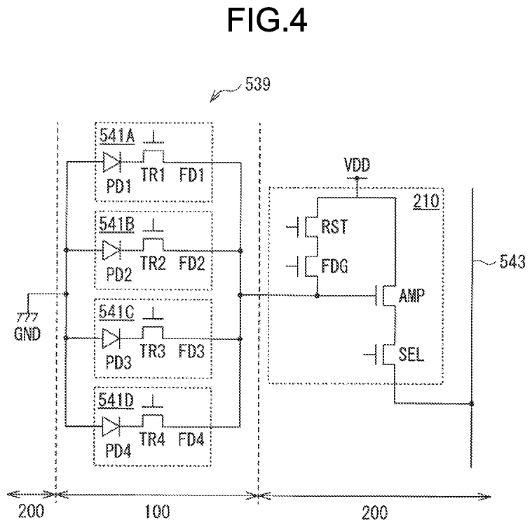

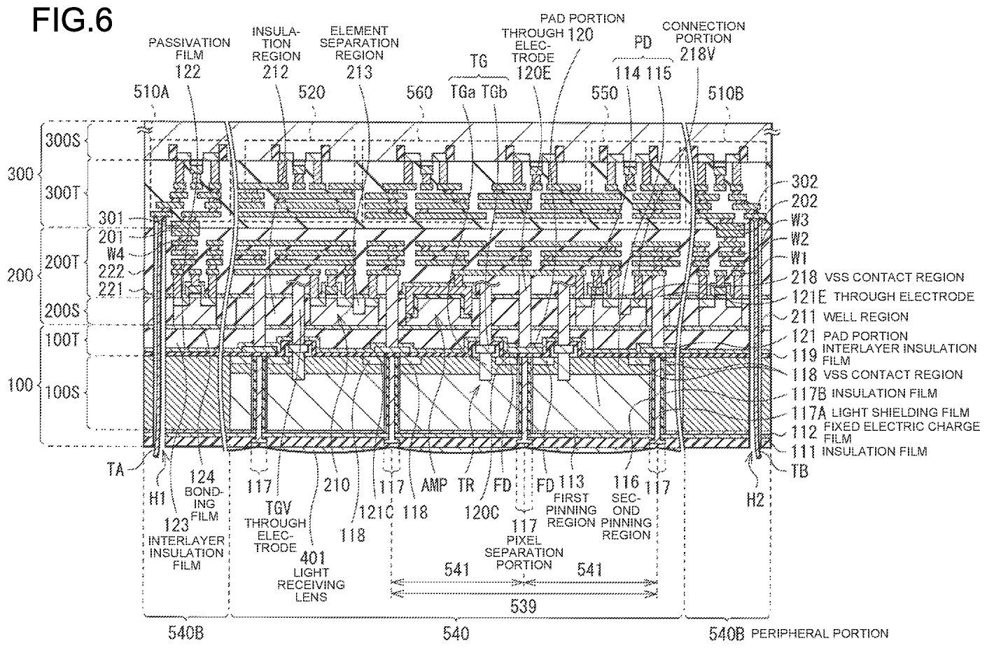

In the pixel array unit 540, a pixel 541 is repeatedly arranged in an array. More specifically, a pixel sharing unit 539 including a plurality of pixels is a repeating unit, and is repeatedly disposed in an array formed with a row direction and a column direction. Note that, in the present specification, for convenience, the row direction may be referred to as an H direction, and the column direction orthogonal to the row direction may be referred to as a V direction. In an example of FIG. 1, one pixel sharing unit 539 includes four pixels (pixels 541A, 541B, 541C, and 541D). Each of the pixels 541A, 541B, 541C, and 541D includes a photodiode PD (illustrated in FIG. 6 and the like to be described later). The pixel sharing unit 539 is a unit that shares one pixel circuit (pixel circuit 210 in FIG. 3 to be described later). In other words, one pixel circuit (pixel circuit 210 to be described later) is provided for every four pixels (pixels 541A, 541B, 541C, and 541D). By operating this pixel circuit in a time-division manner, the pixel signal of each of the pixels 541A, 541B, 541C, and 541D is sequentially read. The pixels 541A, 541B, 541C, and 541D are arranged in, for example, two rows×two columns. In the pixel array unit 540, a plurality of row drive signal lines 542 and a plurality of vertical signal lines (column read lines) 543 are provided together with the pixels 541A, 541B, 541C, and 541D. The row drive signal lines 542 drive the pixels 541 included in each of a plurality of the pixel sharing units 539 arranged side by side in the row direction in the pixel array unit 540. In the pixel sharing unit 539, each of the pixels arranged side by side in the row direction is driven. As will be described in detail later with reference to FIG. 4, the pixel sharing unit 539 is provided with a plurality of transistors. In order to drive each of a plurality of the transistors, a plurality of the row drive signal lines 542 are connected to one pixel sharing unit 539. The pixel sharing unit 539 is connected to the vertical signal lines (column read lines) 543. A pixel signal is read from each of the pixels 541A, 541B, 541C, and 541D included in the pixel sharing unit 539 via the vertical signal lines (column read lines) 543.

FIG. 1 is a block diagram illustrating an example of a functional configuration of an imaging device (imaging device 1) according to an embodiment of the present disclosure.

The imaging device 1 of FIG. 1 includes, for example, an input unit 510A, a row drive unit 520, a timing control unit 530, a pixel array unit 540, a column signal processing unit 550, an image signal processing unit 560, and an output unit 510B.

In the pixel array unit 540, a pixel 541 is repeatedly arranged in an array. More specifically, a pixel sharing unit 539 including a plurality of pixels is a repeating unit, and is repeatedly disposed in an array formed with a row direction and a column direction. Note that, in the present specification, for convenience, the row direction may be referred to as an H direction, and the column direction orthogonal to the row direction may be referred to as a V direction. In an example of FIG. 1, one pixel sharing unit 539 includes four pixels (pixels 541A, 541B, 541C, and 541D). Each of the pixels 541A, 541B, 541C, and 541D includes a photodiode PD (illustrated in FIG. 6 and the like to be described later). The pixel sharing unit 539 is a unit that shares one pixel circuit (pixel circuit 210 in FIG. 3 to be described later). In other words, one pixel circuit (pixel circuit 210 to be described later) is provided for every four pixels (pixels 541A, 541B, 541C, and 541D). By operating this pixel circuit in a time-division manner, the pixel signal of each of the pixels 541A, 541B, 541C, and 541D is sequentially read. The pixels 541A, 541B, 541C, and 541D are arranged in, for example, two rows×two columns. In the pixel array unit 540, a plurality of row drive signal lines 542 and a plurality of vertical signal lines (column read lines) 543 are provided together with the pixels 541A, 541B, 541C, and 541D. The row drive signal lines 542 drive the pixels 541 included in each of a plurality of the pixel sharing units 539 arranged side by side in the row direction in the pixel array unit 540. In the pixel sharing unit 539, each of the pixels arranged side by side in the row direction is driven. As will be described in detail later with reference to FIG. 4, the pixel sharing unit 539 is provided with a plurality of transistors. In order to drive each of a plurality of the transistors, a plurality of the row drive signal lines 542 are connected to one pixel sharing unit 539. The pixel sharing unit 539 is connected to the vertical signal lines (column read lines) 543. A pixel signal is read from each of the pixels 541A, 541B, 541C, and 541D included in the pixel sharing unit 539 via the vertical signal lines (column read lines) 543.

The row drive unit 520 includes, for example, a row address control unit that determines a position of a row for driving a pixel, in other words, includes a row decoder unit, and a row drive circuit unit that generates a signal for driving the pixels 541A, 541B, 541C, and 541D.

The column signal processing unit 550 includes, for example, a load circuit unit that is connected to the vertical signal lines 543 and forms a source follower circuit with the pixels 541A, 541B, 541C, and 541D (pixel sharing unit 539). The column signal processing unit 550 may include an amplifier circuit unit that amplifies a signal read from the pixel sharing unit 539 via the vertical signal lines 543. The column signal processing unit 550 may include a noise processing unit. In the noise processing unit, for example, a noise level of a system is removed from the signal read from the pixel sharing unit 539 as a result of a photoelectric conversion.

The column signal processing unit 550 includes, for example, an analog-digital converter (ADC). In the analog-digital converter, the signal read from the pixel sharing unit 539 or the noise-processed analog signal is converted into a digital signal. The ADC includes, for example, a comparator unit and a counter unit. In the comparator unit, an analog signal to be converted is compared with a reference signal to be compared with the analog signal. In the counter unit, time until the comparison result in the comparator unit is inverted is measured. The column signal processing unit 550 may include a horizontal scanning circuit unit that performs control to scan a column to be read.

The timing control unit 530 supplies a signal for controlling timing to the row drive unit 520 and the column signal processing unit 550 on the basis of a reference clock signal and a timing control signal, which are input to the device.

The image signal processing unit 560 is a circuit that performs various signal processing on data obtained by performing photoelectric conversion, in other words, data obtained by performing an imaging operation in the imaging device 1. The image signal processing unit 560 includes, for example, an image signal processing circuit unit and a data holding unit. The image signal processing unit 560 may include a processor unit.

As an example of the signal processing executed in the image signal processing unit 560, there is tone curve correction processing of increasing the number of gradations in a case where AD-converted imaging data is data obtained by imaging a dark subject, and reducing the number of gradations in a case where the AD-converted imaging data is data obtained by imaging a bright subject. In this case, regarding that on the basis of which tone curve the gradation of the imaging data is corrected, it is desirable to store characteristic data of the tone curve in the data holding unit of the image signal processing unit 560 in advance.

The input unit 510A is for inputting, for example, the reference clock signal, the timing control signal, the characteristic data, and the like to the imaging device 1 from the outside of the device. The timing control signal is, for example, a vertical synchronization signal, a horizontal synchronization signal, or the like. The characteristic data is, for example, to be stored in the data holding unit of the image signal processing unit 560. The input unit 510A includes, for example, an input terminal 511, an input circuit unit 512, an input amplitude changing unit 513, an input data conversion circuit unit 514, and a power supply unit (not illustrated).

The input terminal 511 is an external terminal for inputting data. The input circuit unit 512 is for taking in a signal input to the input terminal 511 into the imaging device 1. In the input amplitude changing unit 513, the amplitude of the signal taken in by the input circuit unit 512 is changed to an amplitude that can be easily used inside the imaging device 1. In the input data conversion circuit unit 514, the arrangement of data rows of the input data is changed. The input data conversion circuit unit 514 includes, for example, a serial-parallel conversion circuit. In the serial-parallel conversion circuit, a serial signal received as input data is converted into a parallel signal. Note that, in the input unit 510A, the input amplitude changing unit 513 and the input data conversion circuit unit 514 may be omitted. The power supply unit supplies power set to various voltages required inside the imaging device 1 on the basis of power supplied to the imaging device 1 from the outside.

When the imaging device 1 is connected to an external memory device, the input unit 510A may be provided with a memory interface circuit that receives data from the external memory device. Examples of the external memory device include a flash memory, an SRAM, and a DRAM.

The output unit 510B outputs image data to the outside of the device. The image data includes, for example, image data captured by the imaging device 1, image data subjected to signal processing by the image signal processing unit 560, and the like. The output unit 510B includes, for example, an output data conversion circuit unit 515, an output amplitude changing unit 516, an output circuit unit 517, and an output terminal 518.

The output data conversion circuit unit 515 is configured of, for example, a parallel-serial conversion circuit, and in the output data conversion circuit unit 515, a parallel signal used inside the imaging device 1 is converted into a serial signal. The output amplitude changing unit 516 changes an amplitude of the signal used inside the imaging device 1. The signal having the changed amplitude is easily used in an external device connected to the outside of the imaging device 1. The output circuit unit 517 is a circuit that outputs data from the inside of the imaging device 1 to the outside of the device, and a wiring outside the imaging device 1 connected to the output terminal 518 is driven by the output circuit unit 517. At the output terminal 518, data is output from the imaging device 1 to the outside of the device. In the output unit 510B, the output data conversion circuit unit 515 and the output amplitude changing unit 516 may be omitted.

When the imaging device 1 is connected to an external memory device, the output unit 510B may be provided with a memory interface circuit that outputs data to the external memory device. Examples of the external memory device include a flash memory, an SRAM, and a DRAM.

[1.2. Schematic Configuration of Imaging Device 1]

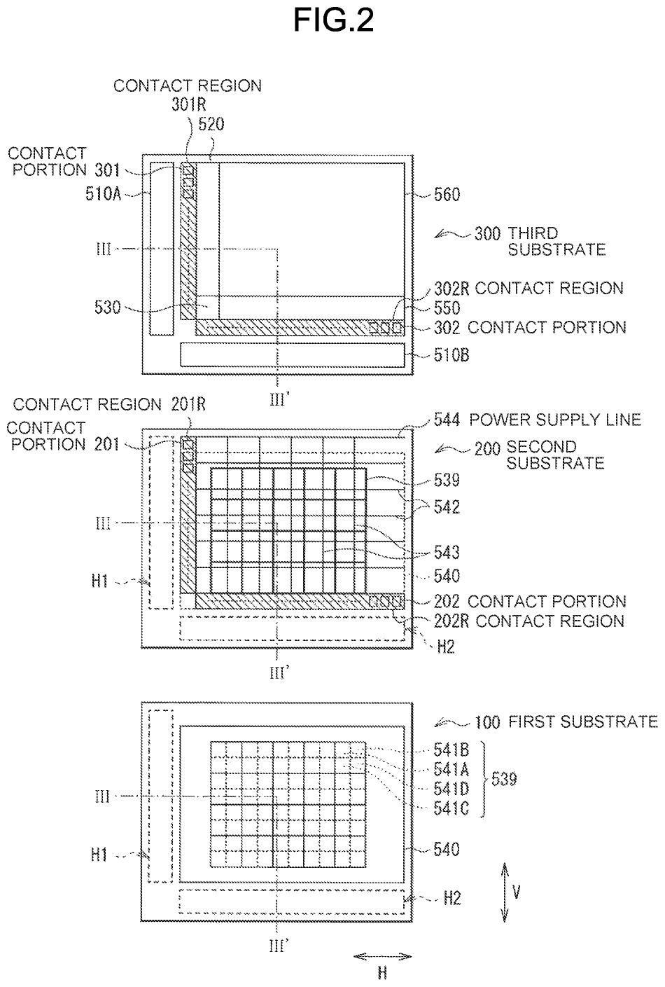

FIGS. 2 and 3 illustrate an example of a schematic configuration of the imaging device 1. The imaging device 1 includes three substrates (first substrate 100, second substrate 200, and third substrate 300). FIG. 2 schematically illustrates a plane configuration of each of the first substrate 100, the second substrate 200, and the third substrate 300, and FIG. 3 schematically illustrates a cross-sectional configuration of the first substrate 100, the second substrate 200, and the third substrate 300 which are stacked on each other. FIG. 3 corresponds to the cross-sectional configuration taken along line III-III′ illustrated in FIG. 2. The imaging device 1 is an imaging device having a three-dimensional structure formed by bonding three substrates (first substrate 100, second substrate 200, and third substrate 300). The first substrate 100 includes a semiconductor layer 100S and a wiring layer 100T. The second substrate 200 includes a semiconductor layer 200S and a wiring layer 200T. The third substrate 300 includes a semiconductor layer 300S and a wiring layer 300T. Here, a combination of a wiring included in each of the first substrate 100, the second substrate 200, and the third substrate 300 and an interlayer insulation film around the wiring is, for convenience, referred to as a wiring layer (100T, 200T, and 300T) provided in each of the substrates (first substrate 100, second substrate 200, and third substrate 300). The first substrate 100, the second substrate 200, and the third substrate 300 are stacked in this order, and the semiconductor layer 100S, the wiring layer 100T, the semiconductor layer 200S, the wiring layer 200T, the wiring layer 300T, and the semiconductor layer 300S are disposed in this order along the stacking direction. Specific configurations of the first substrate 100, the second substrate 200, and the third substrate 300 will be described later. An arrow illustrated in FIG. 3 indicates a direction in which light L is incident to the imaging device 1. In the present specification, for convenience, in the following cross-sectional views, a light incident side in the imaging device 1 may be referred to as “lower”, “lower side”, and “downward”, and a side opposite to the light incident side may be referred to as “upper”, “upper side”, and “upward”. Furthermore, in the present specification, for convenience, regarding a substrate including a semiconductor layer and a wiring layer, a side of the wiring layer may be referred to as a front surface, and a side of the semiconductor layer may be referred to as a rear surface. Note that, the description of the specification is not limited to the terms described above. The imaging device 1 is, for example, a rear-surface irradiation imaging device in which light is incident from the rear surface side of the first substrate 100 including a photodiode.

Both the pixel array unit 540 and the pixel sharing unit 539 included in the pixel array unit 540 are configured by using both the first substrate 100 and the second substrate 200. The first substrate 100 is provided with a plurality of the pixels 541A, 541B, 541C, and 541D included in the pixel sharing unit 539. Each pixel 541 includes a photodiode (photodiode PD to be described later) and a transfer transistor (transfer transistor TR to be described later). The second substrate 200 is provided with a pixel circuit (pixel circuit 210 to be described later) included in the pixel sharing unit 539. The pixel circuit reads a pixel signal transferred from the photodiode of each of the pixels 541A, 541B, 541C, and 541D via the transfer transistor, or resets the photodiode. In addition to such a pixel circuit, the second substrate 200 includes a plurality of the row drive signal lines 542 extending in the row direction and a plurality of the vertical signal lines 543 extending in the column direction. The second substrate 200 further includes a power supply line 544 extending in the row direction. The third substrate 300 includes, for example, the input unit 510A, the row drive unit 520, the timing control unit 530, the column signal processing unit 550, the image signal processing unit 560, and the output unit 510B. For example, a part of the row drive unit 520 is provided in a region overlapping the pixel array unit 540 in the stacking direction of the first substrate 100, the second substrate 200, and the third substrate 300 (hereinafter, simply referred to as stacking direction). More specifically, in the stacking direction, the row drive unit 520 is provided in a region overlapping the vicinity of an end portion of the pixel array unit 540 in the H direction (FIG. 2). For example, a part of the column signal processing unit 550 is provided in a region overlapping the pixel array unit 540 in the stacking direction. More specifically, in the stacking direction, the column signal processing unit 550 is provided in a region overlapping the vicinity of an end portion of the pixel array unit 540 in the V direction (FIG. 2). Although not illustrated, the input unit 510A and the output unit 510B may be disposed in a portion other than the third substrate 300, for example, may be disposed in the second substrate 200. Alternatively, the input unit 510A and the output unit 510B may be provided on the rear surface (light incident surface) side of the first substrate 100. Note that, the pixel circuit provided in the second substrate 200 may also be referred to as a pixel transistor circuit, a pixel transistor group, a pixel transistor, a pixel read circuit, or a read circuit as another name. In the present specification, the term “pixel circuit” is used.

The first substrate 100 and the second substrate 200 are electrically connected by, for example, through electrodes (through electrodes 120E and 121E of FIG. 6 to be described later). For example, the second substrate 200 and the third substrate 300 are electrically connected via a contact portions 201, 202, 301, and 302. The contact portions 201 and 202 are provided in the second substrate 200, and the contact portions 301 and 302 are provided in the third substrate 300. The contact portion 201 of the second substrate 200 is in contact with the contact portion 301 of the third substrate 300, and the contact portion 202 of the second substrate 200 is in contact with the contact portion 302 of the third substrate 300. The second substrate 200 includes a contact region 201R in which a plurality of the contact portions 201 are provided and a contact region 202R in which a plurality of the contact portions 202 are provided. The third substrate 300 includes a contact region 301R in which a plurality of the contact portions 301 are provided and a contact region 302R in which a plurality of the contact portions 302 are provided. The contact regions 201R and 301R are provided between the pixel array unit 540 and the row drive unit 520 in the stacking direction (FIG. 3). In other words, the contact regions 201R and 301R are provided, for example, in a region in which the row drive unit 520 (third substrate 300) and the pixel array unit 540 (second substrate 200) overlap with each other in the stacking direction or in a region in the vicinity thereof. The contact regions 201R and 301R are disposed, for example, at end portions in the H direction in such regions (FIG. 2). In the third substrate 300, for example, the contact region 301R is provided in a part of the row drive unit 520, specifically, at a position overlapping an end portion of the row drive unit 520 in the H direction (FIGS. 2 and 3). For example, the contact portions 201 and 301 connect the row drive unit 520 provided in the third substrate 300 with each of the row drive signal lines 542 provided in the second substrate 200. For example, the contact portions 201 and 301 may connect the input unit 510A provided in the third substrate 300 with the power supply line 544 and a reference potential line (reference potential line VSS to be described later). The contact regions 202R and 302R are provided between the pixel array unit 540 and the column signal processing unit 550 in the stacking direction (FIG. 3). In other words, the contact regions 202R and 302R are provided, for example, in a region in which the column signal processing unit 550 (third substrate 300) and the pixel array unit 540 (second substrate 200) overlap with each other in the stacking direction or in a region in the vicinity thereof. The contact regions 202R and 302R are disposed, for example, at end portions in the V direction in such regions (FIG. 2). In the third substrate 300, for example, the contact region 301R is provided in a part of the column signal processing unit 550, specifically, at a position overlapping an end portion of the column signal processing unit 550 in the V direction (FIGS. 2 and 3). For example, the contact portions 202 and 302 connect a pixel signal (signal corresponding to the amount of electric charges generated as a result of the photoelectric conversion in the photodiode) output from each of a plurality of the pixel sharing units 539 included in the pixel array unit 540 to the column signal processing unit 550 provided in the third substrate 300. The pixel signal is transmitted from the second substrate 200 to the third substrate 300.

FIG. 3 is an example of a cross-sectional view of the imaging device 1 as described above. The first substrate 100, the second substrate 200, and the third substrate 300 are electrically connected to each other via the wiring layers 100T, 200T, and 300T. For example, the imaging device 1 includes an electrical connection portion that electrically connects the second substrate 200 and the third substrate 300. Specifically, the contact portions 201, 202, 301, and 302 are formed of an electrode formed of a conductive material. The conductive material is formed of, for example, a metal material such as copper (Cu), aluminum (Al), or gold (Au). The contact regions 201R, 202R, 301R, and 302R electrically connect the second substrate with the third substrate, for example, by directly bonding wirings formed as electrodes, and enable signal to be input and/or output between the second substrate 200 and the third substrate 300.

The electrical connection portion that electrically connects the second substrate 200 with the third substrate 300 can be provided at a desired place. For example, in a similar manner to the contact regions 201R, 202R, 301R, and 302R described in FIG. 3, the electrical connection portion may be provided in a region overlapping the pixel array unit 540 in the stacking direction. Furthermore, the electrical connection portion may be provided in a region not overlapping the pixel array unit 540 in the stacking direction. Specifically, the electrical connection portion may be provided in a region overlapping a peripheral portion disposed outside the pixel array unit 540 in the stacking direction.

The first substrate 100 and the second substrate 200 are provided with, for example, connection holes H1 and H2. The connection holes H1 and H2 penetrate the first substrate 100 and the second substrate 200 (FIG. 3). The connection holes H1 and H2 are provided outside the pixel array unit 540 (or a portion overlapping the pixel array unit 540) (FIG. 2). For example, the connection hole H1 is disposed outside the pixel array unit 540 in the H direction, and the connection hole H2 is disposed outside the pixel array unit 540 in the V direction. For example, the connection hole H1 reaches the input unit 510A provided in the third substrate 300, and the connection hole H2 reaches the output unit 510B provided in the third substrate 300. The connection holes H1 and H2 may be hollow or at least partially contain a conductive material. For example, there is a configuration in which a bonding wire is connected to an electrode formed as the input unit 510A and/or the output unit 510B. Alternatively, there is a configuration in which the electrode formed as the input unit 510A and/or the output unit 510B is connected to the conductive material provided in the connection holes H1 and H2. The conductive material provided in the connection holes H1 and H2 may be added in a part or all of the connection holes H1 and H2, and the conductive material may be formed on side walls of the connection holes H1 and H2.

Note that, in FIG. 3, the input unit 510A and the output unit 510B are provided in the third substrate 300, but the present disclosure is not limited thereto. For example, by transmitting a signal of the third substrate 300 to the second substrate 200 via the wiring layers 200T and 300T, the input unit 510A and/or the output unit 510B can be provided in the second substrate 200. In a similar manner, by transmitting a signal of the second substrate 200 to the first substrate 100 via the wiring layers 100T and 200T, the input unit 510A and/or the output unit 510B can be provided in the first substrate 100.

FIG. 4 is an equivalent circuit diagram illustrating an example of a configuration of the pixel sharing unit 539. The pixel sharing unit 539 includes a plurality of pixels 541 (in FIG. 4, four pixels 541 of pixels 541A, 541B, 541C, and 541D), one pixel circuit 210 connected to a plurality of the pixels 541, and a vertical signal line 543 connected to the pixel circuit 210. The pixel circuit 210 includes, for example, four transistors, specifically, an amplification transistor AMP, a selection transistor SEL, a reset transistor RST, and an FD conversion gain switching transistor FDG. As described above, the pixel sharing unit 539 sequentially outputs the pixel signal of each of four pixels 541 (pixels 541A, 541B, 541C, and 541D) included in the pixel sharing unit 539 to the vertical signal line 543 by operating one pixel circuit 210 in a time-division manner. One pixel circuit 210 is connected to a plurality of the pixels 541, and a mode in which pixel signals of a plurality of the pixels 541 are output by one pixel circuit 210 in a time-division manner is referred to as “a plurality of pixels 541 shares one pixel circuit 210”.

The pixels 541A, 541B, 541C, and 541D have common components. Hereinafter, in order to distinguish components of the pixels 541A, 541B, 541C, and 541D from each other, an identification number 1 is given to the end of a reference numeral of the component of the pixel 541A, an identification number 2 is given to the end of a reference numeral of the component of the pixel 541B, an identification number 3 is given to the end of a reference numeral of the component of the pixel 541C, and an identification number 4 is given to the end of a reference numeral of the component of the pixel 541D. In a case where it is not necessary to distinguish the components of the pixels 541A, 541B, 541C, and 541D from each other, the identification numbers at the ends of the reference numerals of the components of the pixels 541A, 541B, 541C, and 541D are omitted.

The pixels 541A, 541B, 541C, and 541D include, for example, the photodiode PD, the transfer transistor TR electrically connected to the photodiode PD, and a floating diffusion FD electrically connected to the transfer transistor TR. In the photodiode PD (PD1, PD2, PD3, or PD4), a cathode is electrically connected to a source of the transfer transistor TR, and an anode is electrically connected to the reference potential line (for example, ground). The photodiode PD performs photoelectric conversion on the incident light, and generates an electric charge corresponding to the amount of received light. The transfer transistor TR (transfer transistors TR1, TR2, TR3, or TR4) is, for example, an n-type complementary metal oxide semiconductor (CMOS) transistor. In the transfer transistor TR, a drain is electrically connected to the floating diffusion FD, and a gate is electrically connected to a drive signal line. This drive signal line is a part of a plurality of the row drive signal lines 542 (refer to FIG. 1) connected to one pixel sharing unit 539. The transfer transistor TR transfers the electric charge generated in the photodiode PD to the floating diffusion FD. The floating diffusion FD (floating diffusion FD1, FD2, FD3, or FD4) is an n-type diffusion layer region formed in a p-type semiconductor layer. The floating diffusion FD is electric charge holding means for temporarily holding an electric charge transferred from the photodiode PD, and is electric charge-voltage conversion means for generating a voltage corresponding to the electric charge amount.

Four floating diffusions FD (floating diffusions FD1, FD2, FD3, and FD4) included in one pixel sharing unit 539 are electrically connected to each other, and are electrically connected to a gate of the amplification transistor AMP and a source of the FD conversion gain switching transistor FDG. A drain of the FD conversion gain switching transistor FDG is connected to a source of the reset transistor RST, and a gate of the FD conversion gain switching transistor FDG is connected to the drive signal line. This drive signal line is a part of a plurality of the row drive signal lines 542 connected to one pixel sharing unit 539. A drain of the reset transistor RST is connected to a power supply line VDD, and a gate of the reset transistor RST is connected to the drive signal line. This drive signal line is a part of a plurality of the row drive signal lines 542 connected to one pixel sharing unit 539. The gate of the amplification transistor AMP is connected to the floating diffusion FD, a drain of the amplification transistor AMP is connected to the power supply line VDD, and a source of the amplification transistor AMP is connected to a drain of the selection transistor SEL. A source of the selection transistor SEL is connected to the vertical signal line 543, and a gate of the selection transistor SEL is connected to the drive signal line. This drive signal line is a part of a plurality of the row drive signal lines 542 connected to one pixel sharing unit 539.

When the transfer transistor TR is turned on, the transfer transistor TR transfers the electric charge of the photodiode PD to the floating diffusion FD. A gate (transfer gate TG) of the transfer transistor TR includes, for example, a so-called vertical electrode, and is provided to extend from a front surface of the semiconductor layer (semiconductor layer 100S in FIG. 6 to be described later) to a depth reaching the PD as illustrated in FIG. 6 to be described later. The reset transistor RST resets a potential of the floating diffusion FD to a predetermined potential. When the reset transistor RST is turned on, the reset transistor RST resets the potential of the floating diffusion FD to a potential of the power supply line VDD. The selection transistor SEL controls an output timing of the pixel signal from the pixel circuit 210. The amplification transistor AMP generates, as a pixel signal, a signal of a voltage corresponding to a level of the electric charge held in the floating diffusion FD. The amplification transistor AMP is connected to the vertical signal line 543 via the selection transistor SEL. The amplification transistor AMP constitutes a source follower together with a load circuit unit (refer to FIG. 1) connected to the vertical signal line 543 in the column signal processing unit 550. When the selection transistor SEL is turned on, the amplification transistor AMP outputs a voltage of the floating diffusion FD to the column signal processing unit 550 via the vertical signal line 543. The reset transistor RST, the amplification transistor AMP, and the selection transistor SEL are, for example, N-type CMOS transistors.

The FD conversion gain switching transistor FDG is used when changing a gain of electric charge-voltage conversion in the floating diffusion FD. In general, the pixel signal is small at the time of imaging in a dark place. In a case where electric charge-voltage conversion is performed on the basis of Q=CV, when capacitance (FD capacitance C) of the floating diffusion FD is large, V at the time of conversion into a voltage by the amplification transistor AMP becomes small. On the other hand, in a bright place, since the pixel signal becomes large, the floating diffusion FD cannot receive the electric charge of the photodiode PD unless the FD capacitance C is large. Moreover, the FD capacitance C needs to be large so that V at the time of conversion into a voltage by the amplification transistor AMP does not become excessively large (in other words, it is made smaller). According to this, when the FD conversion gain switching transistor FDG is turned on, a gate capacitance of the FD conversion gain switching transistor FDG increases. Therefore the entire FD capacitance C increases. On the other hand, when the FD conversion gain switching transistor FDG is turned off, the entire FD capacitance C decreases. In this manner, by turning on and off the FD conversion gain switching transistor FDG, the FD capacitance C can be changed, and conversion efficiency can be changed. The FD conversion gain switching transistor FDG is, for example, an N-type CMOS transistor.

Note that, a configuration in which the FD conversion gain switching transistor FDG is not provided is also possible. At this time, for example, the pixel circuit 210 includes three transistors, for example, the amplification transistor AMP, the selection transistor SEL, and the reset transistor RST. The pixel circuit 210 includes, for example, at least one of the pixel transistors such as the amplification transistor AMP, the selection transistor SEL, the reset transistor RST, and the FD conversion gain switching transistor FDG.

The selection transistor SEL may be provided between the power supply line VDD and the amplification transistor AMP. In this case, the drain of the reset transistor RST is electrically connected to the power supply line VDD and the drain of the selection transistor SEL. The source of the selection transistor SEL is electrically connected to the drain of the amplification transistor AMP, and the gate of the selection transistor SEL is electrically connected to the row drive signal lines 542 (refer to FIG. 1). The source of the amplification transistor AMP (output end of the pixel circuit 210) is electrically connected to the vertical signal line 543, and the gate of the amplification transistor AMP is electrically connected to the source of the reset transistor RST. Note that, although not illustrated, the number of the pixels 541 sharing one pixel circuit 210 may not be four. For example, two or eight pixels 541 may share one pixel circuit 210.

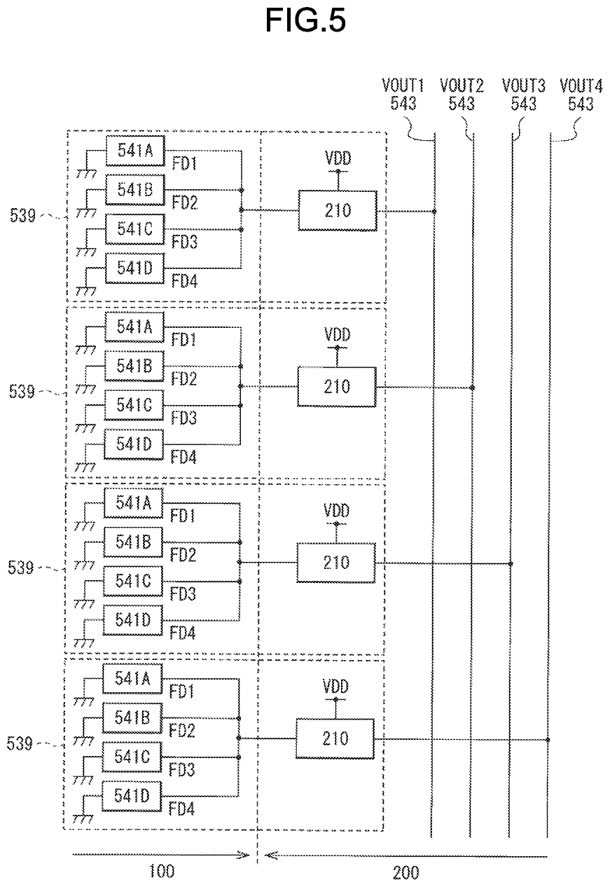

FIG. 5 illustrates an example of a connection state between a plurality of the pixel sharing units 539 and the vertical signal line 543. For example, four pixel sharing units 539 arranged in the column direction are divided into four groups, and the vertical signal line 543 is connected to each of four groups. For ease of description, FIG. 5 illustrates an example in which each of four groups includes one pixel sharing unit 539, but each of four groups may include a plurality of the pixel sharing units 539. As described above, in the imaging device 1, a plurality of the pixel sharing units 539 arranged in the column direction may be divided into groups including one or a plurality of the pixel sharing units 539. For example, the vertical signal line 543 and the column signal processing unit 550 are connected to each of the groups, and pixel signals can be simultaneously read from each of the groups. Alternatively, in the imaging device 1, one vertical signal line 543 may be connected to a plurality of the pixel sharing units 539 arranged in the column direction. At this time, the pixel signals are sequentially read in a time-division manner from a plurality of the pixel sharing units 539 connected to one vertical signal line 543.

[1.3. Specific Configuration of Imaging Device 1]

FIG. 6 illustrates an example of a cross-sectional configuration of the imaging device 1 in a direction perpendicular to the main surfaces of the first substrate 100, the second substrate 200, and the third substrate 300. FIG. 6 schematically illustrates a positional relationship of the components for easy understanding, and may be different from the actual cross section. In the imaging device 1, the first substrate 100, the second substrate 200, and the third substrate 300 are stacked in this order. The imaging device 1 further includes a light receiving lens 401 on the rear surface side (light incident surface side) of the first substrate 100. A color filter layer (not illustrated) may be provided between the light receiving lens 401 and the first substrate 100. The light receiving lens 401 is provided, for example, in each of the pixels 541A, 541B, 541C, and 541D. The imaging device 1 is, for example, a rear-surface irradiation imaging device. The imaging device 1 includes the pixel array unit 540 disposed in a center portion and a peripheral portion 540B disposed outside the pixel array unit 540.

The first substrate 100 includes an insulation film 111, a fixed electric charge film 112, the semiconductor layer 100S, and the wiring layer 100T in this order from the light receiving lens 401 side. The semiconductor layer 100S is configured of, for example, a silicon substrate. The semiconductor layer 100S includes, for example, a p-well layer 115 in a part of the front surface (surface on the wiring layer 100T side) and in the vicinity thereof, and an n-type semiconductor region 114 in the other region (region deeper than the p-well layer 115). For example, the n-type semiconductor region 114 and the p-well layer 115 constitute a pn junction type photodiode PD. The p-well layer 115 is a p-type semiconductor region.

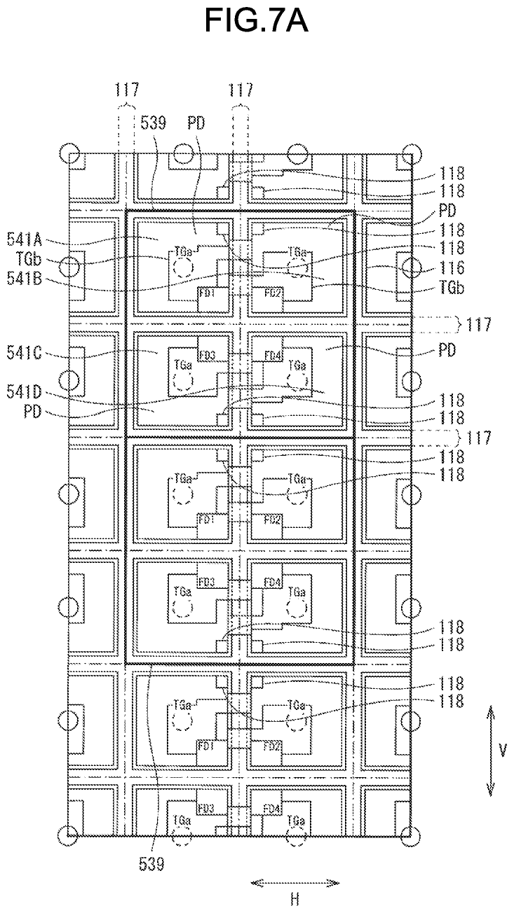

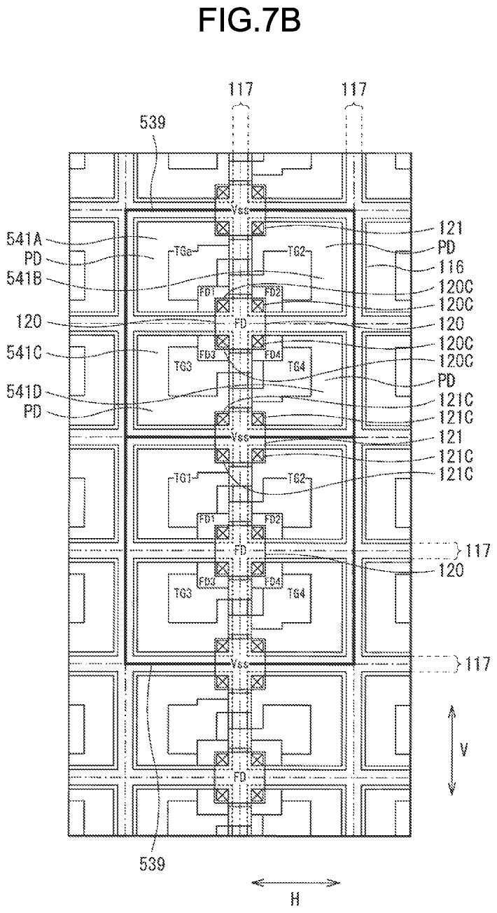

FIG. 7A illustrates an example of a plane configuration of the first substrate 100. FIG. 7A mainly illustrates a plane configuration of a pixel separation portion 117, the photodiode PD, the floating diffusion FD, a VSS contact region 118, and the transfer transistor TR of the first substrate 100. A configuration of the first substrate 100 will be described with reference to FIG. 7A together with FIG. 6.

The floating diffusion FD and the VSS contact region 118 are provided in the vicinity of the front surface of the semiconductor layer 100S. The floating diffusion FD includes an n-type semiconductor region provided in the p-well layer 115. For example, the respective floating diffusions FD (floating diffusions FD1, FD2, FD3, and FD4) of each of the pixels 541A, 541B, 541C, and 541D are provided close to each other in the center portion of the pixel sharing unit 539 (FIG. 7A). Details will be described later, and four floating diffusions (floating diffusions FD1, FD2, FD3, and FD4) included in the pixel sharing unit 539 are electrically connected to each other via electrical connection means (pad portion 120 to be described later) in the first substrate 100 (more specifically, in the wiring layer 100T). Moreover, each of the floating diffusions FD is connected from the first substrate 100 to the second substrate 200 (more specifically, from the wiring layer 100T to the wiring layer 200T) via electrical means (through electrode 120E to be described later). In the second substrate 200 (more specifically, inside the wiring layer 200T), the floating diffusion FD is electrically connected to the gate of the amplification transistor AMP and the source of the FD conversion gain switching transistor FDG by this electrical means.

The VSS contact region 118 is a region electrically connected to the reference potential line VSS, and is disposed away from the floating diffusion FD. For example, in the pixels 541A, 541B, 541C, and 541D, the floating diffusion FD is disposed at one end of each of the pixels in the V direction, and the VSS contact region 118 is disposed at the other end of each of the pixels (FIG. 7A). The VSS contact region 118 is configured by, for example, the p-type semiconductor region. The VSS contact region 118 is connected to, for example, a ground potential or a fixed potential. As a result, a reference potential is supplied to the semiconductor layer 100S.

In addition to the photodiode PD, the floating diffusion FD, and the VSS contact region 118, the transfer transistor TR is provided in the first substrate 100. The photodiode PD, the floating diffusion FD, the VSS contact region 118, and the transfer transistor TR are provided in each of the pixels 541A, 541B, 541C, and 541D. The transfer transistor TR is provided on the front surface side (side opposite to the light incident surface side, and the second substrate 200 side) of the semiconductor layer 100S. The transfer transistor TR includes the transfer gate TG. The transfer gate TG includes, for example, a horizontal portion TGb facing the front surface of the semiconductor layer 100S and a vertical portion TGa provided in the semiconductor layer 100S. The vertical portion TGa extends in a thickness direction of the semiconductor layer 100S. One end of the vertical portion TGa is in contact with the horizontal portion TGb, and the other end is provided in the n-type semiconductor region 114. Since the transfer transistor TR is configured by such a vertical transistor, transfer failure of the pixel signal hardly occurs, and read efficiency of the pixel signal can be improved.

The horizontal portion TGb of the transfer gate TG extends, for example, from a position facing the vertical portion TGa toward the center portion of the pixel sharing unit 539 in the H direction (FIG. 7A). As a result, a position of the through electrode (through electrode TGV to be described later) reaching the transfer gate TG in the H direction can be brought close to a position of the through electrode (through electrode 120E or 121E to be described later) connected to the floating diffusion FD and the VSS contact region 118 in the H direction. For example, a plurality of the pixel sharing units 539 provided in the first substrate 100 have the same configuration (FIG. 7A).

The semiconductor layer 100S is provided with the pixel separation portion 117 that separates the pixels 541A, 541B, 541C, and 541D from each other. The pixel separation portion 117 is formed to extend in a normal direction of the semiconductor layer 100S (direction perpendicular to the front surface of the semiconductor layer 100S). The pixel separation portion 117 is provided so as to partition the pixels 541A, 541B, 541C, and 541D from each other, and has, for example, a grid-like planar shape (FIGS. 7A and 7B). For example, the pixel separation portion 117 electrically and optically separates the pixels 541A, 541B, 541C, and 541D from each other. The pixel separation portion 117 includes, for example, a light shielding film 117A and an insulation film 117B. For example, tungsten (W) or the like is used for the light shielding film 117A. The insulation film 117B is provided between the light shielding film 117A and the p-well layer 115 or the n-type semiconductor region 114. The insulation film 117B is formed of, for example, silicon oxide (SiO). The pixel separation portion 117 has, for example, a full trench isolation (FTI) structure and penetrates the semiconductor layer 100S. Although not illustrated, the pixel separation portion 117 is not limited to the FTI structure penetrating the semiconductor layer 100S. For example, a deep trench isolation (DTI) structure that does not penetrate the semiconductor layer 100S may be used. The pixel separation portion 117 extends in the normal direction of the semiconductor layer 100S, and is formed in a partial region of the semiconductor layer 100S.

In the semiconductor layer 100S, for example, a first pinning region 113 and a second pinning region 116 are provided. The first pinning region 113 is provided in the vicinity of the rear surface of the semiconductor layer 100S, and is disposed between the n-type semiconductor region 114 and the fixed electric charge film 112. The second pinning region 116 is provided on a side surface of the pixel separation portion 117, specifically, between the pixel separation portion 117 and the p-well layer 115 or the n-type semiconductor region 114. The first pinning region 113 and the second pinning region 116 are configured by, for example, the p-type semiconductor region.

The fixed electric charge film 112 having a negative fixed electric charge is provided between the semiconductor layer 100S and the insulation film 111. The first pinning region 113 of a hole accumulation layer is formed at an interface on a light receiving surface (rear surface) side of the semiconductor layer 100S by an electric field induced by the fixed electric charge film 112. Accordingly, generation of a dark current caused by an interface state on the light receiving surface side of the semiconductor layer 100S is suppressed. The fixed electric charge film 112 is formed of, for example, an insulation film having the negative fixed electric charge. Examples of a material of the insulation film having the negative fixed electric charge include hafnium oxide, zircon oxide, aluminum oxide, titanium oxide, or tantalum oxide.

The light shielding film 117A is provided between the fixed electric charge film 112 and the insulation film 111. The light shielding film 117A may be provided continuously with the light shielding film 117A configuring the pixel separation portion 117. The light shielding film 117A between the fixed electric charge film 112 and the insulation film 111 is selectively provided, for example, at a position facing the pixel separation portion 117 in the semiconductor layer 100S. The insulation film 111 is provided so as to cover the light shielding film 117A. The insulation film 111 is formed of, for example, silicon oxide.

The wiring layer 100T provided between the semiconductor layer 100S and the second substrate 200 includes an interlayer insulation film 119, pad portions 120 and 121, a passivation film 122, an interlayer insulation film 123, and a bonding film 124 in this order from the semiconductor layer 100S side. For example, the horizontal portion TGb of the transfer gate TG is provided in the wiring layer 100T. The interlayer insulation film 119 is provided over the entire front surface of the semiconductor layer 100S, and is in contact with the semiconductor layer 100S. The interlayer insulation film 119 is configured by, for example, a silicon oxide film. Note that, the configuration of the wiring layer 100T is not limited to the above, and may be a configuration including a wiring and an insulation film.

FIG. 7B illustrates a configuration of the pad portions 120 and 121 together with the plane configuration illustrated in FIG. 7A. The pad portions 120 and 121 are provided in a selective region on the interlayer insulation film 119. The pad portion 120 connects the floating diffusions FD (floating diffusions FD1, FD2, FD3, and FD4) of the pixels 541A, 541B, 541C, and 541D to each other. For example, the pad portion 120 is disposed at the center portion of the pixel sharing unit 539 in a plan view for each of the pixel sharing units 539 (FIG. 7B). The pad portion 120 is provided so as to cover the pixel separation portion 117, and is disposed so as to overlap at least a part of each of the floating diffusions FD1, FD2, FD3, and FD4 (FIGS. 6 and 7B). Specifically, the pad portion 120 is formed in a region overlapping at least a part of each of a plurality of the floating diffusions FD (floating diffusions FD1, FD2, FD3, and FD4) sharing the pixel circuit 210 and at least a part of the pixel separation portion 117 formed between a plurality of the photodiodes PD (photodiodes PD1, PD2, PD3, and PD4) sharing the pixel circuit 210 in a direction perpendicular to the front surface of the semiconductor layer 100S. The interlayer insulation film 119 is provided with a connection via 120C for electrically connecting the pad portion 120 with the floating diffusions FD1, FD2, FD3, and FD4. The connection via 120C is provided in each of the pixels 541A, 541B, 541C, and 541D. For example, since the connection via 120C is filled with a part of the pad portion 120, the pad portion 120 and the floating diffusions FD1, FD2, FD3, and FD4 are electrically connected.

The pad portion 121 connects a plurality of the VSS contact regions 118 to each other. For example, the VSS contact regions 118 provided in the pixels 541C and 541D of one pixel sharing unit 539 and the VSS contact regions 118 provided in the pixels 541A and 541B of the other pixel sharing unit 539 are electrically connected by the pad portion 121, the pixel sharing units 539 being adjacent to each other in the V direction. The pad portion 121 is provided to cover the pixel separation portion 117, for example, and is disposed to overlap at least a part of each of four VSS contact regions 118. Specifically, the pad portion 121 is formed in a region overlapping at least a part of each of a plurality of the VSS contact regions 118 and at least a part of the pixel separation portion 117 formed between a plurality of the VSS contact regions 118 in a direction perpendicular to the front surface of the semiconductor layer 100S. The interlayer insulation film 119 is provided with a connection via 121C electrically connecting the pad portion 121 with the VSS contact region 118. The connection via 121C is provided in each of the pixels 541A, 541B, 541C, and 541D. For example, since the connection via 121C is filled with a part of the pad portion 121, the pad portion 121 and the VSS contact region 118 are electrically connected. For example, the pad portion 120 and the pad portion 121 of each of a plurality of the pixel sharing units 539 arranged in the V direction are disposed at substantially the same position in the H direction (FIG. 7B).

By providing the pad portion 120, it is possible to reduce the number of wirings for connection from each of the floating diffusions FD to the pixel circuit 210 (for example, the gate electrode of the amplification transistor AMP) in the entire chip. Similarly, by providing the pad portion 121, a wiring for supplying a potential to each of the VSS contact regions 118 can be reduced in the entire chip. As a result, it is possible to reduce an area of the entire chip, suppress electrical interference between the wirings in the miniaturized pixel, and/or reduce a cost by reducing the number of components.

The pad portions 120 and 121 can be provided at desired positions of the first substrate 100 and the second substrate 200. Specifically, the pad portions 120 and 121 can be provided in either the wiring layer 100T or an insulation region 212 of the semiconductor layer 200S. In a case of being provided in the wiring layer 100T, the pad portions 120 and 121 may be brought into direct contact with the semiconductor layer 100S. Specifically, the pad portions 120 and 121 may be directly connected to at least a part of each of the floating diffusions FD and/or the VSS contact regions 118. Furthermore, connection vias 120C and 121C may be provided from each of the floating diffusions FD and/or the VSS contact regions 118 connected to the pad portions 120 and 121, and the pad portions 120 and 121 may be provided at desired positions of the wiring layer 100T and the insulation region 212 of the semiconductor layer 200S.

In particular, in a case where the pad portions 120 and 121 are provided in the wiring layer 100T, it is possible to reduce the number of the wirings connected to the floating diffusion FD and/or the VSS contact region 118 in the insulation region 212 of the semiconductor layer 200S. Accordingly, in the second substrate 200 forming the pixel circuit 210, an area of the insulation region 212 for forming a through wiring for connecting from the floating diffusion FD to the pixel circuit 210 can be reduced. Therefore, it is possible to secure a large area of the second substrate 200 forming the pixel circuit 210. By securing the area of the pixel circuit 210, it is possible to form a large pixel transistor and contribute to improving image quality by reducing noise.

In particular, in a case where the FTI structure is used for the pixel separation portion 117, it is preferable to provide the floating diffusion FD and/or the VSS contact region 118 in each of the pixels 541. Therefore, by using the configurations of the pad portions 120 and 121, the number of the wirings connecting the first substrate 100 and the second substrate 200 can be greatly reduced.

Furthermore, as illustrated in FIG. 7B, for example, the pad portion 120 to which a plurality of the floating diffusions FD are connected and the pad portion 121 to which a plurality of the VSS contact regions 118 are connected are alternately arranged linearly in the V direction. Furthermore, the pad portions 120 and 121 are formed at positions surrounded by a plurality of the photodiodes PD, a plurality of the transfer gates TG, and a plurality of the floating diffusions FD. Accordingly, elements other than the floating diffusion FD and the VSS contact region 118 can be freely disposed in the first substrate 100 forming a plurality of elements, and efficiency of a layout of the entire chip can be improved. Furthermore, symmetry in the layout of the elements formed in each of the pixel sharing units 539 is secured, and variations in characteristics of each of the pixels 541 can be suppressed.

The pad portions 120 and 121 are formed of, for example, polysilicon (Poly Si), more specifically, doped polysilicon doped with impurities. The pad portions 120 and 121 are preferably formed of a conductive material having high heat resistance such as polysilicon, tungsten (W), titanium (Ti), and titanium nitride (TiN). Accordingly, the pixel circuit 210 can be formed after the semiconductor layer 200S of the second substrate 200 is bonded to the first substrate 100. Hereinafter, the reason will be described. Note that, in the following description, a method for forming the pixel circuit 210 after bonding the first substrate 100 to the semiconductor layer 200S of the second substrate 200 is referred to as a first manufacturing method.

Here, it is also conceivable to form the pixel circuit 210 in the second substrate 200 and then bond the pixel circuit 210 to the first substrate 100 (hereinafter, referred to as a second manufacturing method). In the second manufacturing method, an electrode for electrical connection is formed, in advance, on each of the front surface of the first substrate 100 (front surface of the wiring layer 100T) and the front surface of the second substrate 200 (front surface of the wiring layer 200T). When the first substrate 100 and the second substrate 200 are bonded to each other, at the same time, the electrodes for electrical connection, which are formed on the front surface of the first substrate 100 and the front surface of the second substrate 200, come into contact with each other. As a result, electrical connection is formed between the wiring included in the first substrate 100 and the wiring included in the second substrate 200. Therefore, by adopting the configuration of the imaging device 1 using the second manufacturing method, for example, the manufacturing can be performed by using an appropriate process according to the configuration of each of the first substrate 100 and the second substrate 200, and a high-quality and high-performance imaging device can be manufactured.

In the second manufacturing method, when the first substrate 100 and the second substrate 200 are bonded to each other, an error in alignment may occur due to a manufacturing apparatus for bonding. Furthermore, the first substrate 100 and the second substrate 200 have a size of, for example, about several tens of centimeters in diameter, but when the first substrate 100 and the second substrate 200 are bonded to each other, there is a possibility that an expansion and contraction of the substrates occurs in a microscopic region of respective portions of the first substrate 100 and the second substrate 200. This expansion and contraction of the substrates is caused due to a slight shift in timing of contacting between the substrates. Due to such expansion and contraction of the first substrate 100 and the second substrate 200, an error may occur in the position of the electrode for electrical connection formed on each of the front surface of the first substrate 100 and the front surface of the second substrate 200. In the second manufacturing method, even when such an error occurs, it is preferable to take measures so that the electrodes of each of the first substrate 100 and the second substrate 200 come into contact with each other. Specifically, at least one, preferably both of the electrodes of the first substrate 100 and the second substrate 200 are increased in size in consideration of the above described error. Therefore, when the second manufacturing method is used, for example, the size of the electrode formed on the front surface of the first substrate 100 or the second substrate 200 (size in a plane direction of the substrate) is larger than the size of an internal electrode extending from the inside of the first substrate 100 or the second substrate 200 to the front surface in the thickness direction.

On the other hand, since the pad portions 120 and 121 are formed of a heat resistant conductive material, the first manufacturing method can be used. In the first manufacturing method, after the first substrate 100 including the photodiode PD, the transfer transistor TR, and the like is formed, the first substrate 100 and the second substrate 200 (semiconductor layer 200S) are bonded to each other. At this time, the second substrate 200 is in a state in which a pattern such as an active element and a wiring layer constituting the pixel circuit 210 is not formed. Since the second substrate 200 is in a state before the pattern is formed, even when an error occurs in a bonding position when the first substrate 100 and the second substrate 200 are bonded to each other, this bonding error does not cause an error in alignment between the pattern of the first substrate 100 and the pattern of the second substrate 200. This is because the pattern of the second substrate 200 is formed after the first substrate 100 and the second substrate 200 are bonded to each other. Note that, when the pattern is formed in the second substrate, for example, in an exposure apparatus for forming a pattern, the pattern is formed while the pattern formed in the first substrate is set as an alignment target. For the above described reason, the error in the bonding position between the first substrate 100 and the second substrate 200 does not cause a problem in manufacturing the imaging device 1 in the first manufacturing method. For the same reason, an error caused by the expansion and contraction of the substrates, the expansion and contraction being caused in the second manufacturing method, does not cause a problem in manufacturing the imaging device 1 in the first manufacturing method.

In the first manufacturing method, after the first substrate 100 and the second substrate 200 (semiconductor layer 200S) are bonded to each other in this manner, the active element is formed in the second substrate 200. After that, the through electrodes 120E and 121E, and the through electrode TGV (FIG. 6) are formed. In forming the through electrodes 120E, 121E, and TGV, for example, a pattern of the through electrode is formed by reduction projection exposure of the exposure apparatus from above the second substrate 200. Since the reduction projection exposure is used, even when an error occurs in alignment between the second substrate 200 and the exposure apparatus, the magnitude of the error is only a fraction of the error (inverse number of the reduction projection exposure magnification) of the error of the second manufacturing method in the second substrate 200. Therefore, by adopting the configuration of the imaging device 1 using the first manufacturing method, it is easy to align the elements formed on each of the first substrate 100 and the second substrate 200, and it is possible to manufacture a high-quality and high-performance imaging device.

The imaging device 1 manufactured by using such a first manufacturing method has features different from those of the imaging device manufactured by the second manufacturing method. Specifically, in the imaging device 1 manufactured by the first manufacturing method, for example, the through electrodes 120E, 121E, and TGV have substantially constant thicknesses (sizes in a plane direction of the substrate) from the second substrate 200 to the first substrate 100. Alternatively, when the through electrodes 120E, 121E, and TGV have a tapered shape, the through electrodes 120E, 121E, and TGV have a tapered shape with a constant slope. In the imaging device 1 including the through electrodes 120E, 121E, and TGV, the pixel 541 is easy to miniaturize.

Here, when the imaging device 1 is manufactured by the first manufacturing method, since the active element is formed in the second substrate 200 after the first substrate 100 and the second substrate 200 (semiconductor layer 200S) are bonded to each other, the first substrate 100 is also affected by the heating treatment necessary for forming the active element. Therefore, as described above, it is preferable to use a conductive material having high heat resistance for the pad portions 120 and 121 provided in the first substrate 100. For example, the pad portions 120 and 121 are preferably formed of a material having a melting point higher (that is, having higher heat resistance) than at least a part of the wiring material included in the wiring layer 200T of the second substrate 200. For example, a conductive material having high heat resistance such as doped polysilicon, tungsten, titanium, or titanium nitride is used for the pad portions 120 and 121. Accordingly, the imaging device 1 can be manufactured by using the first manufacturing method.

For example, the passivation film 122 is provided over the entire front surface of the semiconductor layer 100S so as to cover the pad portions 120 and 121 (FIG. 6). The passivation film 122 is configured by, for example, a silicon nitride (SiN) film. The interlayer insulation film 123 covers the pad portions 120 and 121 with the passivation film 122 interposed therebetween. The interlayer insulation film 123 is provided, for example, over the entire front surface of the semiconductor layer 100S. The interlayer insulation film 123 is configured by, for example, a silicon oxide (SiO) film. The bonding film 124 is provided on a bonding surface between the first substrate 100 (specifically, the wiring layer 100T) and the second substrate 200. That is, the bonding film 124 is in contact with the second substrate 200. The bonding film 124 is provided over the entire main surface of the first substrate 100. The bonding film 124 is configured by, for example, a silicon nitride film.

The light receiving lens 401 faces the semiconductor layer 100S, for example, with the fixed electric charge film 112 and the insulation film 111 interposed therebetween (FIG. 6). The light receiving lens 401 is provided, for example, at a position facing the photodiode PD of each of the pixels 541A, 541B, 541C, and 541D.

The second substrate 200 includes the semiconductor layer 200S and the wiring layer 200T in this order from the first substrate 100 side. The semiconductor layer 200S is formed by the silicon substrate. In the semiconductor layer 200S, a well region 211 is provided in the thickness direction. The well region 211 is, for example, the p-type semiconductor region. The second substrate 200 is provided with the pixel circuit 210 disposed for each of the pixel sharing units 539. The pixel circuit 210 is provided, for example, on the front surface side (wiring layer 200T side) of the semiconductor layer 200S. In the imaging device 1, the second substrate 200 is bonded to the first substrate 100 so that the rear surface side (semiconductor layer 200S side) of the second substrate 200 faces the front surface side (wiring layer 100T side) of the first substrate 100. That is, the second substrate 200 is bonded to the first substrate 100 in a face-to-back manner.

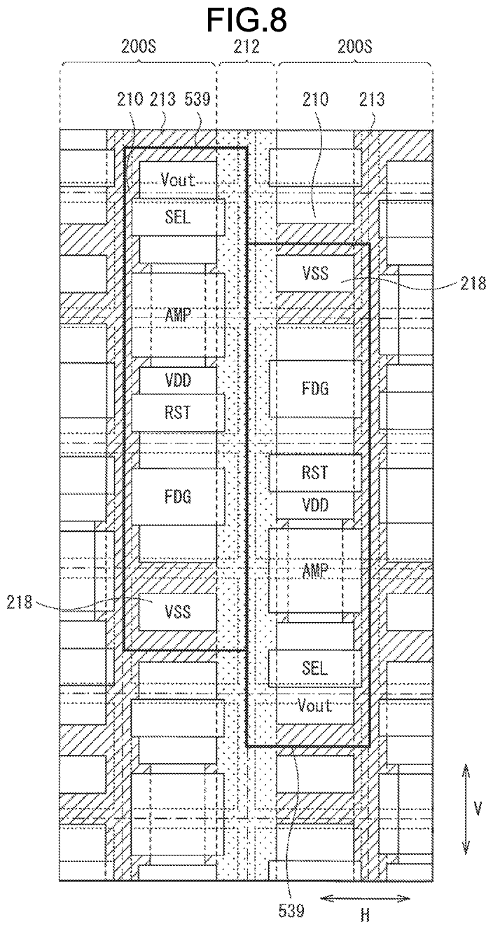

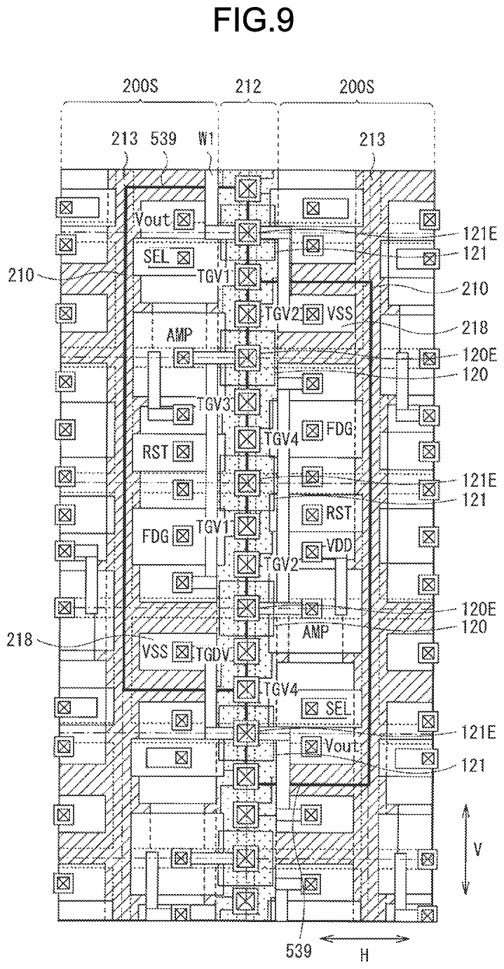

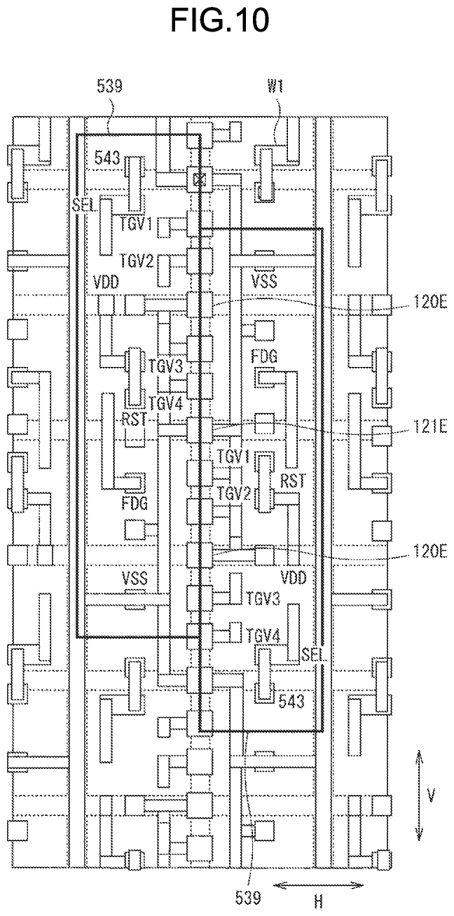

FIGS. 8 to 12 schematically illustrate an example of a plane configuration of the second substrate 200. FIG. 8 illustrates a configuration of the pixel circuit 210 provided in the vicinity of the front surface of the semiconductor layer 200S. FIG. 9 schematically illustrates a configuration of each part of the wiring layer 200T (specifically, a first wiring layer W1 to be described later), the semiconductor layer 200S connected to the wiring layer 200T, and the first substrate 100. FIGS. 10 to 12 illustrate an example of a plane configuration of the wiring layer 200T. Hereinafter, a configuration of the second substrate 200 will be described with reference to FIGS. 8 to 12 together with FIG. 6. In FIGS. 8 and 9, an outer shape of the photodiode PD (boundary between the pixel separation portion 117 and the photodiode PD) is indicated by a broken line, and a boundary between the semiconductor layer 200S and an element separation region 213 or an insulation region 212 in a portion overlapping the gate electrode of each transistor constituting the pixel circuit 210 is indicated by a dotted line. In a portion overlapping the gate electrode of the amplification transistor AMP, a boundary between the semiconductor layer 200S and the element separation region 213 and a boundary between the element separation region 213 and the insulation region 212 are provided on one side in a channel width direction.

The second substrate 200 is provided with the insulation region 212 that divides the semiconductor layer 200S and the element separation region 213 provided in a part of the semiconductor layer 200S in the thickness direction (FIG. 6). For example, the through electrodes 120E and 121E and the through electrodes TGV (through electrodes TGV1, TGV2, TGV3, and TGV4) of two pixel sharing units 539 connected to two pixel circuits 210 are disposed in the insulation region 212 provided between two pixel circuits 210 adjacent in the H direction (FIG. 9).

The insulation region 212 has substantially the same thickness as the thickness of the semiconductor layer 200S (FIG. 6). The semiconductor layer 200S is divided by the insulation region 212. The through electrodes 120E and 121E and the through electrode TGV are disposed in the insulation region 212. The insulation region 212 is formed of, for example, silicon oxide.

The through electrodes 120E and 121E are provided to penetrate the insulation region 212 in the thickness direction. Upper ends of the through electrodes 120E and 121E are connected to wirings (first wiring W1, second wiring W2, third wiring W3, and fourth wiring W4 to be described later) of the wiring layer 200T. The through electrodes 120E and 121E are provided to penetrate the insulation region 212, the bonding film 124, the interlayer insulation film 123, and the passivation film 122, and lower ends thereof are connected to the pad portions 120 and 121 (FIG. 6). The through electrode 120E electrically connects the pad portion 120 with the pixel circuit 210. That is, the floating diffusion FD of the first substrate 100 is electrically connected to the pixel circuit 210 of the second substrate 200 by the through electrode 120E. The through electrode 121E electrically connects the pad portion 121 with the reference potential line VSS of the wiring layer 200T. That is, the VSS contact region 118 of the first substrate 100 is electrically connected to the reference potential line VSS of the second substrate 200 by the through electrode 121E.

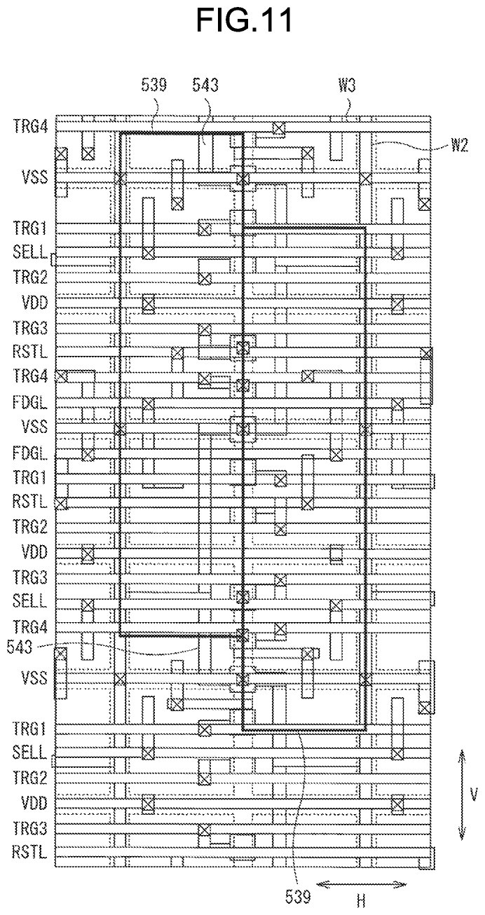

The through electrode TGV is provided to penetrate the insulation region 212 in the thickness direction. An upper end of the through electrode TGV is connected to the wiring of the wiring layer 200T. The through electrode TGV is provided to penetrate the insulation region 212, the bonding film 124, the interlayer insulation film 123, the passivation film 122, and the interlayer insulation film 119, and a lower end thereof is connected to the transfer gate TG (FIG. 6). The through electrode TGV electrically connects the transfer gate TG (transfer gate TG1, TG2, TG3, or TG4) of each of the pixels 541A, 541B, 541C, and 541D to the wirings (a part of the row drive signal lines 542, specifically, wirings TRG1, TRG2, TRG3, and TRG4 in FIG. 11 to be described later) of the wiring layer 200T. That is, the transfer gate TG of the first substrate 100 is electrically connected to the wiring TRG of the second substrate 200 by the through electrode TGV, and a drive signal is sent to each of the transfer transistors TR (transfer transistors TR1, TR2, TR3, and TR4).

The insulation region 212 is a region for insulating the through electrodes 120E and 121E, and the through electrode TGV for electrically connecting the first substrate 100 to the second substrate 200 from the semiconductor layer 200S. For example, the through electrodes 120E and 121E, and the through electrodes TGV (through electrodes TGV1, TGV2, TGV3, and TGV4) connected to two pixel circuits 210 are disposed in the insulation region 212 provided between two pixel circuits 210 (pixel sharing units 539) adjacent in the H direction. The insulation region 212 is provided, for example, to extend in the V direction (FIGS. 8 and 9). Here, by devising the arrangement of the horizontal portion TGb of the transfer gate TG, the horizontal portion TGb is disposed so that a position of the through electrode TGV in the H direction is close to a position of the through electrodes 120E and 121E in the H direction as compared with a position of the vertical portion TGa (FIGS. 7A and 9). For example, the through electrode TGV is disposed at substantially the same position as the through electrodes 120E and 120E in the H direction. As a result, the through electrodes 120E and 121E, and the through electrode TGV can be collectively provided in the insulation region 212 extending in the V direction. As another arrangement example, it is also conceivable to provide the horizontal portion TGb only in a region overlapping the vertical portion TGa. In this case, the through electrode TGV is formed substantially immediately above the vertical portion TGa, and for example, the through electrode TGV is disposed substantially at the center portion of each of the pixels 541 in the H direction and the V direction. At this time, the position of the through electrode TGV in the H direction greatly deviates from the positions of the through electrodes 120E and 121E in the H direction. For example, an insulation region 212 is provided around the through electrode TGV, and the through electrodes 120E and 121E in order to electrically insulate the through electrode TGV, and the through electrodes 120E and 121E from the adjacent semiconductor layer 200S. In a case where the position of the through electrode TGV in the H direction and the positions of the through electrodes 120E and 121E in the H direction are greatly separated from each other, it is necessary to provide the insulation region 212 independently around each of the through electrodes 120E, 121E, and TGV. As a result, the semiconductor layer 200S is finely divided. In the comparison with this, the layout in which the through electrodes 120E and 121E, and the through electrode TGV are collectively disposed in the insulation region 212 extending in the V direction can increase the size of the semiconductor layer 200S in the H direction. Therefore, a large area of a semiconductor element formation region in the semiconductor layer 200S can be secured. Accordingly, for example, the size of the amplification transistor AMP can be increased, and noise can be suppressed.

As described with reference to FIG. 4, the pixel sharing unit 539 has a structure in which the floating diffusions FD respectively provided in a plurality of the pixels 541 are electrically connected to each other, and a plurality of the pixels 541 share one pixel circuit 210. The floating diffusions FD are electrically connected to each other by the pad portion 120 provided in the first substrate 100 (FIGS. 6 and 7B). The electrical connection portion (pad portion 120) provided in the first substrate 100 and the pixel circuit 210 provided in the second substrate 200 are electrically connected via one through electrode 120E. As another structure example, it is also conceivable to provide the electrical connection portion between the floating diffusions FD in the second substrate 200. In this case, the pixel sharing unit 539 is provided with four through electrodes connected to the floating diffusions FD1, FD2, FD3, and FD4, respectively. Therefore, in the second substrate 200, the number of through electrodes penetrating the semiconductor layer 200S increases, and the insulation region 212 insulating a periphery of these through electrodes increases. In comparison with this, in the structure in which the pad portion 120 is provided in the first substrate 100 (FIGS. 6 and 7B), the number of the through electrodes can be reduced, and the insulation region 212 can be reduced. Therefore, a large area of a semiconductor element formation region in the semiconductor layer 200S can be secured. Accordingly, for example, the size of the amplification transistor AMP can be increased, and noise can be suppressed.

The element separation region 213 is provided on the front surface side of the semiconductor layer 200S. The element separation region 213 has a shallow trench isolation (STI) structure. In the element separation region 213, the semiconductor layer 200S is dug in the thickness direction (direction perpendicular to the main surface of the second substrate 200), and the dug portion is filled with an insulation film. The insulation film is formed of, for example, silicon oxide. The element separation region 213 separates a plurality of the transistors constituting the pixel circuit 210 from each other in accordance with the layout of the pixel circuit 210. The semiconductor layer 200S (specifically, the well region 211) extends below the element separation region 213 (deep portion of the semiconductor layer 200S).

Here, with reference to FIGS. 7A, 7B, and 8, a difference between the outer shape (outer shape in the plane direction of the substrate) of the pixel sharing unit 539 in the first substrate 100 and the outer shape of the pixel sharing unit 539 in the second substrate 200 will be described.

In the imaging device 1, the pixel sharing unit 539 is provided over both the first substrate 100 and the second substrate 200. For example, the outer shape of the pixel sharing unit 539 provided in the first substrate 100 is different from the outer shape of the pixel sharing unit 539 provided in the second substrate 200.

In FIGS. 7A and 7B, outlines of the pixels 541A, 541B, 541C, and 541D are indicated by a one-dot chain line, and the outer shape of the pixel sharing unit 539 is indicated by a thick line. For example, the pixel sharing unit 539 of the first substrate 100 includes two pixels 541 (pixels 541A and 541B) disposed adjacent to each other in the H direction and two pixels 541 (pixels 541C and 541D) disposed adjacent to each other in the V direction. That is, the pixel sharing unit 539 of the first substrate 100 includes four pixels 541 adjacent to each other and formed in two rows×two columns, and the pixel sharing unit 539 of the first substrate 100 has a substantially square outer shape. In the pixel array unit 540, such pixel sharing units 539 are disposed adjacent to each other at a two-pixel pitch (pitch corresponding to two pixels 541) in the H direction and a two-pixel pitch (pitch corresponding to two pixels 541) in the V direction.

In FIGS. 8 and 9, outlines of the pixels 541A, 541B, 541C, and 541D are indicated by a one-dot chain line, and the outer shape of the pixel sharing unit 539 is indicated by a thick line. For example, the outer shape of the pixel sharing unit 539 of the second substrate 200 is smaller than the pixel sharing unit 539 of the first substrate 100 in the H direction, and larger than the pixel sharing unit 539 of the first substrate 100 in the V direction. For example, the pixel sharing unit 539 of the second substrate 200 is formed in a size (region) corresponding to one pixel in the H direction, and is formed in a size corresponding to four pixels in the V direction. That is, the pixel sharing unit 539 of the second substrate 200 is formed in a size corresponding to the pixels arranged to be adjacent to each other and in one row×four columns, and the pixel sharing unit 539 of the second substrate 200 has a substantially rectangular outer shape.

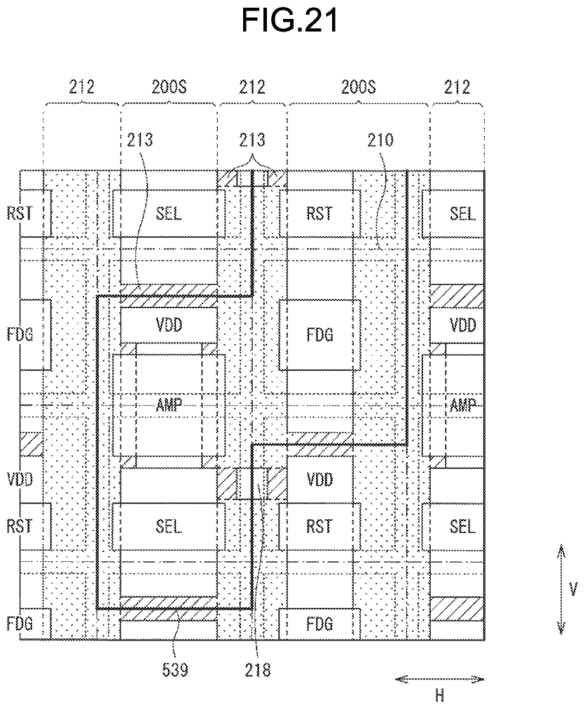

For example, on each of the pixel circuits 210, the selection transistor SEL, the amplification transistor AMP, the reset transistor RST, and the FD conversion gain switching transistor FDG are arranged in this order in the V direction (FIG. 8). By forming the outer shape of each of the pixel circuits 210 in a substantially rectangular shape as described above, four transistors (selection transistor SEL, amplification transistor AMP, reset transistor RST, the FD conversion gain switching transistor FDG) can be disposed side by side in one direction (V direction in FIG. 8). As a result, the drain of the amplification transistor AMP and the drain of the reset transistor RST can be shared in one diffusion region (diffusion region connected to the power supply line VDD). For example, the region of each of the pixel circuits 210 can be formed in a substantially square shape (refer to FIG. 21 to be described later). In this case, two transistors are disposed in one direction, and it is difficult to share the drain of the amplification transistor AMP and the drain of the reset transistor RST in one diffusion region. Therefore, by forming the region of the pixel circuit 210 in a substantially rectangular shape, four transistors can be easily disposed close to each other, and the formation region of the pixel circuit 210 can be reduced. That is, the pixel can be miniaturized. Furthermore, when it is unnecessary to reduce the formation region of the pixel circuit 210, the formation region of the amplification transistor AMP can be increased to suppress noise.

For example, in the vicinity of the front surface of the semiconductor layer 200S, a VSS contact region 218 connected to the reference potential line VSS is provided in addition to the selection transistor SEL, the amplification transistor AMP, the reset transistor RST, and the FD conversion gain switching transistor FDG. The VSS contact region 218 is configured by, for example, the p-type semiconductor region. The VSS contact region 218 is electrically connected to the VSS contact region 118 of the first substrate 100 (semiconductor layer 100S) via the wiring of the wiring layer 200T and the through electrode 121E. The VSS contact region 218 is provided, for example, at a position adjacent to the source of the FD conversion gain switching transistor FDG with the element separation region 213 interposed therebetween (FIG. 8).

Next, a positional relationship between the pixel sharing unit 539 provided in the first substrate 100 and the pixel sharing unit 539 provided in the second substrate 200 will be described with reference to FIGS. 7B and 8. For example, one (for example, an upper side of the paper of FIG. 7B) of two pixel sharing units 539 arranged in the V direction of the first substrate 100 is connected to one (for example, a left side of the paper of FIG. 8) of two pixel sharing units 539 arranged in the H direction of the second substrate 200. For example, the other (for example, a lower side of the paper of FIG. 7B) of two pixel sharing units 539 arranged in the V direction of the first substrate 100 is connected to the other (for example, a right side of the paper of FIG. 8) of two pixel sharing units 539 arranged in the H direction of the second substrate 200.

For example, in two pixel sharing units 539 arranged in the H direction of the second substrate 200, an internal layout (arrangement of transistors and the like) of one pixel sharing unit 539 is substantially equal to a layout obtained by inverting the internal layout of the other pixel sharing unit 539 in the V direction and the H direction. Hereinafter, effects obtained by this layout will be described.

In two pixel sharing units 539 arranged in the V direction of the first substrate 100, each of the pad portions 120 is disposed at the center portion of the outer shape of each of the pixel sharing units 539, that is, at the center portion of the pixel sharing unit 539 in the V direction and the H direction (FIG. 7B). On the other hand, since the pixel sharing unit 539 of the second substrate 200 has a substantially rectangular outer shape long in the V direction as described above, for example, the amplification transistor AMP connected to the pad portion 120 is disposed at a position deviated upward in the paper of drawing from the center of the pixel sharing unit 539 in the V direction. For example, when the internal layouts of two pixel sharing units 539 arranged in the H direction of the second substrate 200 are the same, a distance between the amplification transistor AMP of one pixel sharing unit 539 and the pad portion 120 (for example, the pad portion 120 of the pixel sharing unit 539 on the upper side of the paper of FIG. 7B) becomes relatively short. However, the distance between the amplification transistor AMP of the other pixel sharing unit 539 and the pad portion 120 (for example, the pad portion 120 of the pixel sharing unit 539 on the lower side of the paper of FIG. 7) becomes long. For this reason, an area of the wiring required for connecting the amplification transistor AMP with the pad portion 120 increases, and a wiring layout of the pixel sharing unit 539 may become complicated. This may give an influence to miniaturization of the imaging device 1.

On the other hand, by inverting the internal layouts of two pixel sharing units 539 arranged in the H direction of the second substrate 200 at least in the V direction, the distances between the amplification transistor AMP and the pad portion 120 of both of two pixel sharing units 539 can be shortened. Therefore, it is easy to miniaturize the imaging device 1 as compared with a configuration in which the internal layouts of two pixel sharing units 539 arranged in the H direction of the second substrate 200 are the same. Note that, a plane layout of each of a plurality of the pixel sharing units 539 of the second substrate 200 is bilaterally symmetrical in a range illustrated in FIG. 8, but is bilaterally asymmetrical when including a layout of the first wiring layer W1 illustrated in FIG. 9 to be described later.

Furthermore, it is preferable that the internal layouts of two pixel sharing units 539 arranged in the H direction of the second substrate 200 are also inverted in the H direction. Hereinafter, the reason will be described. As illustrated in FIG. 9, each of two pixel sharing units 539 arranged in the H direction of the second substrate 200 is connected to the pad portions 120 and 121 of the first substrate 100. For example, the pad portions 120 and 121 are disposed at the center portion of two pixel sharing units 539 arranged in the H direction of the second substrate 200 in the H direction (between two pixel sharing units 539 arranged in the H direction). Therefore, it is possible to reduce the distance between each of a plurality of the pixel sharing units 539 of the second substrate 200, and the pad portions 120 and 121 by inverting the internal layouts of two pixel sharing units 539 arranged in the H direction of the second substrate 200 in the H direction. That is, it is easier to miniaturize the imaging device 1.

Furthermore, the position of the outline of the pixel sharing unit 539 of the second substrate 200 may not be aligned with the position of any one of the outlines of the pixel sharing units 539 of the first substrate 100. For example, in one pixel sharing unit 539 (for example, a left side of the paper of FIG. 9) of two pixel sharing units 539 arranged in the H direction of the second substrate 200, the outline of the one pixel sharing unit 539 in the V direction (for example, an upper side of the paper of FIG. 9) is disposed outside the outline of one pixel sharing unit 539 of the pixel sharing units 539 in the V direction (for example, an upper side of the paper of FIG. 7B) of the corresponding first substrate 100. Furthermore, in the other pixel sharing unit 539 (for example, a right side of the paper of FIG. 9) of two pixel sharing units 539 arranged in the H direction of the second substrate 200, the outline of the other pixel sharing unit 539 in the V direction (for example, a lower side of the paper of FIG. 9) is disposed outside the outline of the other pixel sharing unit 539 of the pixel sharing units 539 in the V direction (for example, a lower side of the paper of FIG. 7B) of the corresponding first substrate 100. As described above, by disposing the pixel sharing unit 539 of the second substrate 200 and the pixel sharing unit 539 of the first substrate 100 to each other, the distance between the amplification transistor AMP and the pad portion 120 can be shortened. Therefore, it is easy to miniaturize the imaging device 1.

Furthermore, the positions of the outlines of a plurality of the pixel sharing units 539 of the second substrate 200 may not be aligned. For example, two pixel sharing units 539 arranged in the H direction of the second substrate 200 are disposed so that the positions of the outlines in the V direction are deviated. As a result, the distance between the amplification transistor AMP and the pad portion 120 can be shortened. Therefore, it is easy to miniaturize the imaging device 1.

A repeated arrangement of the pixel sharing units 539 in the pixel array unit 540 will be described with reference to FIGS. 7B and 9. The pixel sharing unit 539 of the first substrate 100 has the size formed by two pixels 541 in the H direction and the size formed by two pixels 541 in the V direction (FIG. 7B). For example, in the pixel array unit 540 of the first substrate 100, the pixel sharing unit 539 having the size corresponding to four pixels 541 is repeatedly arranged adjacent to each other at a two-pixel pitch in the H direction (pitch corresponding to two pixels 541) and at two-pixel pitch in the V direction (pitch corresponding to two pixels 541). Alternatively, the pixel array unit 540 of the first substrate 100 may be provided with a pair of the pixel sharing units 539 formed by disposing two pixel sharing units 539 to be adjacent to each other in the V direction. In the pixel array unit 540 of the first substrate 100, for example, a pair of the pixel sharing units 539 is repeatedly arranged adjacent to each other at a two-pixel pitch in the H direction (pitch corresponding to two pixels 541) and at a four-pixel pitch in the V direction (pitch corresponding to four pixels 541). The pixel sharing unit 539 of the second substrate 200 has the size formed by one pixel 541 in the H direction and the size formed by four pixels 541 in the V direction (FIG. 9). For example, the pixel array unit 540 of the second substrate 200 is provided with a pair of the pixel sharing units 539 including two pixel sharing units 539 having a size corresponding to four pixels 541. The pixel sharing units 539 are disposed adjacent to each other in the H direction, and are disposed to be shifted in the V direction. In the pixel array unit 540 of the second substrate 200, for example, a pair of the pixel sharing units 539 is repeatedly arranged adjacent to each other without a gap at a two-pixel pitch in the H direction (pitch corresponding to two pixels 541) and at a four-pixel pitch in the V direction (pitch corresponding to four pixels 541). Such a repeated arrangement of the pixel sharing units 539 enables the pixel sharing units 539 to be disposed without a gap. Therefore, it is easy to miniaturize the imaging device 1.

The amplification transistor AMP preferably has, for example, a fin type three-dimensional structure (FIG. 6). Accordingly, an effective gate width is increased, and noise can be suppressed. The selection transistor SEL, the reset transistor RST, and the FD conversion gain switching transistor FDG have, for example, a planar structure. The amplification transistor AMP may have the planar structure. Alternatively, the selection transistor SEL, the reset transistor RST, or the FD conversion gain switching transistor FDG may have a three-dimensional structure.

The wiring layer 200T includes, for example, a passivation film 221, an interlayer insulation film 222, and a plurality of wirings (first wiring layer W1, second wiring layer W2, third wiring layer W3, and fourth wiring layer W4). The passivation film 221 is, for example, in contact with the front surface of the semiconductor layer 200S and covers the entire front surface of the semiconductor layer 200S. The passivation film 221 covers the gate electrode of each of the selection transistor SEL, the amplification transistor AMP, the reset transistor RST, and the FD conversion gain switching transistor FDG. The interlayer insulation film 222 is provided between the passivation film 221 and the third substrate 300. A plurality of the wirings (first wiring layer W1, second wiring layer W2, third wiring layer W3, and fourth wiring layer W4) are separated by the interlayer insulation film 222. The interlayer insulation film 222 is formed of, for example, silicon oxide.

In the wiring layer 200T, for example, the first wiring layer W1, the second wiring layer W2, the third wiring layer W3, the fourth wiring layer W4, and the contact portions 201 and 202 are provided in this order from the semiconductor layer 200S side, and are insulated from each other by the interlayer insulation film 222. The interlayer insulation film 222 is provided with a plurality of connection portions that connect the first wiring layer W1, the second wiring layer W2, the third wiring layer W3, or the fourth wiring layer W4 with lower layers thereof. Each of the connection portions is a portion in which a connection hole provided in the interlayer insulation film 222 is filled with a conductive material. For example, the interlayer insulation film 222 is provided with a connection portion 218V that connects the first wiring layer W1 and the VSS contact region 218 of the semiconductor layer 200S. For example, a hole diameter of the connection portion connecting the elements of the second substrate 200 is different from hole diameters of the through electrodes 120E and 121E, and the through electrode TGV. Specifically, the hole diameter of the connection hole connecting the elements of the second substrate 200 is preferably smaller than the hole diameters of the through electrodes 120E and 121E, and the through electrode TGV. Hereinafter, the reason will be described. A depth of the connection portion (connection portion 218V or the like) provided in the wiring layer 200T is smaller than depths of the through electrodes 120E and 121E, and the through electrode TGV. Therefore, in the connection portion, the connection hole can be easily filled with the conductive material as compared with the through electrodes 120E and 121E, and the through electrode TGV. By making the hole diameter of the connection portion smaller than the hole diameters of the through electrodes 120E and 121E, and the through electrode TGV, it is easy to miniaturize the imaging device 1.

For example, the through electrode 120E is connected to the gate of the amplification transistor AMP and the source of the FD conversion gain switching transistor FDG (specifically, a connection hole reaching the source of the FD conversion gain switching transistor FDG) by the first wiring layer W1. Since the first wiring layer W1 connects, for example, the through electrode 121E with the connection portion 218V, the VSS contact region 218 of the semiconductor layer 200S and the VSS contact region 118 of the semiconductor layer 100S are electrically connected.

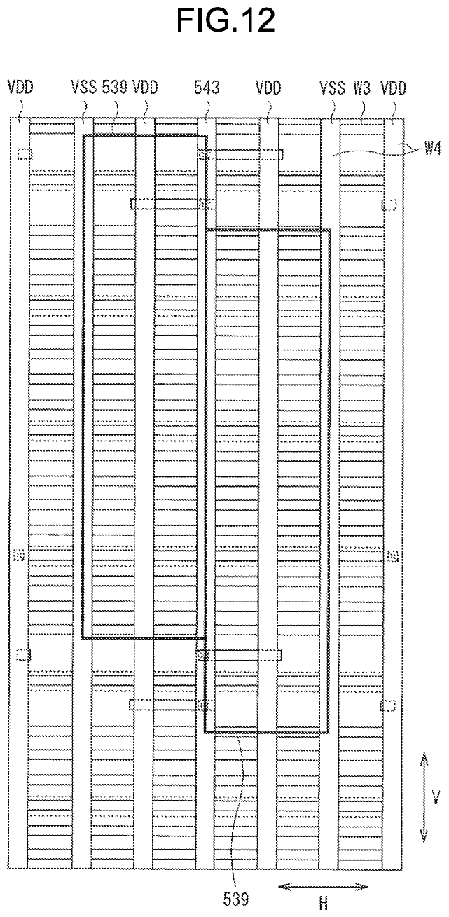

Next, a plane configuration of the wiring layer 200T will be described with reference to FIGS. 10 to 12. FIG. 10 illustrates an example of a plane configuration of the first wiring layer W1 and the second wiring layer W2. FIG. 11 illustrates an example of a plane configuration of the second wiring layer W2 and the third wiring layer W3. FIG. 12 illustrates an example of a plane configuration of the third wiring layer W3 and the fourth wiring layer W4.

For example, the third wiring layer W3 includes wirings TRG1, TRG2, TRG3, TRG4, SELL, RSTL, and FDGL extending in the H direction (row direction) (FIG. 11). These wirings correspond to a plurality of the row drive signal lines 542 described with reference to FIG. 4. The wirings TRG1, TRG2, TRG3, and TRG4 are for sending a drive signal to the transfer gates TG1, TG2, TG3, and TG4, respectively. The wirings TRG1, TRG2, TRG3, and TRG4 are connected to the transfer gates TG1, TG2, TG3, and TG4, respectively via the second wiring layer W2, the first wiring layer W1, and the through electrode 120E. The wiring SELL is for sending a drive signal to the gate of the selection transistor SEL, the wiring RSTL is for sending a drive signal to the gate of the reset transistor RST, and the wiring FDGL is for sending a drive signal to the gate of the FD conversion gain switching transistor FDG. The wirings SELL, RSTL, and FDGL are connected to the gates of the selection transistor SEL, the reset transistor RST, and the FD conversion gain switching transistor FDG, respectively via the second wiring layer W2, the first wiring layer W1, and the connection portion.

For example, the fourth wiring layer W4 includes the power supply line VDD, the reference potential line VSS, and the vertical signal line 543, which extend in the V direction (column direction) (FIG. 12). The power supply line VDD is connected to the drain of the amplification transistor AMP and the drain of the reset transistor RST via the third wiring layer W3, the second wiring layer W2, the first wiring layer W1, and the connection portion. The reference potential line VSS is connected to the VSS contact region 218 via the third wiring layer W3, the second wiring layer W2, the first wiring layer W1, and the connection portion 218V. Furthermore, the reference potential line VSS is connected to the VSS contact region 118 of the first substrate 100 via the third wiring layer W3, the second wiring layer W2, the first wiring layer W1, the through electrode 121E, and the pad portion 121. The vertical signal line 543 is connected to the source (Vout) of the selection transistor SEL via the third wiring layer W3, the second wiring layer W2, the first wiring layer W1, and the connection portion.

The contact portions 201 and 202 may be provided at a position overlapping the pixel array unit 540 in a plan view (for example, FIG. 3), or may be provided in the peripheral portion 540B outside the pixel array unit 540 (for example, FIG. 6). The contact portions 201 and 202 are provided on the front surface of the second substrate 200 (surface on the wiring layer 200T side). The contact portions 201 and 202 are formed of, for example, metal such as copper (Cu) and aluminum (Al). The contact portions 201 and 202 are exposed to the front surface of the wiring layer 200T (surface on the third substrate 300 side). The contact portions 201 and 202 are used for electrical connection between the second substrate 200 and the third substrate 300 and bonding between the second substrate 200 and the third substrate 300.

FIG. 6 illustrates an example in which a peripheral circuit is provided in the peripheral portion 540B of the second substrate 200. This peripheral circuit may include a part of the row drive unit 520, or a part of the column signal processing unit 550. Furthermore, as illustrated in FIG. 3, the peripheral circuit may not be disposed in the peripheral portion 540B of the second substrate 200, and the connection holes H1 and H2 may be disposed in the vicinity of the pixel array unit 540.

The third substrate 300 includes, for example, the wiring layer 300T and the semiconductor layer 300S in this order from the second substrate 200 side. For example, the front surface of the semiconductor layer 300S is provided on the second substrate 200 side. The semiconductor layer 300S is formed by the silicon substrate. A circuit is provided in a portion on the front surface side of the semiconductor layer 300S. Specifically, for example, at least some of the input unit 510A, the row drive unit 520, the timing control unit 530, the column signal processing unit 550, the image signal processing unit 560, and the output unit 510B are provided in a portion on the front surface side of the semiconductor layer 300S. The wiring layer 300T provided between the semiconductor layer 300S and the second substrate 200 includes, for example, the interlayer insulation film, a plurality of the wiring layers separated by the interlayer insulation film, and the contact portions 301 and 302. The contact portions 301 and 302 are exposed on a front surface (surface on the second substrate 200 side) of the wiring layer 300T, the contact portion 301 is in contact with the contact portion 201 of the second substrate 200, and the contact portion 302 is in contact with the contact portion 202 of the second substrate 200. The contact portions 301 and 302 are electrically connected to a circuit (for example, at least one of the input unit 510A, the row drive unit 520, the timing control unit 530, the column signal processing unit 550, the image signal processing unit 560, and the output unit 510B) formed in the semiconductor layer 300S. The contact portions 301 and 302 are formed of, for example, metal such as copper (Cu) and aluminum (Al). For example, an external terminal TA is connected to the input unit 510A via the connection hole H1, and an external terminal TB is connected to the output unit 510B via the connection hole H2.

Here, features of the imaging device 1 will be described.

In general, an imaging device mainly includes a photodiode and a pixel circuit. Here, when an area of the photodiode is increased, the electric charge generated as a result of the photoelectric conversion increases, and as a result, a signal/noise ratio (S/N ratio) of the pixel signal is improved, and the imaging device can output better image data (image information). On the other hand, when the size of the transistor (particularly, the size of the amplification transistor) included in the pixel circuit is increased, noise generated in the pixel circuit is reduced, and as a result, an S/N ratio of an imaging signal is improved, and the imaging device can output better image data (image information).

However, in the imaging device in which the photodiode and the pixel circuit are provided on the same semiconductor substrate, when the area of the photodiode is increased in a limited area of the semiconductor substrate, the size of the transistor included in the pixel circuit may be reduced. Furthermore, when the size of the transistor included in the pixel circuit is increased, the area of the photodiode may be reduced.

In order to solve these problems, for example, the imaging device 1 of the embodiment uses a structure in which a plurality of the pixels 541 share one pixel circuit 210, and the shared pixel circuit 210 is disposed to overlap the photodiode PD. As a result, it is possible to realize making the area of the photodiode PD as large as possible and making the size of the transistor included in the pixel circuit 210 as large as possible in the limited area of the semiconductor substrate. Accordingly, the S/N ratio of the pixel signal can be improved, and the imaging device 1 can output better image data (image information).

When a structure is realized in which a plurality of the pixels 541 share one pixel circuit 210 and the shared pixel circuit 210 is disposed to overlap the photodiode PD, a plurality of the wirings connected to one pixel circuit 210 extend from the floating diffusion FD of each of a plurality of the pixels 541. In order to secure a large area of the semiconductor substrate 200 forming the pixel circuit 210, for example, a connection wiring can be formed in which a plurality of the extending wirings are connected to each other and integrated into one. Similarly, for a plurality of the wirings extending from the VSS contact region 118, it is possible to connect a plurality of the extending wirings to each other and form the connection wiring to be integrated into one.

For example, when the connection wiring that mutually connects a plurality of the wirings extending from the floating diffusion FD of each of a plurality of the pixels 541 is formed in the semiconductor substrate 200 forming the pixel circuit 210, it is conceivable that an area for forming the transistor included in the pixel circuit 210 is reduced. Similarly, when the connection wiring that mutually connects a plurality of the wirings extending from the VSS contact region 118 of each of a plurality of the pixels 541 and integrates the wirings into one is formed in the semiconductor substrate 200 forming the pixel circuit 210, it is conceivable that the area for forming the transistor included in the pixel circuit 210 is reduced.

In order to solve these problems, for example, the imaging device 1 of the embodiment can have a structure in which a plurality of the pixels 541 share one pixel circuit 210, and the shared pixel circuit 210 is disposed to overlap the photodiode PD, the structure in which the first substrate 100 is provided with the connection wiring that mutually connects the floating diffusions FD of each of a plurality of the pixels 541 and integrates the floating diffusions FD into one, and the connection wiring that mutually connects the VSS contact regions 118 included in each of a plurality of the pixels 541 and integrates the VSS contact regions 118 into one.

Here, when the second manufacturing method described above is used as a manufacturing method for providing, in the first substrate 100, the connection wiring that mutually connects the floating diffusions FD of each of a plurality of the pixels 541 and integrates the floating diffusion FD into one and the connection wiring that mutually connects the VSS contact regions 118 of each of a plurality of the pixels 541 and integrates the VSS contact regions 118 into one, for example, it is possible to manufacture a high-quality and high-performance imaging device by using appropriate processes according to the configuration of each of the first substrate 100 and the second substrate 200. Furthermore, the connection wiring of the first substrate 100 and the second substrate 200 can be formed by an easy process. Specifically, in a case of using the second manufacturing method described above, electrodes connected to the floating diffusions FD and electrodes connected to the VSS contact regions 118 are provided on the front surface of the first substrate 100 and the front surface of the second substrate 200, respectively, which are the bonding boundary surfaces of the first substrate 100 and the second substrate 200. Moreover, when the first substrate 100 and the second substrate 200 are bonded to each other, it is preferable to increase the size of the electrodes formed on two substrate front surfaces so that the electrodes formed on two substrate front surfaces come into contact with each other even when the positional deviation occurs between the electrodes provided on two substrate front surfaces. In this case, it is conceivable that it becomes difficult to dispose the electrodes described above in a limited area of each of the pixels included in the imaging device 1.

In order to solve the problem that a large electrode is required on the bonding boundary surfaces between the first substrate 100 and the second substrate 200, for example, the imaging device 1 of the embodiment can use the first manufacturing method described above as a manufacturing method in which a plurality of the pixels 541 share one pixel circuit 210, and the shared pixel circuit 210 is disposed to overlap the photodiode PD. Accordingly, it is easy to align the elements formed in each of the first substrate 100 and the second substrate 200, and it is possible to manufacture a high-quality and high-performance imaging device. Moreover, a unique structure made by using this manufacturing method can be provided. That is, a structure in which the semiconductor layer 100S and the wiring layer 100T of the first substrate 100, and the semiconductor layer 200S and the wiring layer 200T of the second substrate 200 are stacked in this order, in other words, a structure in which the first substrate 100 and the second substrate 200 are stacked in a face-to-back manner is provided, and the through electrodes 120E and 121E are provided from the front surface side of the semiconductor layer 200S of the second substrate 200 to the front surface of the semiconductor layer 100S of the first substrate 100 by penetrating the semiconductor layer 200S and the wiring layer 100T of the first substrate 100.

In the structure in which the first substrate 100 is provided with the connection wiring that mutually connects the floating diffusions FD of each of a plurality of the pixels 541 and integrates the floating diffusions FD into one and the connection wiring that mutually connects the VSS contact regions 118 of each of a plurality of the pixels 541 and integrates the VSS contact regions 118 into one, when this structure and the second substrate 200 are stacked by using the first manufacturing method to form the pixel circuit 210 in the second substrate 200, there is a possibility that the connection wiring formed in the first substrate 100 is affected by the heating treatment necessary when the active element included in the pixel circuit 210 is formed.

Therefore, in order to solve the problem that the connection wiring is affected by the heating treatment when the active element is formed, it is desirable that the imaging device 1 of the embodiment use a conductive material having high heat resistance for the connection wiring that mutually connects the floating diffusions FD of each of a plurality of the pixels 541 and integrates the floating diffusions FD into one and the connection wiring that mutually connects the VSS contact regions 118 of each of a plurality of the pixels 541 and integrates the VSS contact regions 118 into one. Specifically, as the conductive material having high heat resistance, a material having a melting point higher than that of at least a part of the wiring material included in the wiring layer 200T of the second substrate 200 can be used.

As described above, for example, the imaging device 1 of the embodiment has: (1) a structure in which the first substrate 100 and the second substrate 200 are stacked in a face-to-back manner (specifically, a structure in which the semiconductor layer 100S and the wiring layer 100T of the first substrate 100, and the semiconductor layer 200S and the wiring layer 200T of the second substrate 200 are stacked in this order); (2) a structure in which the through electrodes 120E and 121E are provided from the front surface side of the semiconductor layer 200S of the second substrate 200 to the front surface of the semiconductor layer 100S of the first substrate 100 by penetrating the semiconductor layer 200S and the wiring layer 100T of the first substrate 100; and (3) a structure in which the connection wiring that mutually connects the floating diffusions FD included in each of a plurality of the pixels 541 and integrates the floating diffusions FD into one and the connection wiring that mutually connects the VSS contact regions 118 included in each of a plurality of the pixels 541 and integrates the VSS contact regions 118 into one are formed of a conductive material having high heat resistance, so that without providing large electrodes in an interface between the first substrate 100 and the second substrate 200, the first substrate 100 can be provided with the connection wiring that mutually connects the floating diffusions FD included in each of a plurality of the pixels 541 and integrates the floating diffusions FD into one and the connection wiring that mutually connects the VSS contact regions 118 included in each of a plurality of the pixels 541 and integrates the VSS contact regions 118 into one.

[1.4. Operation of Imaging Device 1]

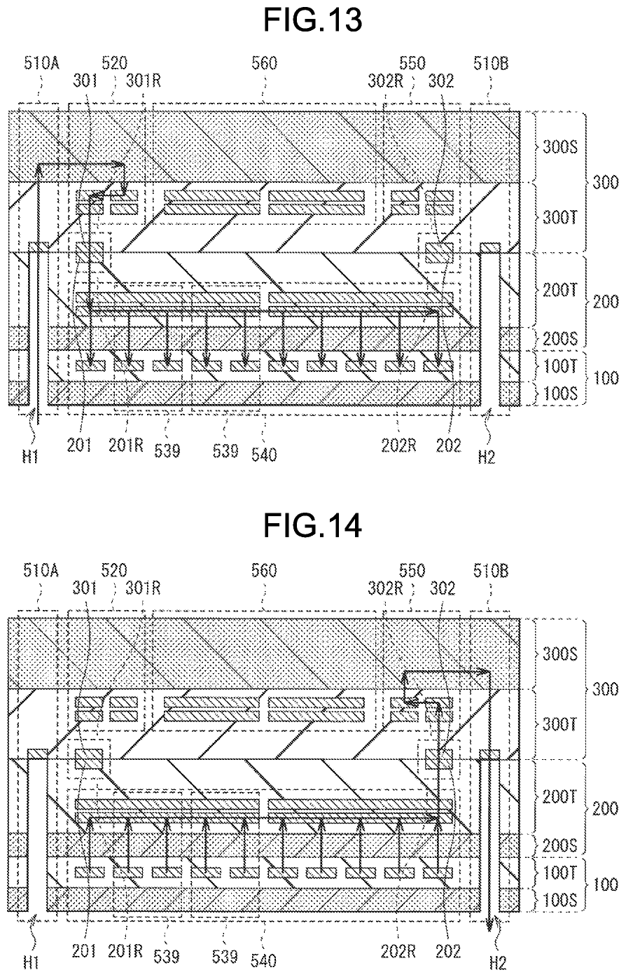

Next, the operation of the imaging device 1 will be described with reference to FIGS. 13 and 14. FIGS. 13 and 14 are drawings obtained by adding arrows representing a path of each signal to FIG. 3. In FIG. 13, an input signal input to the imaging device 1 from the outside, and paths of a power supply potential and a reference potential are indicated by arrows. In FIG. 14, a signal path of the pixel signal output from the imaging device 1 to the outside is indicated by an arrow. For example, the input signal (for example, a pixel clock and a synchronization signal) input to the imaging device 1 via the input unit 510A is transmitted to the row drive unit 520 of the third substrate 300, and the row drive unit 520 creates a row drive signal. The row drive signal is sent to the second substrate 200 via the contact portions 301 and 201. Moreover, the row drive signal reaches each of the pixel sharing units 539 of the pixel array unit 540 via the row drive signal line 542 in the wiring layer 200T. Among the row drive signals reaching the pixel sharing units 539 of the second substrate 200, the drive signal other than the transfer gate TG is input to the pixel circuit 210, and each of the transistors included in the pixel circuit 210 is driven. A drive signal of the transfer gate TG is input to the transfer gates TG1, TG2, TG3, and TG4 of the first substrate 100 via the through electrode TGV, and the pixels 541A, 541B, 541C, and 541D are driven (FIG. 13). Furthermore, from the outside of the imaging device 1, the power supply potential and the reference potential supplied to the input unit 510A (input terminal 511) of the third substrate 300 are sent to the second substrate 200 via the contact portions 301 and 201, and supplied to the pixel circuit 210 of each of the pixel sharing units 539 via the wiring in the wiring layer 200T. The reference potential is further supplied to the pixels 541A, 541B, 541C, and 541D of the first substrate 100 via the through electrode 121E. On the other hand, the pixel signal photoelectrically converted in each of the pixels 541A, 541B, 541C, and 541D of the first substrate 100 is sent to the pixel circuit 210 of the second substrate 200 via the through electrode 120E for each of the pixel sharing units 539. A pixel signal based on this pixel signal is sent from the pixel circuit 210 to the third substrate 300 via the vertical signal line 543 and the contact portions 202 and 302. The pixel signal is processed by the column signal processing unit 550 and the image signal processing unit 560 of the third substrate 300, and then output to the outside via the output unit 510B.

[1.5. Effects]

In the embodiment, the pixels 541A, 541B, 541C, and 541D (pixel sharing unit 539) and the pixel circuit 210 are provided in different substrates, respectively (first substrate 100 and second substrate 200). Accordingly, the areas of the pixels 541A, 541B, 541C, and 541D and the pixel circuit 210 can be increased as compared with a case where the pixels 541A, 541B, 541C, and 541D and the pixel circuit 210 are formed in the same substrate. As a result, the amount of the pixel signals obtained by photoelectric conversion can be increased, and transistor noise of the pixel circuit 210 can be reduced. Accordingly, the signal/noise ratio of the pixel signal is improved, and the imaging device 1 can output better pixel data (image information). Furthermore, the imaging device 1 can be miniaturized (in other words, the pixel size can be reduced and the size of the imaging device 1 can be reduced). The imaging device 1 can increase the number of pixels per unit area by reducing the pixel size, and can output a high-quality image.

Furthermore, in the imaging device 1, the first substrate 100 and the second substrate 200 are electrically connected to each other by the through electrodes 120E and 121E provided in the insulation region 212. For example, a method for connecting the first substrate 100 and the second substrate 200 by bonding pad electrodes to each other, or a method for connecting the first substrate 100 and the second substrate 200 by the through wiring (for example, through Si Via (TSV)) penetrating the semiconductor layer may be considered. As compared with such a method, by providing the through electrodes 120E and 121E in the insulation region 212, the area required for connecting the first substrate 100 and the second substrate 200 can be reduced. Accordingly, the pixel size can be reduced, and the size of the imaging device 1 can be further reduced. Furthermore, resolution can be further increased by further miniaturizing the area per pixel. When it is not necessary to reduce the chip size, the formation regions of the pixels 541A, 541B, 541C, and 541D and the pixel circuit 210 can be enlarged. As a result, the amount of the pixel signals obtained by photoelectric conversion can be increased, and noise of the transistor included in the pixel circuit 210 can be reduced. Accordingly, the signal/noise ratio of the pixel signal is improved, and the imaging device 1 can output better pixel data (image information).

Furthermore, in the imaging device 1, the pixel circuit 210, and the column signal processing unit 550 and the image signal processing unit 560 are provided in different substrates, respectively (second substrate 200 and third substrate 300). As a result, the area of the pixel circuit 210 and the areas of the column signal processing unit 550 and the image signal processing unit 560 can be increased as compared with a case where the pixel circuit 210, and the column signal processing unit 550 and the image signal processing unit 560 are formed in the same substrate. Therefore, noise generated in the column signal processing unit 550 can be reduced, and an advanced image processing circuit can be mounted due to the image signal processing unit 560. Accordingly, the signal/noise ratio of the pixel signal is improved, and the imaging device 1 can output better pixel data (image information).

Furthermore, in the imaging device 1, the pixel array unit 540 is provided in the first substrate 100 and the second substrate 200, and the column signal processing unit 550 and the image signal processing unit 560 are provided in the third substrate 300. Furthermore, the contact portions 201, 202, 301, and 302 connecting the second substrate 200 with the third substrate 300 are formed above the pixel array unit 540. Therefore, the contact portions 201, 202, 301, and 302 can be freely laid out without interference with various wirings provided in the pixel array in layout. Accordingly, the contact portions 201, 202, 301, and 302 can be used for electrical connection between the second substrate 200 and the third substrate 300. By using the contact portions 201, 202, 301, and 302, for example, the column signal processing unit 550 and the image signal processing unit 560 have a higher degree of freedom in layout. Therefore, noise generated in the column signal processing unit 550 can be reduced, and an advanced image processing circuit can be mounted due to the image signal processing unit 560. Accordingly, the signal/noise ratio of the pixel signal is improved, and the imaging device 1 can output better pixel data (image information).

Furthermore, in the imaging device 1, the pixel separation portion 117 penetrates the semiconductor layer 100S. As a result, color mixing among the pixels 541A, 541B, 541C, and 541D can be suppressed even in a case where a distance between adjacent pixels (pixels 541A, 541B, 541C, and 541D) is shortened due to miniaturization of the area per pixel. Accordingly, the signal/noise ratio of the pixel signal is improved, and the imaging device 1 can output better pixel data (image information).

Furthermore, in the imaging device 1, the pixel circuit 210 is provided for each of the pixel sharing units 539. As a result, as compared with a case where the pixel circuit 210 is provided in each of the pixels 541A, 541B, 541C, and 541D, the formation region of the transistors (amplification transistor AMP, reset transistor RST, selection transistor SEL, and FD conversion gain switching transistor FDG) constituting the pixel circuit 210 can be enlarged. For example, noise can be suppressed by enlarging the formation region of the amplification transistor AMP. Accordingly, the signal/noise ratio of the pixel signal is improved, and the imaging device 1 can output better pixel data (image information).

Moreover, in the imaging device 1, the pad portion 120 that electrically connects the floating diffusions FD (floating diffusions FD1, FD2, FD3, and FD4) of four pixels (pixels 541A, 541B, 541C, and 541D) is provided in the first substrate 100. As a result, the number of the through electrodes (through electrode 120E) connecting the first substrate 100 and the second substrate 200 can be reduced as compared with a case where the pad portion 120 is provided in the second substrate 200. Therefore, the insulation region 212 can be made small, and the formation region (semiconductor layer 200S) of the transistors constituting the pixel circuit 210 can be secured in a sufficient size. Accordingly, the noise of the transistor included in the pixel circuit 210 can be reduced, and the signal/noise ratio of the pixel signal is improved, and the imaging device 1 can output better pixel data (image information).

Hereinafter, a modified example of the imaging device 1 according to the embodiment described above will be described. In the following modified example, the same reference numerals are given to the same configurations as those of the embodiment.

### 2. Modified Example

### 2.1. Modified Example 1-1

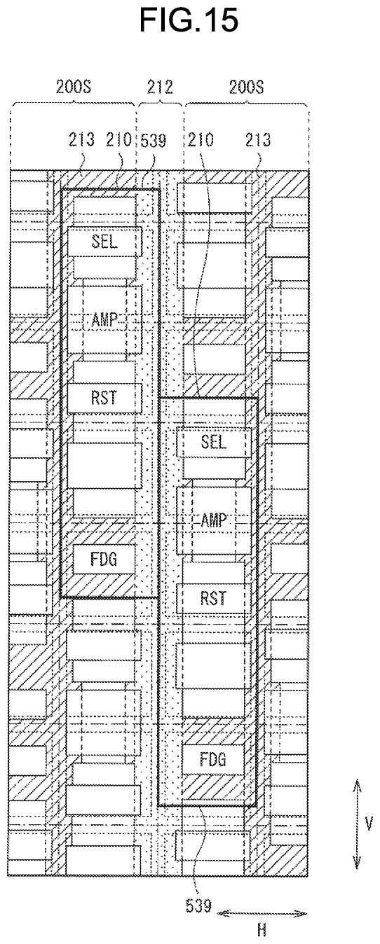

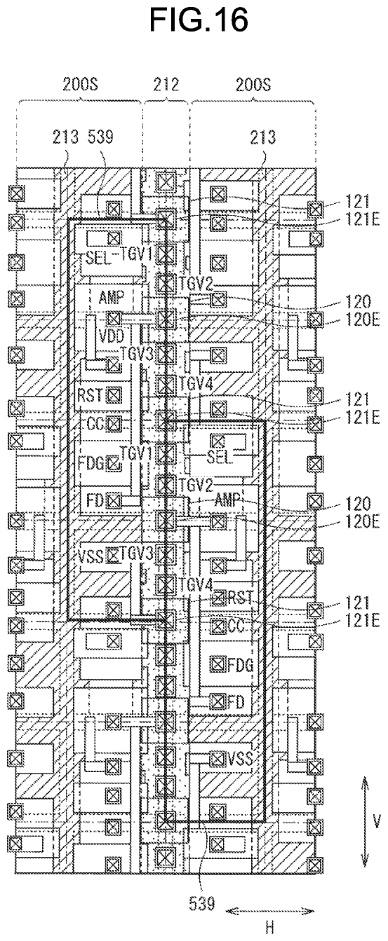

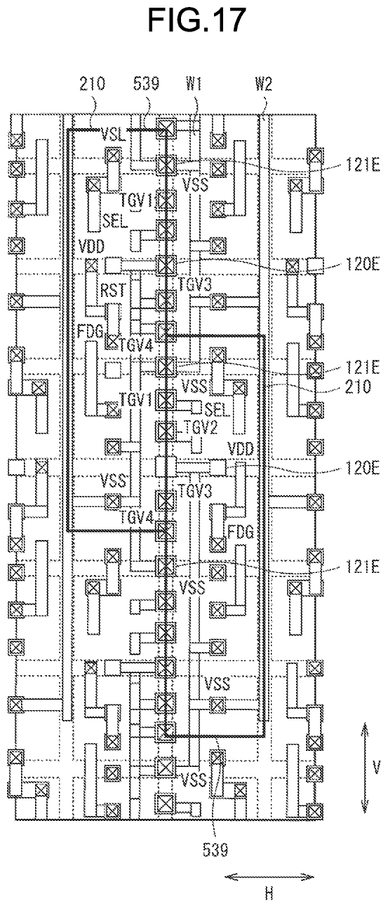

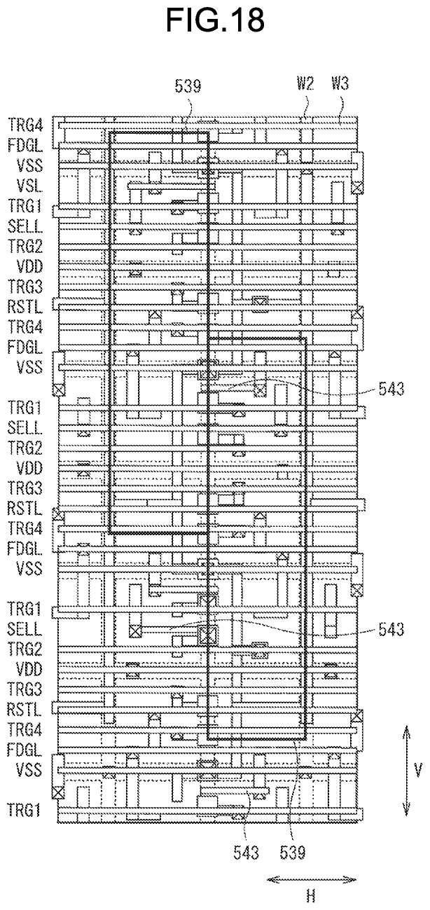

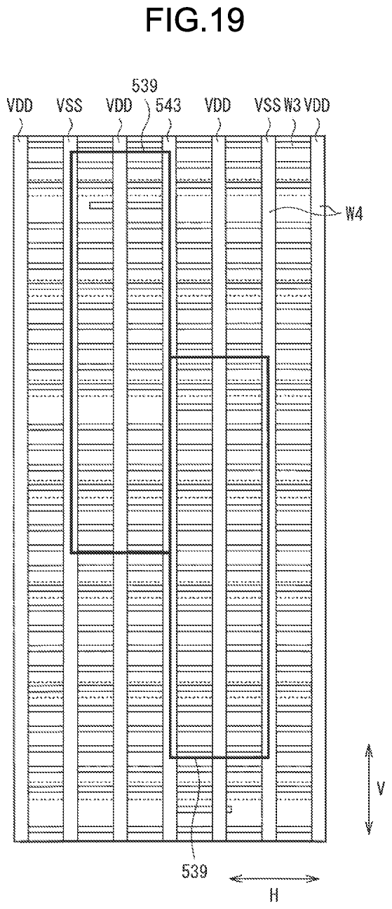

FIGS. 15 to 19 illustrate a modified example of the plane configuration of the imaging device 1 according to the embodiment. FIG. 15 schematically illustrates the plane configuration in the vicinity of the front surface of the semiconductor layer 200S of the second substrate 200, and corresponds to FIG. 8 described in the embodiment. FIG. 16 schematically illustrates a configuration of each part of the first wiring layer W1, the semiconductor layer 200S connected to the first wiring layer W1, and the first substrate 100, and corresponds to FIG. 9 described in the embodiment. FIG. 17 illustrates an example of a plane configuration of the first wiring layer W1 and the second wiring layer W2, and corresponds to FIG. 10 described in the embodiment. FIG. 18 illustrates an example of a plane configuration of the second wiring layer W2 and the third wiring layer W3, and corresponds to FIG. 11 described in the embodiment. FIG. 19 illustrates an example of a plane configuration of the third wiring layer W3 and the fourth wiring layer W4, and corresponds to FIG. 12 described in the embodiment.

In the modified example, as illustrated in FIG. 16, among two pixel sharing units 539 arranged in the H direction of the second substrate 200, an internal layout of one pixel sharing unit 539 (for example, the right side of the paper) has a configuration in which an internal layout of the other pixel sharing unit 539 (for example, the left side of the paper) is inverted only in the H direction. Furthermore, the deviation between the outline of one pixel sharing unit 539 and the outline of the other pixel sharing unit 539 in the V direction is larger than the deviation (FIG. 9) described in the embodiment. In this manner, by increasing the deviation in the V direction, the distance between the amplification transistor AMP of the other pixel sharing unit 539 and the pad portion 120 connected to the amplification transistor AMP (pad portion 120 on the other pixel sharing unit 539 (lower side of the paper) of two pixel sharing units 539 arranged in the V direction illustrated in FIG. 7) can be reduced. With such a layout, Modified Example 1-1 of the imaging device 1 illustrated in FIGS. 15 to 19 can make the area of plane layouts of two pixel sharing units 539 arranged in the H direction the same as the area of the pixel sharing units 539 of the second substrate 200 described in the embodiment without mutually inverting the plane layouts of two pixel sharing units arranged in the H direction in the V direction. Note that, the plane layout of the pixel sharing unit 539 of the first substrate 100 is the same as the plane layout (FIGS. 7A and 7B) described in the embodiment. Therefore, the imaging device 1 of the modified example can obtain the same effects as those of the imaging device 1 described in the embodiment. The arrangement of the pixel sharing units 539 of the second substrate 200 is not limited to the arrangement described in the embodiment and the modified example.

### 2.2. Modified Example 1-2

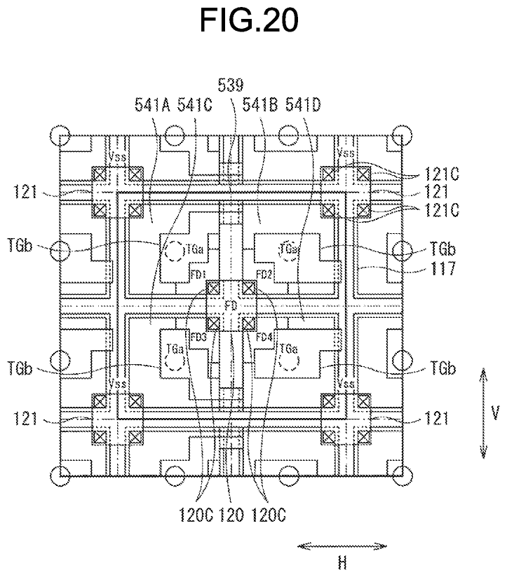

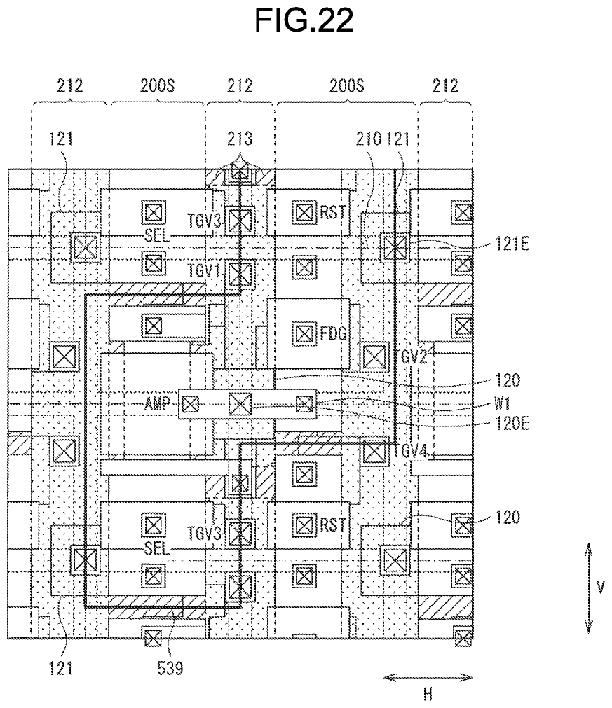

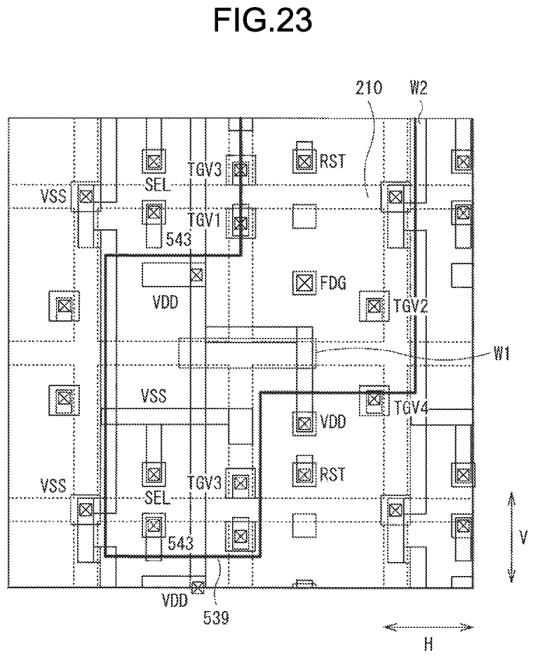

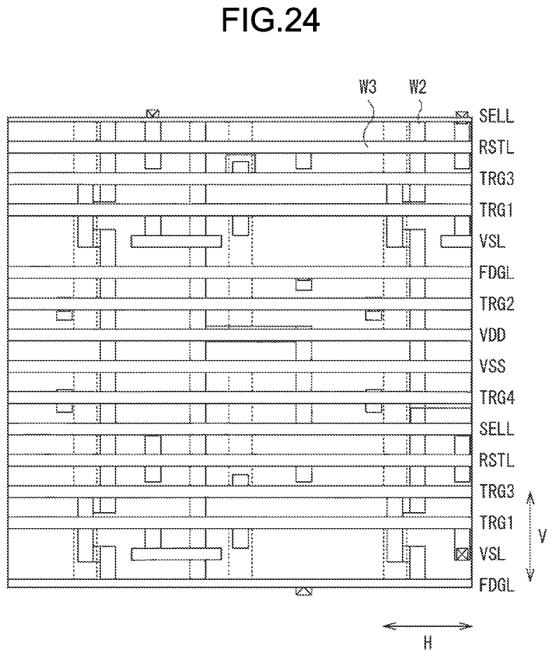

FIGS. 20 to 25 illustrate a modified example of the plane configuration of the imaging device 1 according to the embodiment. FIG. 20 schematically illustrates the plane configuration of the first substrate 100, and corresponds to FIG. 7A described in the embodiment. FIG. 21 schematically illustrates the plane configuration in the vicinity of the front surface of the semiconductor layer 200S of the second substrate 200, and corresponds to FIG. 8 described in the embodiment. FIG. 22 schematically illustrates a configuration of each part of the first wiring layer W1, the semiconductor layer 200S connected to the first wiring layer W1, and the first substrate 100, and corresponds to FIG. 9 described in the embodiment. FIG. 23 illustrates an example of a plane configuration of the first wiring layer W1 and the second wiring layer W2, and corresponds to FIG. 10 described in the embodiment. FIG. 24 illustrates an example of a plane configuration of the second wiring layer W2 and the third wiring layer W3, and corresponds to FIG. 11 described in the embodiment. FIG. 25 illustrates an example of a plane configuration of the third wiring layer W3 and the fourth wiring layer W4, and corresponds to FIG. 12 described in the embodiment.

In the modified example, an outer shape of each of the pixel circuits 210 has a substantially square plane shape (FIG. 21 and the like). In this point, the plane configuration of the imaging device 1 of the modified example is different from the plane configuration of the imaging device 1 described in the embodiment.

For example, the pixel sharing unit 539 of the first substrate 100 is formed over a pixel region of 2 rows×2 columns, and has a substantially square plane shape (FIG. 20), as described in the embodiment. For example, in each of the pixel sharing units 539, the horizontal portions TGb of the transfer gates TG1 and TG3 of the pixel 541A and the pixel 541C of one pixel column extend in a direction toward the center portion of the pixel sharing unit 539 in the H direction from a position overlapping the vertical portion TGa (more specifically, a direction toward outer edges of the pixels 541A and 541C, and a direction toward the center portion of the pixel sharing unit 539), and the horizontal portions TGb of the transfer gates TG2 and TG4 of the pixel 541B and the pixel 541D of the other pixel column extend in a direction toward the outside of the pixel sharing unit 539 in the H direction from a position overlapping the vertical portion TGa (more specifically, a direction toward outer edges of the pixels 541B and 541D, and a direction toward the outside of the pixel sharing unit 539). The pad portion 120 connected to the floating diffusion FD is provided at the center portion of the pixel sharing unit 539 (center portion of the pixel sharing unit 539 in the H direction and the V direction), and the pad portion 121 connected to the VSS contact region 118 is provided at an end portion of the pixel sharing unit 539 at least in the H direction (in the H direction and the V direction in FIG. 20).

As another arrangement example, it is also conceivable to provide the horizontal portions TGb of the transfer gates TG1, TG2, TG3, and TG4 only in a region facing the vertical portions TGa. At this time, the semiconductor layer 200S is likely to be finely divided as described in the embodiment. Therefore, it is difficult to form a large transistor of the pixel circuit 210. On the other hand, when the horizontal portions TGb of the transfer gates TG1, TG2, TG3, and TG4 extend in the H direction from the position overlapping the vertical portion TGa as in the above modified example, a width of the semiconductor layer 200S can be increased as described in the embodiment. Specifically, the positions of the through electrodes TGV1 and TGV3 connected to the transfer gates TG1 and TG3 in the H direction can be disposed close to the position of the through electrode 120E in the H direction, and the positions of the through electrodes TGV2 and TGV4 connected to the transfer gates TG2 and TG4 in the H direction can be disposed close to the position of the through electrode 121E in the H direction (FIG. 22). Accordingly, the width (size in the H direction) of the semiconductor layer 200S extending in the V direction can be increased as described in the embodiment. Therefore, it is possible to increase the size of the transistor of the pixel circuit 210, particularly, the size of the amplification transistor AMP. As a result, the signal/noise ratio of the pixel signal is improved, and the imaging device 1 can output better pixel data (image information).

The pixel sharing unit 539 of the second substrate 200 has, for example, substantially the same size as that of the pixel sharing unit 539 of the first substrate 100 in the H direction and the V direction, and is provided over, for example, a region corresponding to a pixel region of approximately 2 rows×2 columns. For example, in each of the pixel circuits 210, the selection transistor SEL and the amplification transistor AMP are disposed side by side in the V direction in one semiconductor layer 200S extending in the V direction, and the FD conversion gain switching transistor FDG and the reset transistor RST are disposed side by side in the V direction in one semiconductor layer 200S extending in the V direction. One semiconductor layer 200S provided with the selection transistor SEL and the amplification transistor AMP and one semiconductor layer 200S provided with the FD conversion gain switching transistor FDG and the reset transistor RST are disposed in the H direction via the insulation region 212. The insulation region 212 extends in the V direction (FIG. 21).

Here, the outer shape of the pixel sharing unit 539 of the second substrate 200 will be described with reference to FIGS. 21 and 22. For example, the pixel sharing unit 539 of the first substrate 100 illustrated in FIG. 20 is connected to the amplification transistor AMP and the selection transistor SEL provided on one side of the pad portion 120 in the H direction (left side of the paper of FIG. 22), and the FD conversion gain switching transistor FDG and the reset transistor RST provided on the other side of the pad portion 120 in the H direction (right side of the paper of FIG. 22). The outer shape of the pixel sharing unit 539 of the second substrate 200 including the amplification transistor AMP, the selection transistor SEL, the FD conversion gain switching transistor FDG, and the reset transistor RST is determined by the following four outer edges.

A first outer edge is an outer edge of one end of the semiconductor layer 200S including the selection transistor SEL and the amplification transistor AMP in the V direction (upper end of the paper of FIG. 22). The first outer edge is provided between the amplification transistor AMP included in the pixel sharing unit 539 and the selection transistor SEL included in the pixel sharing unit 539 adjacent to one side of the pixel sharing unit 539 in the V direction (upper side of the paper of FIG. 22). More specifically, the first outer edge is provided at the center portion of the element separation region 213 between the amplification transistor AMP and the selection transistor SEL in the V direction. A second outer edge is an outer edge of the other end of the semiconductor layer 200S including the selection transistor SEL and the amplification transistor AMP in the V direction (lower end of the paper of FIG. 22). The second outer edge is provided between the selection transistor SEL included in the pixel sharing unit 539 and the amplification transistor AMP included in the pixel sharing unit 539 adjacent to the other side of the pixel sharing unit 539 in the V direction (lower side of the paper of FIG. 22). More specifically, the second outer edge is provided at the center portion of the element separation region 213 between the selection transistor SEL and the amplification transistor AMP in the V direction. A third outer edge is an outer edge of the other end of the semiconductor layer 200S including the reset transistor RST and the FD conversion gain switching transistor FDG in the V direction (lower end of the paper of FIG. 22). The third outer edge is provided between the FD conversion gain switching transistor FDG included in the pixel sharing unit 539 and the reset transistor RST included in the pixel sharing unit 539 adjacent to the other side of the pixel sharing unit 539 in the V direction (lower side of the paper of FIG. 22). More specifically, the third outer edge is provided at the center portion of the element separation region 213 between the FD conversion gain switching transistor FDG and the reset transistor RST in the V direction. A fourth outer edge is an outer edge of one end of the semiconductor layer 200S including the reset transistor RST and the FD conversion gain switching transistor FDG in the V direction (upper end of the paper of FIG. 22). The fourth outer edge is provided between the reset transistor RST included in the pixel sharing unit 539 and the FD conversion gain switching transistor FDG (not illustrated) included in the pixel sharing unit 539 adjacent to one side of the pixel sharing unit 539 in the V direction (upper side of the paper of FIG. 22). More specifically, the fourth outer edge is provided at the center portion of the element separation region 213 (not illustrated) between the reset transistor RST and the FD conversion gain switching transistor FDG in the V direction.

In the outer shape of the pixel sharing unit 539 of the second substrate 200 including the first outer edge, the second outer edge, the third outer edge, and the fourth outer edge, the third outer edge and the fourth outer edge are disposed to be shifted to one side in the V direction (in other words, offset to one side in the V direction) with respect to the first outer edge and the second outer edge. By using such a layout, both the gate of the amplification transistor AMP and the source of the FD conversion gain switching transistor FDG can be disposed as close as possible to the pad portion 120. Therefore, an area of the wiring connecting the amplification transistor AMP with the FD conversion gain switching transistor FDG is reduced, and the imaging device 1 can be easily miniaturized. Note that, the VSS contact region 218 is provided between the semiconductor layer 200S including the selection transistor SEL and the amplification transistor AMP and the semiconductor layer 200S including the reset transistor RST and the FD conversion gain switching transistor FDG. For example, a plurality of the pixel circuits 210 have the same arrangement.

The imaging device 1 including such a second substrate 200 can also obtain the same effects as those described in the embodiment. The arrangement of the pixel sharing units 539 of the second substrate 200 is not limited to the arrangement described in the embodiment and the modified example.

### 2.3. Modified Example 1-3

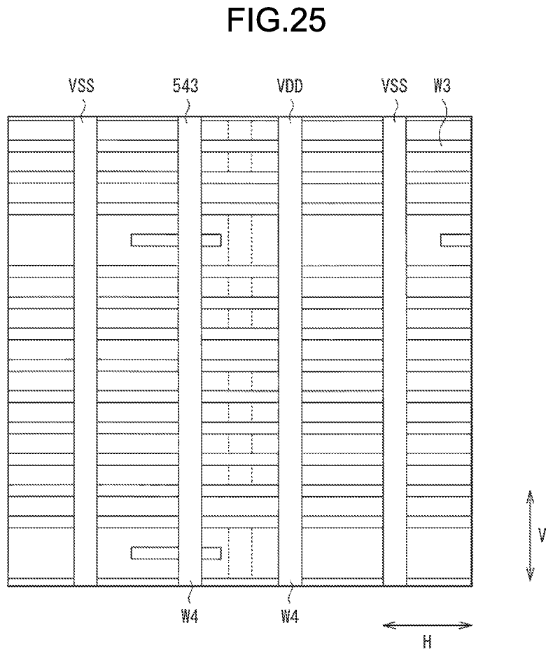

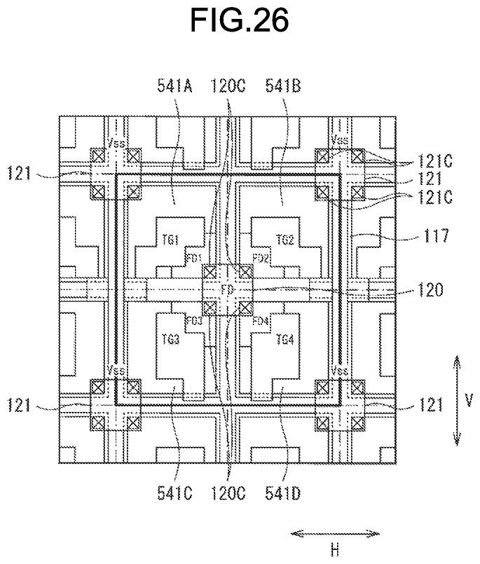

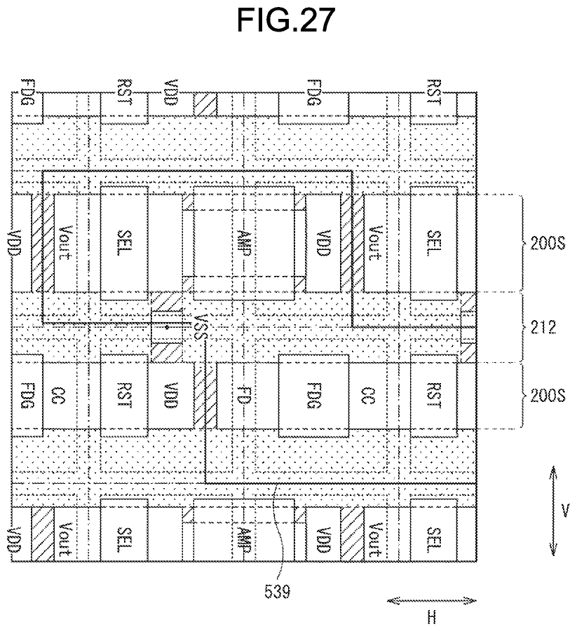

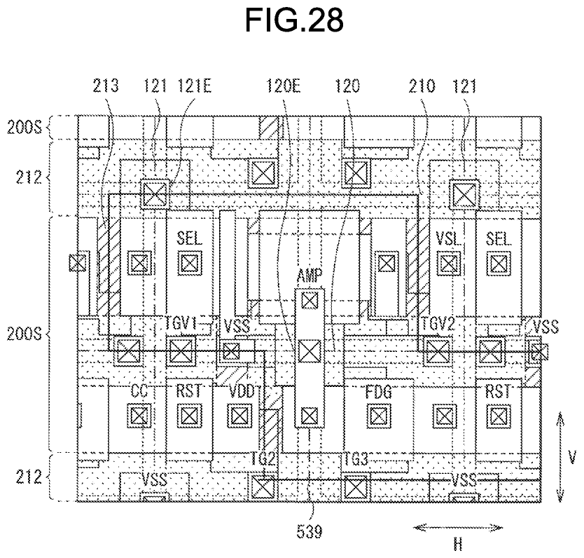

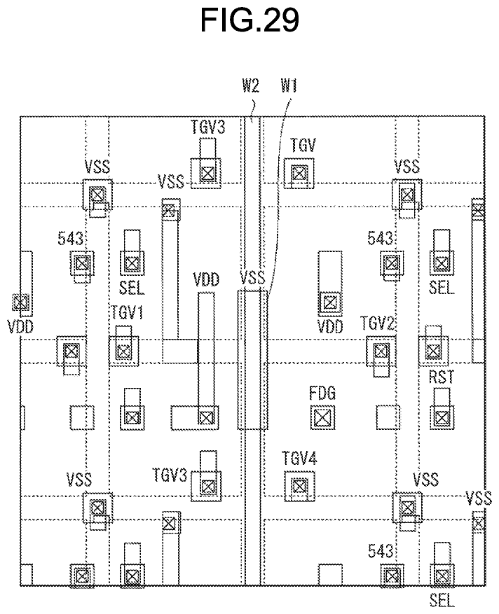

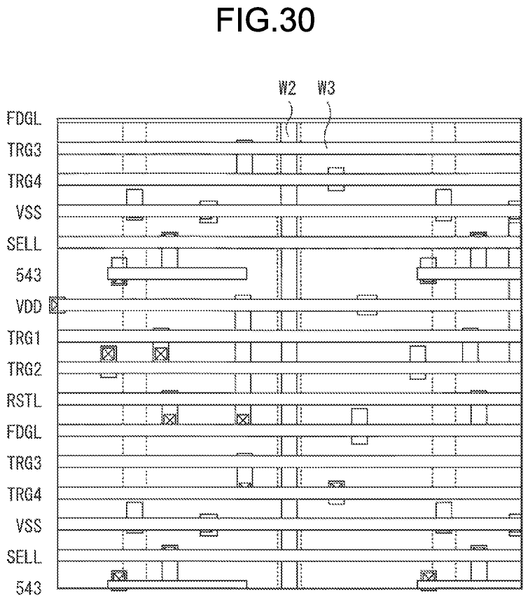

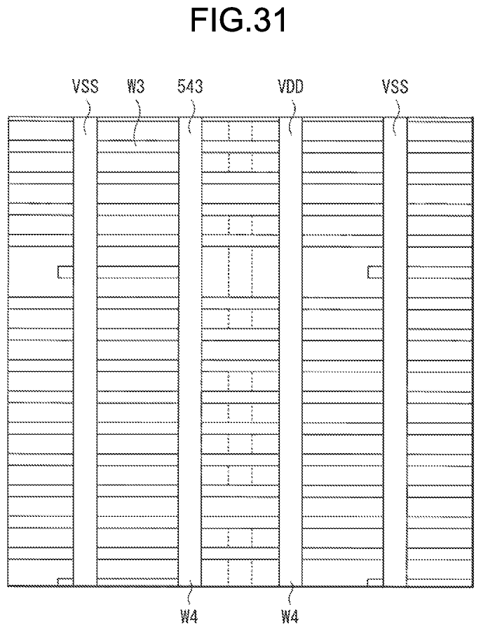

FIGS. 26 to 31 illustrate a modified example of the plane configuration of the imaging device 1 according to the embodiment. FIG. 26 schematically illustrates the plane configuration of the first substrate 100, and corresponds to FIG. 7B described in the embodiment. FIG. 27 schematically illustrates the plane configuration in the vicinity of the front surface of the semiconductor layer 200S of the second substrate 200, and corresponds to FIG. 8 described in the embodiment. FIG. 28 schematically illustrates a configuration of each part of the first wiring layer W1, the semiconductor layer 200S connected to the first wiring layer W1, and the first substrate 100, and corresponds to FIG. 9 described in the embodiment. FIG. 29 illustrates an example of a plane configuration of the first wiring layer W1 and the second wiring layer W2, and corresponds to FIG. 10 described in the embodiment. FIG. 30 illustrates an example of a plane configuration of the second wiring layer W2 and the third wiring layer W3, and corresponds to FIG. 11 described in the embodiment. FIG. 31 illustrates an example of a plane configuration of the third wiring layer W3 and the fourth wiring layer W4, and corresponds to FIG. 12 described in the embodiment.

In the modified example, the semiconductor layer 200S of the second substrate 200 extends in the H direction (FIG. 28). That is, the modified example substantially corresponds to a configuration in which the plane configuration of the imaging device 1 illustrated in FIG. 21 and the like is rotated by 90 degrees.

For example, the pixel sharing unit 539 of the first substrate 100 is formed over a pixel region of 2 rows×2 columns, and has a substantially square plane shape (FIG. 26), as described in the embodiment. For example, in each of the pixel sharing units 539, the transfer gates TG1 and TG2 of the pixel 541A and the pixel 541B of one pixel row extend toward the center portion of the pixel sharing unit 539 in the V direction, and the transfer gates TG3 and TG4 of the pixel 541C and the pixel 541D of the other pixel row extend in an outer direction of the pixel sharing unit 539 in the V direction. The pad portion 120 connected to the floating diffusion FD is provided at the center portion of the pixel sharing unit 539, and the pad portion 121 connected to the VSS contact region 118 is provided at an end portion of the pixel sharing unit 539 at least in the V direction (in the V direction and the H direction in FIG. 26). At this time, the positions of the through electrodes TGV1 and TGV2 of the transfer gates TG1 and TG2 in the V direction are close to the position of the through electrode 120E in the V direction, and the positions of the through electrodes TGV3 and TGV4 of the transfer gates TG3 and TG4 in the V direction are close to the position of the through electrode 121E in the V direction (FIG. 28). Therefore, the width (size in the V direction) of the semiconductor layer 200S extending in the H direction can be increased with the same reason described in the embodiment. Accordingly, it is possible to increase the size of the amplification transistor AMP and suppress noise.

In each of the pixel circuits 210, the selection transistor SEL and the amplification transistor AMP are disposed side by side in the H direction, and the reset transistor RST is disposed at a position adjacent to the selection transistor SEL in the V direction with the insulation region 212 interposed between the selection transistor SEL and the reset transistor RST (FIG. 27). The FD conversion gain switching transistor FDG is disposed side by side with the reset transistor RST in the H direction. The VSS contact region 218 is provided in an island shape in the insulation region 212. For example, the third wiring layer W3 extends in the H direction (FIG. 30), and the fourth wiring layer W4 extends in the V direction (FIG. 31).

The imaging device 1 including such a second substrate 200 can also obtain the same effects as those described in the embodiment. The arrangement of the pixel sharing units 539 of the second substrate 200 is not limited to the arrangement described in the embodiment and the modified example. For example, the semiconductor layer 200S described in the embodiment and Modified Example 1-1 may extend in the H direction.

### 2.4. Modified Example 1-4

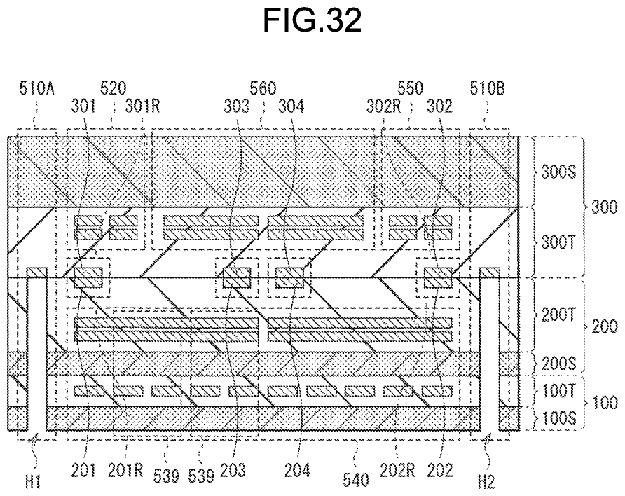

FIG. 32 schematically illustrates a modified example of a cross-sectional configuration of the imaging device 1 according to the embodiment. FIG. 32 corresponds to FIG. 3 described in the embodiment. In the modified example, in addition to the contact portions 201, 202, 301, and 302, the imaging device 1 includes contact portions 203, 204, 303, and 304 at a position facing the center portion of the pixel array unit 540. In this point, the imaging device 1 of the modified example is different from the imaging device 1 described in the embodiment.

The contact portions 203 and 204 are provided in the second substrate 200, and a bonding surface with the third substrate 300 is exposed. The contact portions 303 and 304 are provided in the third substrate 300, and a bonding surface with the second substrate 200 is exposed. The contact portion 203 is in contact with the contact portion 303, and the contact portion 204 is in contact with the contact portion 304. That is, in the imaging device 1, the second substrate 200 and the third substrate 300 are connected by the contact portions 203, 204, 303, and 304 in addition to the contact portions 201, 202, 301, and 302.

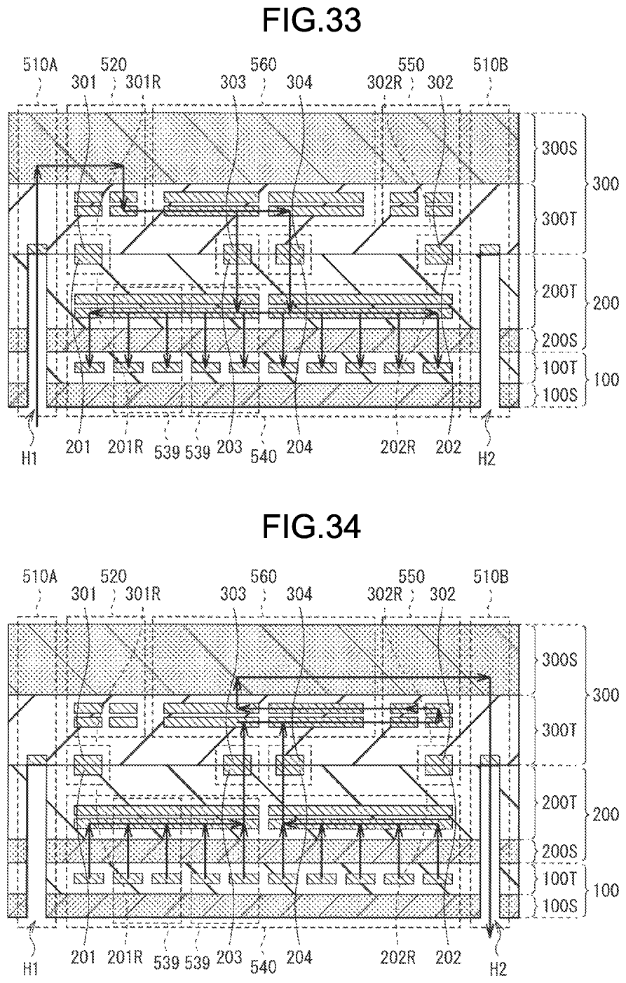

Next, an operation of the imaging device 1 will be described with reference to FIGS. 33 and 34. In FIG. 33, an input signal input to the imaging device 1 from the outside, and paths of the power supply potential and the reference potential are indicated by arrows. In FIG. 34, a signal path of the pixel signal output from the imaging device 1 to the outside is indicated by an arrow. For example, the input signal input to the imaging device 1 via the input unit 510A is transmitted to the row drive unit 520 of the third substrate 300, and the row drive unit 520 creates a row drive signal. The row drive signal is sent to the second substrate 200 via the contact portions 303 and 203. Moreover, the row drive signal reaches each of the pixel sharing units 539 of the pixel array unit 540 via the row drive signal line 542 in the wiring layer 200T. Among the row drive signals reaching the pixel sharing units 539 of the second substrate 200, the drive signal other than the transfer gate TG is input to the pixel circuit 210, and each of the transistors included in the pixel circuit 210 is driven. A drive signal of the transfer gate TG is input to the transfer gates TG1, TG2, TG3, and TG4 of the first substrate 100 via the through electrode TGV, and the pixels 541A, 541B, 541C, and 541D are driven. Furthermore, from the outside of the imaging device 1, the power supply potential and the reference potential supplied to the input unit 510A (input terminal 511) of the third substrate 300 are sent to the second substrate 200 via the contact portions 303 and 203, and supplied to the pixel circuit 210 of each of the pixel sharing units 539 via the wiring in the wiring layer 200T. The reference potential is further supplied to the pixels 541A, 541B, 541C, and 541D of the first substrate 100 via the through electrode 121E. On the other hand, the pixel signal photoelectrically converted in each of the pixels 541A, 541B, 541C, and 541D of the first substrate 100 is sent to the pixel circuit 210 of the second substrate 200 for each of the pixel sharing units 539. The pixel signal based on this pixel signal is sent from the pixel circuit 210 to the third substrate 300 via the vertical signal line 543 and the contact portions 204 and 304. The pixel signal is processed by the column signal processing unit 550 and the image signal processing unit 560 of the third substrate 300, and then output to the outside via the output unit 510B.

The imaging device 1 including the contact portions 203, 204, 303, and 304 can also obtain the same effects as those described in the embodiment. The position, the number, and the like of the contact portions can be changed according to the design of the circuit or the like of the third substrate 300 to which the wiring is connected via the contact portions 303 and 304.

### 2.5. Modified Example 1-5

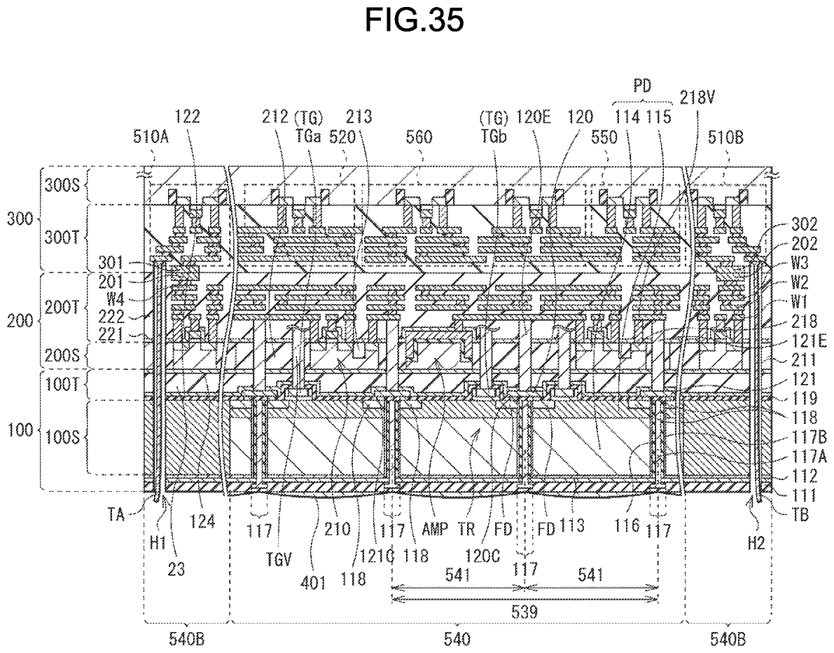

FIG. 35 illustrates a modified example of a cross-sectional configuration of the imaging device 1 according to the embodiment. FIG. 35 corresponds to FIG. 6 described in the embodiment. In the modified example, the transfer transistor TR having a planar structure is provided in the first substrate 100. In this point, the imaging device 1 of the modified example is different from the imaging device 1 described in the embodiment.

In the transfer transistor TR, the transfer gate TG is configured only by the horizontal portion TGb. In other words, the transfer gate TG does not include the vertical portion TGa, and is provided to face the semiconductor layer 100S.

The imaging device 1 including the transfer transistor TR having the planar structure can also obtain the same effects as those described in the embodiment. Moreover, it is also conceivable to form the photodiode PD to be closer to the front surface of the semiconductor layer 100S by providing a planar transfer gate TG in the first substrate 100 as compared with a case where the vertical transfer gate TG is provided in the first substrate 100, so that a saturation signal amount (Qs) is increased. Furthermore, it is conceivable that the method for forming the planar transfer gate TG in the first substrate 100 includes a smaller number of manufacturing steps than those of the method for forming the vertical transfer gate TG in the first substrate 100, and the photodiode PD is less likely to be adversely affected due to the manufacturing steps.

### 2.6. Modified Example 1-6

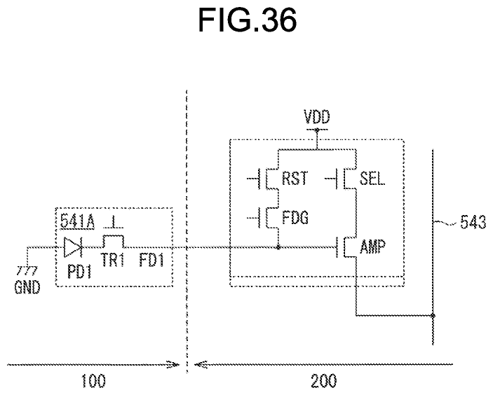

FIG. 36 illustrates a modified example of the pixel circuit of the imaging device 1 according to the embodiment. FIG. 36 corresponds to FIG. 4 described in the embodiment. In the modified example, the pixel circuit 210 is provided for each pixel (pixel 541A). That is, the pixel circuit 210 is not shared by a plurality of the pixels. In this point, the imaging device 1 of the modified example is different from the imaging device 1 described in the embodiment.

The imaging device 1 of the modified example is the same as the imaging device 1 described in the embodiment in that the pixel 541A and the pixel circuit 210 are provided in different substrates (first substrate 100 and second substrate 200). Therefore, the imaging device 1 according to the modified example can obtain the same effects as those described in the embodiment.

### 2.7. Modified Example 1-7

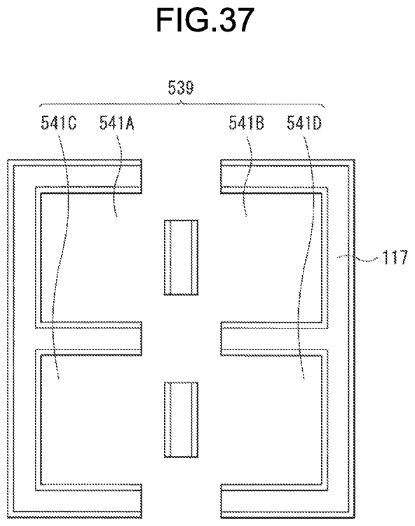

FIG. 37 illustrates a modified example of the plane configuration of the pixel separation portion 117 described in the embodiment. A gap may be provided in the pixel separation portion 117 surrounding each of the pixels 541A, 541B, 541C, and 541D. That is, the entire periphery of the pixels 541A, 541B, 541C, and 541D may not be surrounded by the pixel separation portion 117. For example, the gap in the pixel separation portion 117 is provided in the vicinity of the pad portions 120 and 121 (refer to FIG. 7B).

In the embodiment, an example in which the pixel separation portion 117 has the FTI structure penetrating the semiconductor layer 100S (refer to FIG. 6) has been described, and the pixel separation portion 117 may have a configuration other than the FTI structure. For example, the pixel separation portion 117 may not be provided so as to completely penetrate the semiconductor layer 100S, and may have a so-called deep trench isolation (DTI) structure.

### 2.8. Modified Example 1-8

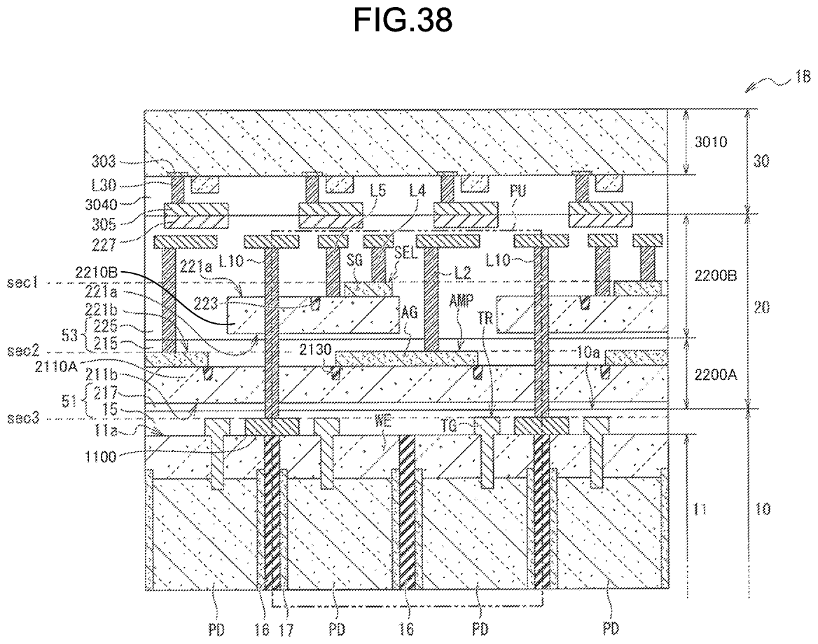

Meanwhile, in the embodiments described so far, the pixel circuit 210 including the amplification transistor AMP, the reset transistor RST, and the selection transistor SEL has been described as the circuit being provided in the second substrate 200. In other words, in the embodiments described so far, the amplification transistor AMP, the reset transistor RST, and the selection transistor SEL are formed in the same substrate 200. However, in the embodiment of the present disclosure, for example, two stacked substrates may be used instead of one second substrate 200. In this case, at least one transistor among the transistors included in the pixel circuit 210 may be provided on one substrate of the stacked substrates, and the remaining transistors may be provided in the other substrate. Specifically, for example, a lower substrate 2200A and an upper substrate 2200B, which are stacked, (refer to FIG. 38) may be used instead of one second substrate 200. In this case, an interlayer insulation film 53 and the wiring are formed in the lower substrate 2200A, and the upper substrate 2200B is further stacked. The upper substrate 2200B is stacked on a side opposite to the surface of the lower substrate 2200A facing the semiconductor substrate 11, and a desired transistor can be provided on the upper substrate 2200B. As an example, the amplification transistor AMP can be formed in the lower substrate 2200A, and the reset transistor RST and/or the selection transistor SEL can be formed in the upper substrate 2200B.

Furthermore, in the embodiment of the present disclosure, three or more stacked substrates may be used instead of one second substrate 200. Then, a desired transistor among a plurality of the transistors included in the pixel circuit 210 may be provided in each of the stacked substrates. In this case, the type of the transistor provided in the stacked substrate is not limited.

As described above, by using a plurality of stacked substrates instead of one second substrate 200, an area occupied by the pixel circuit 210 can be reduced. Moreover, by reducing the area of the pixel circuit 210 and miniaturizing each of the transistors, the area of the chips constituting the imaging device 1 can be reduced. In such a case, the area of only a desired transistor among the amplification transistor AMP, the reset transistor RST, and the selection transistor SEL that can constitute the pixel circuit 210 may be increased. For example, noise can be reduced by enlarging the area of the amplification transistor AMP.

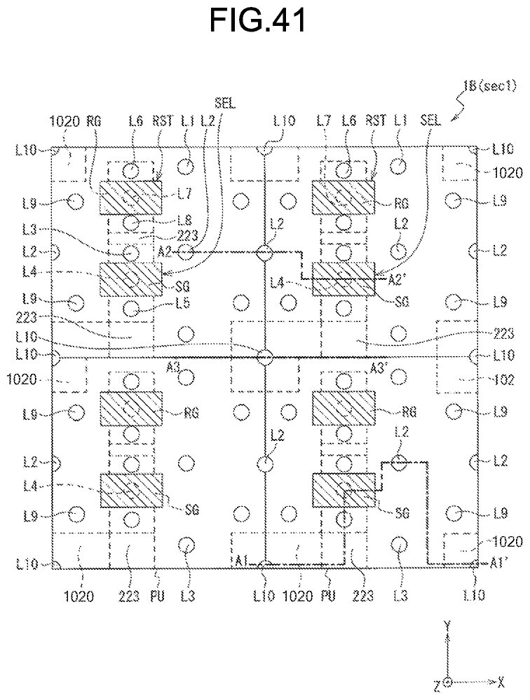

Modified Example 1-8 in which two stacked substrates are used instead of one second substrate 200 will be described with reference to FIGS. 38 to 43. FIGS. 38 to 40 are cross-sectional views in a thickness direction, which illustrates a configuration example of an imaging device 1B according to Modified Example 1-8 of the embodiment. FIGS. 41 to 43 are horizontal cross-sectional views illustrating a layout example of a plurality of pixel units PU according to Modified Example 1-8 of the embodiment. Note that, the cross-sectional views illustrated in FIGS. 38 to 40 are merely schematic views, and are not views intended to strictly and correctly illustrate an actual structure. In the cross-sectional views illustrated in FIGS. 38 to 40, the positions of the transistors and impurity diffusion layers in the horizontal direction are intentionally changed from a position sec1 to a position sec3 in order to easily explain the configuration of the imaging device 1B on the paper.

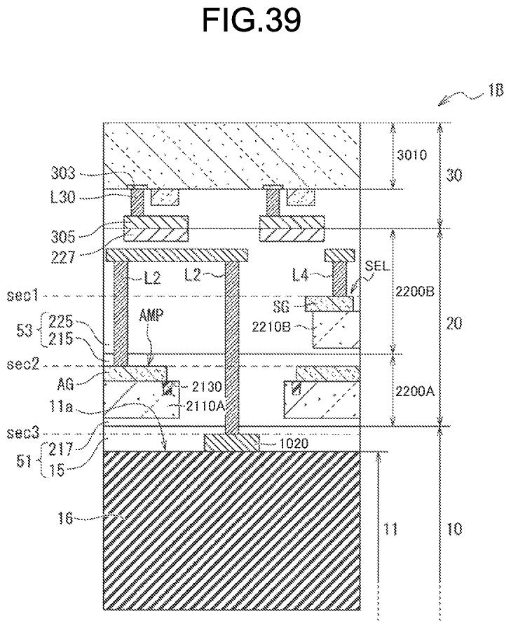

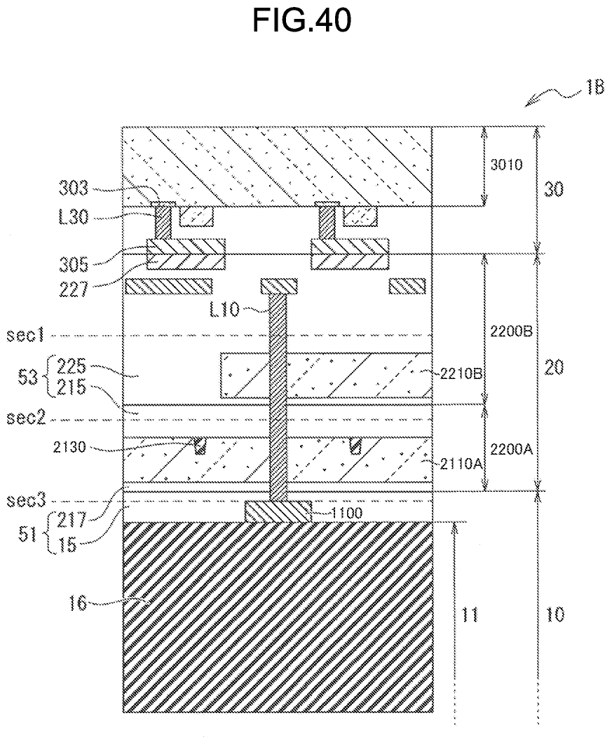

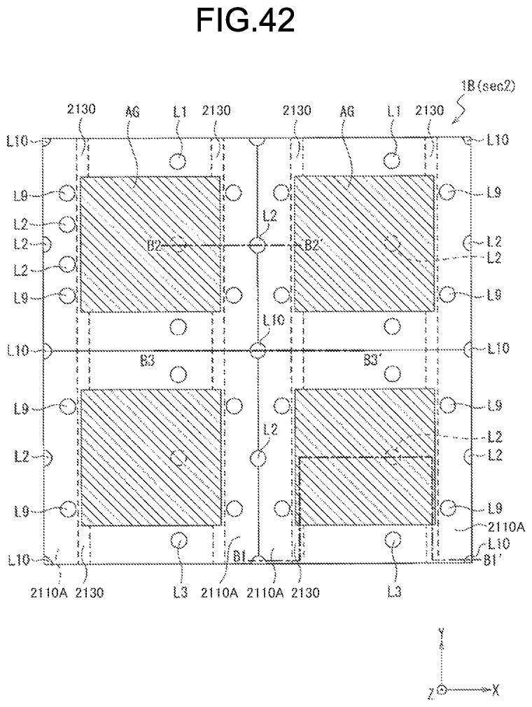

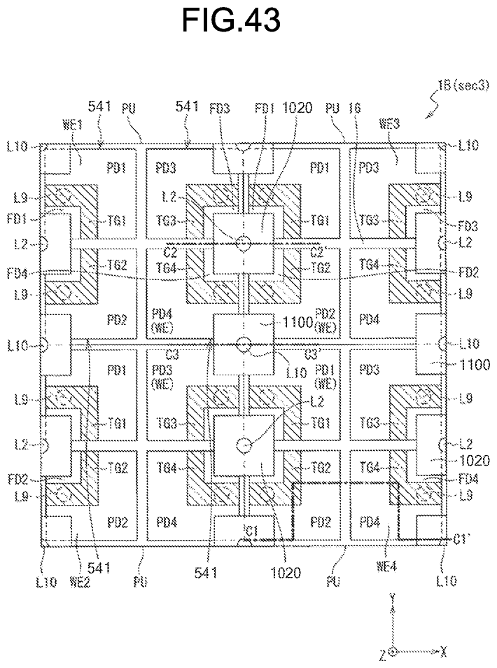

Specifically, in a pixel unit PU of the imaging device 1B illustrated in FIG. 38, a cross section at the position sec1 is a cross section taken along line A1-A1′ of FIG. 41, a cross section at the position sec2 is a cross section taken along line B1-B1′ of FIG. 42, and a cross section at the position sec3 is a cross section taken along line C1-C1′ of FIG. 43. Similarly, in the imaging device 1B illustrated in FIG. 39, a cross section at the position sec1 is a cross section taken along line A2-A2′ of FIG. 41, a cross section at the position sec2 is a cross section taken along line B2-B2′ of FIG. 42, and a cross section at the position sec3 is a cross section taken along line C2-C2′ of FIG. 43. In the imaging device 1B illustrated in FIG. 40, a cross section at the position sec1 is a cross section taken along line A3-A3′ of FIG. 41, a cross section at the position sec2 is a cross section taken along line B3-B3′ of FIG. 42, and a cross section at the position sec3 is a cross section taken along line C3-C3′ of FIG. 43.

As illustrated in FIGS. 39 and 43, the imaging device 1B shares a common pad electrode 1020 disposed across a plurality of the pixels 541 and one wiring L2 provided on the common pad electrode 1020. For example, in the imaging device 1B, there is a region in which the respective floating diffusions FD1 to FD4 of four pixels 541 are adjacent to each other via an element separation layer 16 in a plan view. The common pad electrode 1020 is provided in this region. The common pad electrode 1020 is disposed across four floating diffusions FD1 to FD4, and is electrically connected to each of four floating diffusions FD1 to FD4. The common pad electrode 1020 is made of, for example, a polysilicon film doped with an n-type impurity or a p-type impurity.

One wiring L2 (that is, floating diffusion contact) is provided on a central portion of the common pad electrode 1020. As illustrated in FIGS. 39 and 41 to 43, the wiring L2 provided on the central portion of the common pad electrode 1020 extends from a first substrate portion 10 to the upper substrate 2200B of the second substrate portion 20 through the lower substrate 2200A of the second substrate portion 20, and is connected to a gate electrode AG of the amplification transistor AMP via the wiring or the like provided on the upper substrate 2200B.

Furthermore, as illustrated in FIGS. 38 and 43, the imaging device 1B shares a common pad electrode 1100 disposed across a plurality of the pixels 541 and one wiring L10 provided on the common pad electrode 1100. For example, in the imaging device 1B, there is a region in which respective well layers WE of four pixels 541 are adjacent to each other via the element separation layer 16 in a plan view. The common pad electrode 1100 is provided in this region. The common pad electrode 1100 is disposed across the respective well layers WE of four pixels 541, and is electrically connected to the respective well layers WE of four pixels 541. As an example, the common pad electrode 1100 is disposed between one common pad electrode 1020 and another common pad electrode 1020, which are disposed in a Y-axis direction. In the Y-axis direction, the common pad electrodes 1020 and 1100 are alternately disposed. The common pad electrode 1100 is made of, for example, a polysilicon film doped with an n-type impurity or a p-type impurity.

One wiring L10 (that is, well contact) is provided on the central portion of the common pad electrode 1100. As illustrated in FIGS. 38, 40, and 41 to 43, the wiring L10 provided on the central portion of the common pad electrode 1100 extends from the first substrate portion 10 to the upper substrate 2200B of the second substrate portion 20 through the lower substrate 2200A of the second substrate portion 20, and is connected to the reference potential line that supplies the reference potential (for example, ground potential: 0 V) via the wiring or the like provided in the upper substrate 2200B.

The wiring L10 provided on the central portion of the common pad electrode 1100 is electrically connected to an upper surface of the common pad electrode 1100, an inner surface of a through hole provided in the lower substrate 2200A, and an inner surface of a through hole provided in the upper substrate 2200B. Accordingly, the well layer WE of the semiconductor substrate 11 of the first substrate portion 10, the well layer of the lower substrate 2200A and the well layer of the upper substrate 2200B of the second substrate portion 20 are connected to the reference potential (for example, ground potential: 0 V).

The imaging device 1B according to the modified example exhibits the same effects as those of the imaging device 1 according to the embodiment of the present disclosure described above. Furthermore, the imaging device 1B further includes the common pad electrodes 1020 and 1100 provided on a front surface 11a side of the semiconductor substrate 11 constituting the first substrate portion 10 and disposed across a plurality of (for example, four) pixels 541 adjacent to each other. The common pad electrode 1020 is electrically connected to the floating diffusions FD of four pixels 541. The common pad electrode 1100 is electrically connected to the well layers WE of four pixels 541. According to this, the wiring L2 connected to the floating diffusions FD can be made common for every four pixels 541. For every four pixels 541, the wiring L10 connected to the well layers WE can be made common. Accordingly, since the number of the wirings L2 and L10 can be reduced, the area of the pixel 541 can be reduced, and the size of the imaging device 1B can be reduced.

### 3. Second Embodiment

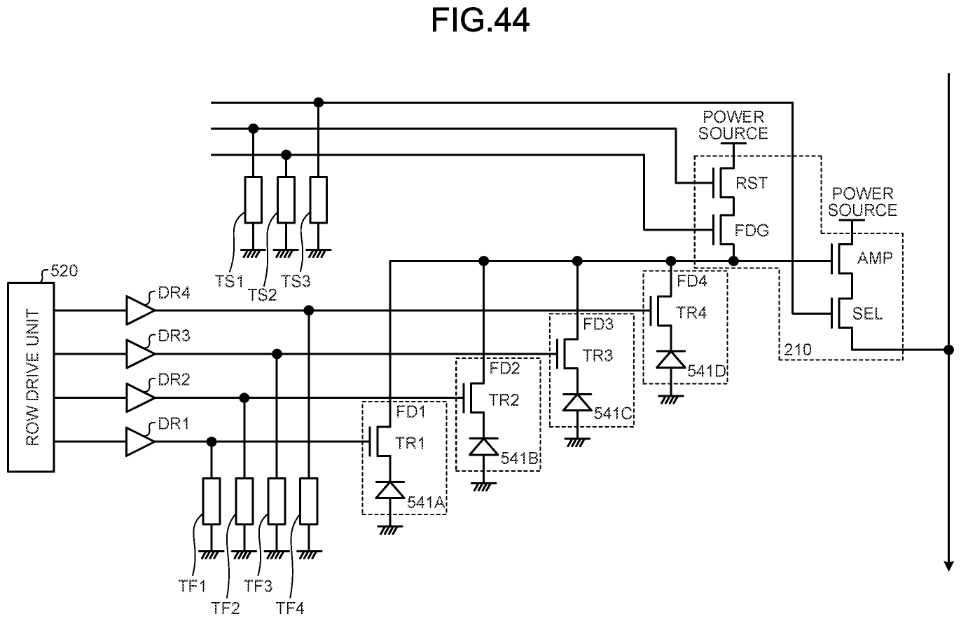

An imaging device 1A according to a second embodiment will be described with reference to FIGS. 44 to 57. The imaging device 1A according to the second embodiment of the present disclosure includes a plasma (process) induced damage (PID) protection element for preventing a damage (PID) from being caused by a plasma processing during the manufacturing. Note that, hereinafter, the same contents as those of the first embodiment will not be described, and only contents different from those of the first embodiment will be described.

The PID is generated when the wiring or the through electrode connected to the gate electrode of the transistor functions as an antenna during the plasma processing. Specifically, the PID is generated when electric charges in plasma are collected in an antenna and flow into a gate insulation film as a current. Since the PID generates a defect or a carrier trap level at an interface between the gate insulation film and the semiconductor substrate or in the gate insulation film, a threshold voltage of the transistor is varied.

Therefore, in the second embodiment of the present disclosure, the PID protection element is provided for each transistor (transfer transistor TR, selection transistor SEL, or the like) included in the imaging device 1A. Accordingly, the electric charges in plasma can flow into the substrate via the PID protection element instead of the gate insulation film, and variation of the threshold voltage of the transistor can be suppressed.

### 3.1. Functional Configuration Example of Imaging Device 1A

Here, a circuit configuration example of the imaging device 1A provided with the PID protection element will be described with reference to FIG. 44. FIG. 44 is a diagram illustrating a circuit configuration example of the imaging device 1A according to the second embodiment of the present disclosure. For example, FIG. 44 illustrates a circuit configuration in a case where the PID protection elements TF1 to TF4 and TS1 to TS3 are provided in the pixels 541A, 541B, 541C, and 541D and the pixel circuit 210 illustrated in FIG. 4, and the PID protection elements may be similarly provided in another circuit illustrated in FIG. 36. Note that, in a case where it is not necessary to distinguish the PID protection elements TF1 to TF4 and TS1 to TS3 from each other, identification numbers at the end of the reference numerals are omitted such as PID protection elements TF and TS.

As illustrated in FIG. 44, the gates of the transfer transistors TR1 to TR4 are connected to the row drive unit 520 via drivers DR1 to DR4, respectively.

The PID protection element TF is an element having a PN junction, and is, for example, a thyristor type protection element or a bipolar type protection element. One end of the PID protection element TF is connected to the gate of the transfer transistor TR, and the other end is grounded. The PID protection element TF protects the transfer transistor TR from the plasma damage (PID) generated during the plasma processing.

The PID protection element TS1 has one end connected to the gate of the reset transistor RST and the other end grounded. The PID protection element TS1 protects the reset transistor RST from the PID. The PID protection element TS2 has one end connected to the gate of the FD transfer transistor FDG and the other end grounded. The PID protection element TS2 protects the FD transfer transistor FDG from the PID. The PID protection element TS3 has one end connected to the gate of the selection transistor SEL and the other end grounded. The PID protection element TS3 protects the selection transistor SEL from the PID. The PID protection elements TS1 to TS3 are elements having a PN junction, and are, for example, thyristor type protection elements or bipolar type protection elements.

Note that, a floating diffusion (not illustrated) that temporarily holds data captured by the photodiode PD is connected to the gate of the amplification transistor AMP. The floating diffusion has a PN diode and has a function of protecting the amplification transistor AMP from the PID. As described above, in a case where the floating diffusion having the PN diode is connected to the amplification transistor AMP, an addition of the PID protection element protecting the amplification transistor AMP can be omitted, and an increase in the chip area of the imaging device 1A can be suppressed.

As described above, the PID protection elements TS1 to TS3 are protection elements protecting the pixel transistors (in the embodiment, among the pixel transistors, the reset transistor RST, the FD transfer transistor FDG, and the selection transistor SEL are included except the amplification transistor AMP).

### 3.2. Schematic Structure Example of Imaging Device 1A

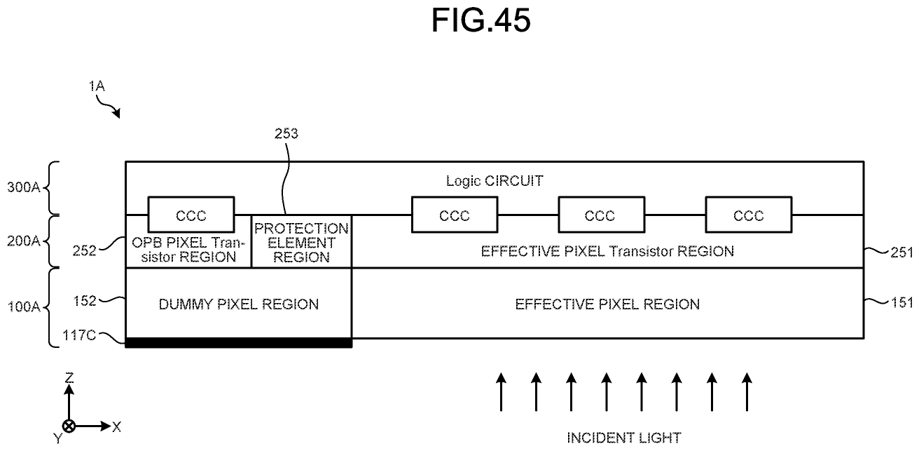

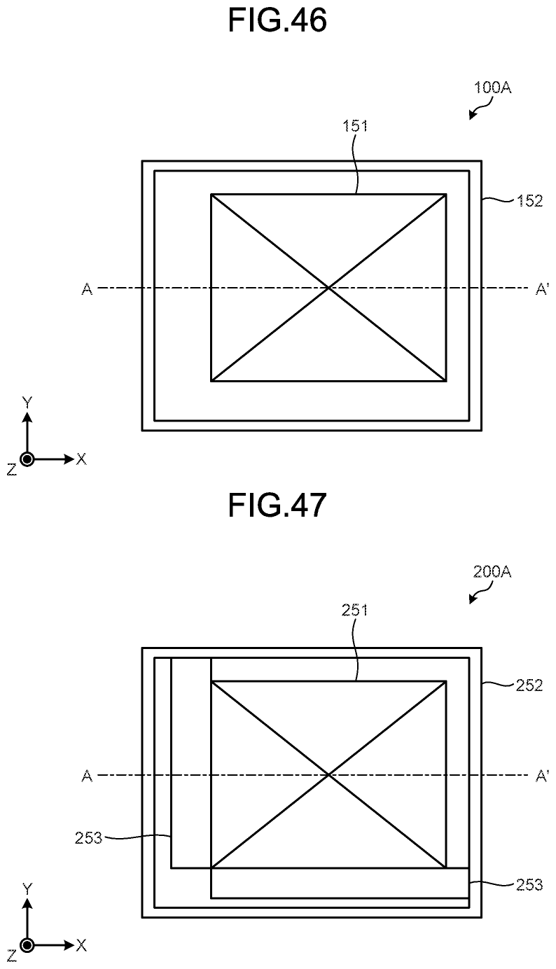

A schematic structure example of the imaging device 1A will be described with reference to FIGS. 45 to 47. FIG. 45 is a schematic longitudinal sectional view of the imaging device 1A. FIG. 46 is a view illustrating a schematic structure example of a first substrate 100A. FIG. 47 is a view illustrating a schematic structure example of a second substrate 200A. Note that, FIG. 45 schematically illustrates a cross-sectional configuration taken along line A-A′ illustrated in FIGS. 46 and 47. Furthermore, in FIGS. 45 to 47, illustration of a part of configurations such as the connection holes H1 and H2 (refer to FIG. 2) is omitted in order to simplify the description.

As illustrated in FIG. 45, the imaging device 1A includes a first substrate 100A, a second substrate 200A, and a third substrate 300A. The first substrate 100A to the third substrate 300A are stacked and formed. Furthermore, the first substrate 100A and the second substrate 200A are semiconductor substrates having a device layer and a wiring layer formed of, for example, silicon (Si). The third substrate 300A is a semiconductor substrate on which a logic circuit is formed. Furthermore, a multilayer wiring layer (not illustrated) is formed between the second substrate 200A and the third substrate 300A. The second substrate 200A and the third substrate 300A are connected to each other, for example, via a connection portion formed by a copper-copper connection (CCC) or the like. The imaging device 1A is, for example, a rear-surface irradiation imaging device which incident light enters from a lower side of FIG. 45.

Note that, hereinafter, a stacking direction of the first substrate 100A, the second substrate 200A, and the third substrate 300A is also referred to as a Z-axis direction. Furthermore, a direction in which the third substrate 300A is disposed in the Z-axis direction is defined as a positive direction of the Z-axis. Furthermore, two directions orthogonal to each other on a plane (horizontal plane) perpendicular to the Z-axis direction are also referred to as an X-axis direction and a Y-axis direction, respectively.

Furthermore, in the following description, in a case where the pixels 541A, 541B, 541C, and 541D are not distinguished from each other, the pixels are also simply referred to as a pixel 5410.

As illustrated in FIGS. 45 and 46, the first substrate 100A is provided with an effective pixel region 151 and a dummy pixel region 152.

In the effective pixel region 151, for example, effective pixels among a plurality of the pixels 5410 are provided in a matrix. The effective pixel region 151 corresponds to a region in which a subject image is formed via an optical system (not illustrated) such as a lens in the pixel array unit 540 of the imaging device 1A. That is, an image signal based on an electric signal read from an effective pixel included in the effective pixel region 151 in the pixel array unit 540 of the imaging device 1A is output from the imaging device 1A as a capturing result of an image.

The dummy pixel region 152 is, for example, a region provided around the effective pixel region 151 and shielded from light by metal or the like. In the dummy pixel region 152, an optical black (OPB) pixel and a dummy pixel among a plurality of the pixels 5410 are provided. The OPB pixel is a pixel in which the transfer transistor TR is connected to the pixel circuit 210 among a plurality of the pixels 5410, and is used for measuring a level of a pixel signal serving as a reference for correcting a black level, for example. The dummy pixel is a pixel in which the transfer transistor TR is not connected to the pixel circuit 210 among a plurality of the pixels 5410, and is provided between the OPB pixel and the effective pixel, for example. Accordingly, for example, incident light leaking into the OPB pixel can be reduced.

In the dummy pixel region 152 on the light incident surface of the first substrate 100A, a light shielding film 117C is formed to shield incident light from a Z-axis negative direction.

As illustrated in FIGS. 45 and 47, an effective pixel transistor region 251, an OPB pixel transistor region 252, and a protection element region 253 are provided in the second substrate 200A.

The effective pixel transistor region 251 is provided with an effective pixel circuit that outputs a pixel signal based on an electric charge output from an effective pixel in a pixel circuit 220. The OPB pixel transistor region 252 is provided with an OPB pixel circuit that outputs a pixel signal based on an electric charge output from an OPB pixel in a pixel circuit 220. Furthermore, the protection element region 253 is provided with the PID protection elements TF and TS.

Note that, the effective pixel transistor region 251 is disposed at an upper portion of the effective pixel region 151 in the Z-axis direction. Furthermore, the OPB pixel transistor region 252 and the protection element region 253 are disposed at an upper portion of the dummy pixel region 152 in the Z-axis direction. In other words, when viewed from the Z-axis positive direction, the effective pixel region 151 overlaps the effective pixel transistor region 251, and the dummy pixel region 152 overlaps the OPB pixel transistor region 252 and the protection element region 253.

### 3.3. Specific Configuration Example of Imaging Device 1A

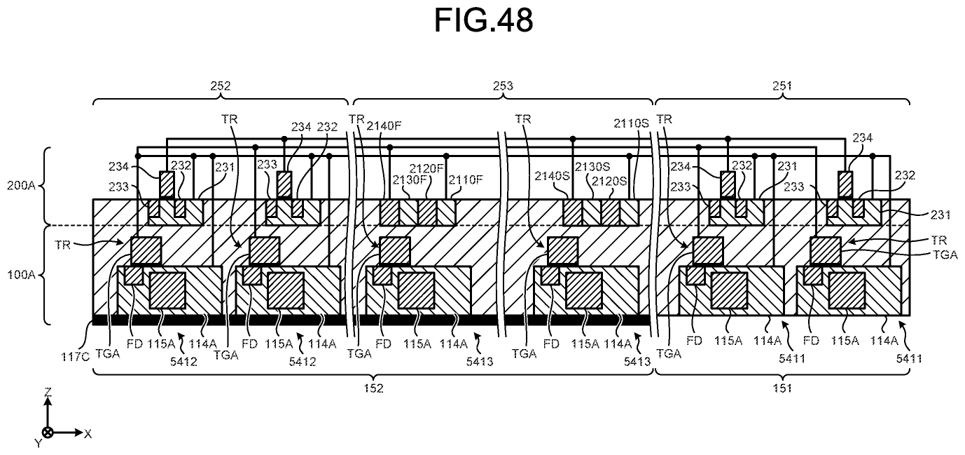

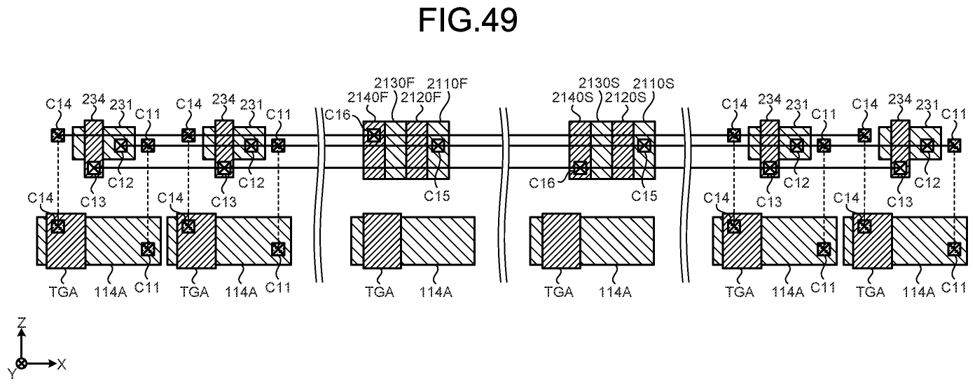

Next, a specific configuration example of the imaging device 1A according to the second embodiment of the present disclosure will be described with reference to FIGS. 48 and 49. FIG. 48 is a view for describing an example of a cross-sectional configuration of the imaging device 1A. FIG. 49 is a view for describing an example of a plane configuration of the first substrate 100A and the second substrate 200A.

FIGS. 48 and 49 schematically illustrate a positional relationship of the components for easy understanding, and some components such as the third substrate 300A, the light receiving lens, the color filter layer, and the wiring layer are not illustrated. Furthermore, in FIG. 49, illustration of the insulation film is omitted. As described above, the cross-sectional configuration and the plane configuration illustrated in FIGS. 48 and 49 may be different from the actual cross section and the plane of the imaging device 1A. Note that, in FIGS. 48 and 49, the connection relationship between the components is indicated by a solid line. Furthermore, the upper view of FIG. 49 schematically illustrates a top view of the second substrate 200A, and the lower view of FIG. 49 schematically illustrates a top view of the first substrate 100A.

The first substrate 100A includes, for example, a semiconductor layer. In the semiconductor layer of the first substrate 100A, a plurality of effective pixels 5411 are formed in the effective pixel region 151. Furthermore, a plurality of OPB pixels 5412 and a plurality of dummy pixels 5413 are formed in the dummy pixel region 152. Since the configurations of each of the effective pixels 5411, each of the OPB pixels 5412, and each of the dummy pixels 5413 are the same except for the presence or absence of the wiring, the configuration of the pixel 5410 will be described without distinguishing them.

The photodiode PD of the pixel 5410 includes, for example, a PN junction photodiode having an N-type semiconductor region 115A of the first substrate 100A and a P-type semiconductor region 114A formed so as to cover the N-type semiconductor region 115A. Note that, each photodiode PD is electrically separated by a pixel separation portion (not illustrated). A through contact C11 connected to an upper layer wiring (not illustrated) is provided in the P-type semiconductor region 114A of the effective pixel 5411 and the OPB pixel 5412. The P-type semiconductor region 114A of the photodiode PD is connected to a first P-type semiconductor region 2110F of the PID protection element TF via the through contact C11.

The first substrate 100A includes the transfer transistor TR including a gate electrode TGA and an N-type source region as the floating diffusion FD. The transfer transistor TR is configured as, for example, a metal oxide semiconductor (MOS) type field effect transistor (MOSFET). A through contact C14 connected to an upper layer wiring (not illustrated) is provided in the gate electrode TGA of the transfer transistor TR. The gate electrode TGA is connected to a second N-type semiconductor region 2140F of the PID protection element TF via a through contact C14.

In the dummy pixel region 152 on the light incident surface of the first substrate 100A (region in which the OPB pixel 5412 and the dummy pixel 5413 are formed), a light shielding film 117C is formed to shield incident light from a Z-axis negative direction.

The second substrate 200A includes, for example, a semiconductor layer and a wiring layer (not illustrated). In the semiconductor layer of the second substrate 200A, an effective pixel circuit corresponding to the effective pixel 5411 is provided in the effective pixel transistor region 251. In the OPB pixel transistor region 252, an OPB pixel circuit corresponding to the OPB pixel 5412 is provided. The PID protection elements TF and TS are provided in the protection element region 253.

FIGS. 48 and 49 illustrate the selection transistors SEL of the effective pixel circuit and the OPB pixel circuit, and do not illustrate the amplification transistor AMP, the reset transistor RST, and the FD transfer transistor FDG.

Note that, since the configurations of the selection transistors SEL of the effective pixel circuit and the OPB pixel circuit are the same, the configuration of the selection transistor SEL will be described without distinguishing the effective pixel circuit from the OPB pixel circuit. Furthermore, in order to distinguish the components of the PID protection elements TF and TS from each other, an identification symbol F is given to the end of the symbol of the component of the PID protection element TF, and an identification symbol S is given to the end of the symbol of the component of the PID protection element TS. In a case where it is not necessary to distinguish the components of the PID protection elements TF and TS from each other, the identification symbols at the end of the symbols of the components of the PID protection elements TF and TS are omitted.

The selection transistor SEL includes an N-type source region 233 and an N-type drain region 232, which are provided in a P-type semiconductor region 231 of the second substrate 200A. A gate electrode 234 of the selection transistor SEL is disposed on the second substrate 200A between the source region 233 and the drain region 232. A contact C12 connected to an upper layer wiring (not illustrated) is provided in the P-type semiconductor region 231. The P-type semiconductor region 231 is connected to a P-type semiconductor region 2110S of the PID protection element TS via the contact C12. A contact C13 connected to an upper layer wiring (not illustrated) is provided in the gate electrode 234. The gate electrode 234 is connected to a second N-type semiconductor region 2140S of the PID protection element TS via the contact C13.

The PID protection elements TF and TS provided in the protection element region 253 of the second substrate 200A have, for example, a first P-type semiconductor region 2110, a first N-type semiconductor region 2120, a second P-type semiconductor region 2130, and a second N-type semiconductor region 2140 in order in the X-axis positive direction. As described above, the PID protection elements TF and TS have a PN-PN junction structure in the horizontal direction (X-axis direction in FIGS. 48 and 49) of the second substrate 200A.

Note that, the PID protection elements TF and TS may have an NP-NP junction structure instead of the PN-PN junction structure. Furthermore, the first P-type semiconductor region 2110, the first N-type semiconductor region 2120, the second P-type semiconductor region 2130, and the second N-type semiconductor region 2140 may be disposed side by side (in a horizontal direction) on the horizontal plane of the second substrate 200A, and may have the PN-PN junction structure in the Y-axis direction, for example.

When the first substrate 100A to the third substrate 300A are stacked, a thickness (length in the stacking direction) of the imaging device 1A increases. Therefore, there is a demand for reducing a thickness of each substrate. In particular, there is a demand for reducing the thickness of the substrate like the substrate to be stacked on the substrate. Therefore, in the second embodiment of the present disclosure, the first P-type semiconductor region 2110, the first N-type semiconductor region 2120, the second P-type semiconductor region 2130, and the second N-type semiconductor region 2140 of the PID protection elements TF and TS are disposed side by side on the horizontal plane of the second substrate 200A. Accordingly, the thicknesses of the PID protection elements TF and TS can be reduced, and the thickness of the second substrate 200A can also be reduced.

### 3.4. Example of Manufacturing Process of Imaging Device 1A

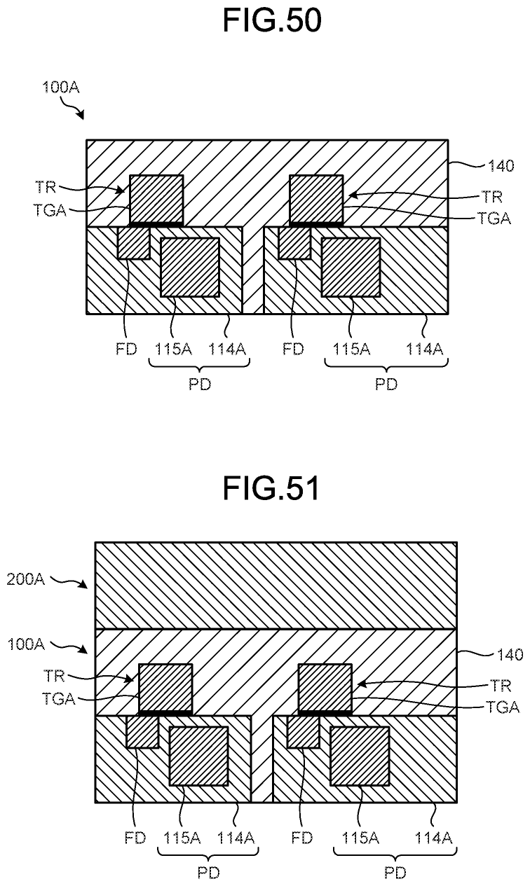

Next, an example of a manufacturing process of the imaging device 1A according to the second embodiment of the present disclosure will be described with reference to FIGS. 50 to 55. FIGS. 50 to 55 are flow diagrams for describing an example of a procedure of a manufacturing process of the imaging device 1A according to the second embodiment of the present disclosure. Note that, FIGS. 50 to 55 illustrate a part of a cross section of the imaging device 1A.

As illustrated in FIG. 50, the photodiode PD including the N-type semiconductor region 115A and the P-type semiconductor region 114A, the gate electrode TGA of the transfer transistor TR, and the source region as the floating diffusion FD are formed in the first substrate 100A. The gate electrode TGA and the floating diffusion FD are covered with an insulation film 140.

Next, as illustrated in FIG. 51, the first substrate 100A and the second substrate 200A which is a P-type silicon substrate or the like, are bonded to each other. At this time, a pressure of 0.1 MPa to several MPa is applied, and heat treatment is performed at about 350° C. to 600° C. As a result, the first substrate 100A and the second substrate 200A are bonded to each other via the insulation film 140. Note that, before the first substrate 100A and the second substrate 200A are bonded to each other, the bonding surface of the first substrate 100A and the bonding surface of the second substrate 200A may be each subjected to O₂ plasma treatment.

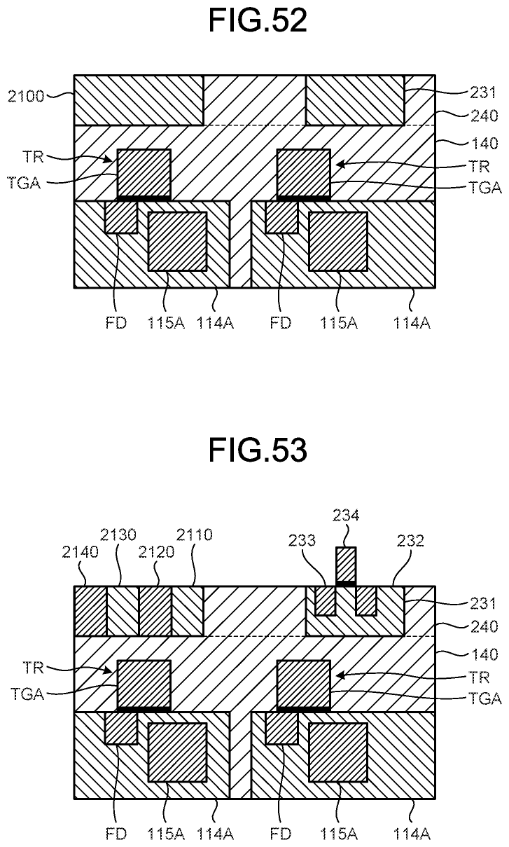

Subsequently, as illustrated in FIG. 52, the second substrate 200A is ground to have a thickness of 0. several μm to several μm by chemical mechanical polishing (CMP), and element separation is performed on the second substrate 200A while leaving the region 2100 in which the pixel circuit such as the selection transistor SEL and the PID protection elements TF and TS are formed. Specifically, a resist pattern is formed by photolithography in a region in which the pixel circuit and the PID protection elements TF and TS are formed, and the other region is etched by dry etching. After the resist pattern is ashed, an insulation film 240 such as a silicon oxide film is formed by a CVD method and a portion removed by etching is backfilled with the second substrate 200A. An excessive insulation film 240 is removed by the CMP to expose the front surface of the second substrate 200A.

As illustrated in FIG. 53, the selection transistor SEL and the PID protection elements TF and TS are formed in the second substrate 200A. Specifically, a gate oxide film is formed on the front surface of the second substrate 200A by a thermal oxidation method. A polysilicon film or the like is formed by the CVD method, a resist pattern is formed by the photolithography, the polysilicon film is etched, and the resist pattern is ashed to form the gate electrode 234. Phosphorus or arsenic is implanted into the second substrate 200A on opposite sides of the gate electrode 234 by ion implantation, and heat treatment is performed by a rapid thermal annealing (RTA) method to form the source region 233 and the drain region 232. Furthermore, similarly, phosphorus or arsenic is implanted, by ion implantation, into the region 2100 of the second substrate 200A in which the PID protection elements TF and TS are formed, and heat treatment is performed by the rapid thermal annealing (RTA) method, so that the first P-type semiconductor region 2110 and the second P-type semiconductor region 2130, and the first N-type semiconductor region 2120 and the second N-type semiconductor region 2140 are formed. As a result, the PID protection elements TF and TS are formed. Note that, the source region 233, the drain region 232, and the PID protection elements TF and TS are formed by being simultaneously processed.

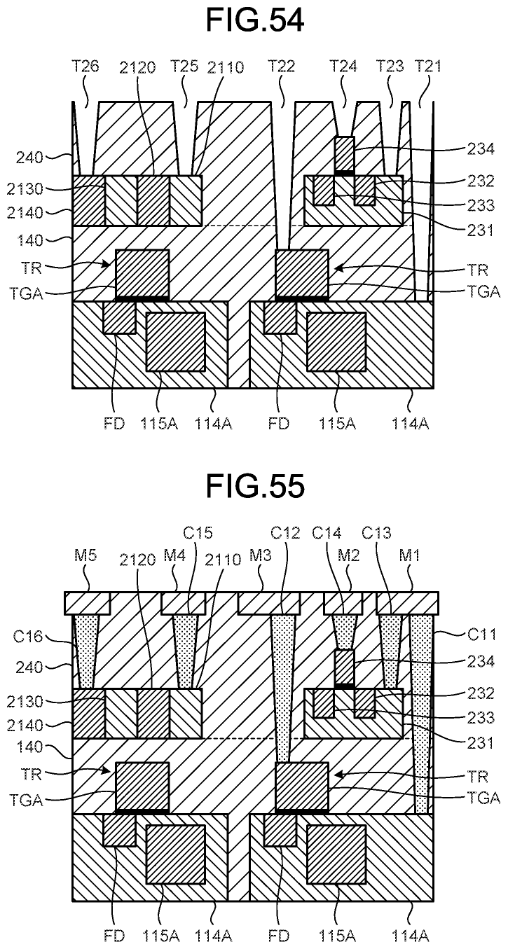

As illustrated in FIG. 54, through holes T21 to T26 are formed. Specifically, the insulation film 240 covering the selection transistor SEL is further formed by the CVD method, and the front surface of the insulation film 240 is planarized by the CMP. A resist pattern is formed on the front surface of the insulation film 240 by the photolithography, and the through holes T21 to T26 reaching the N-type semiconductor region 115A, the gate electrode TGA, the P-type semiconductor region 231, the gate electrode 234, the first P-type semiconductor region 2110, and the second N-type semiconductor region 2140 are formed by dry etching.

Next, as illustrated in FIG. 55, after the through holes T21 to T26 are formed, the through holes are filled with a W film or the like by the CVD method, and the excessive W film is removed by the CMP to form contacts C11 to C16. After that, wirings M1 to M5 are formed, the third substrate 300A in which the logic circuit is formed is bonded, and then the manufacturing process of the imaging device 1A is ended.

### 3.5. Comparative Example

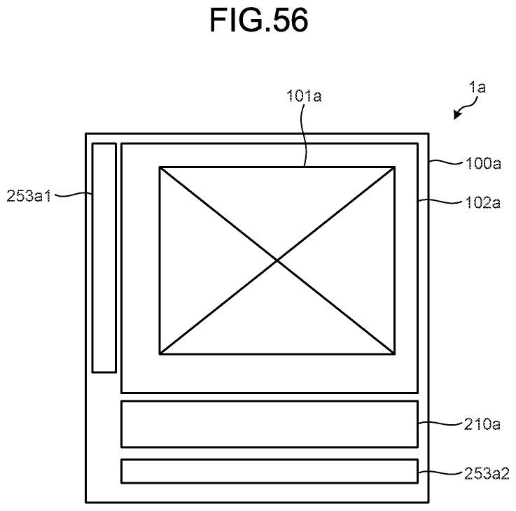

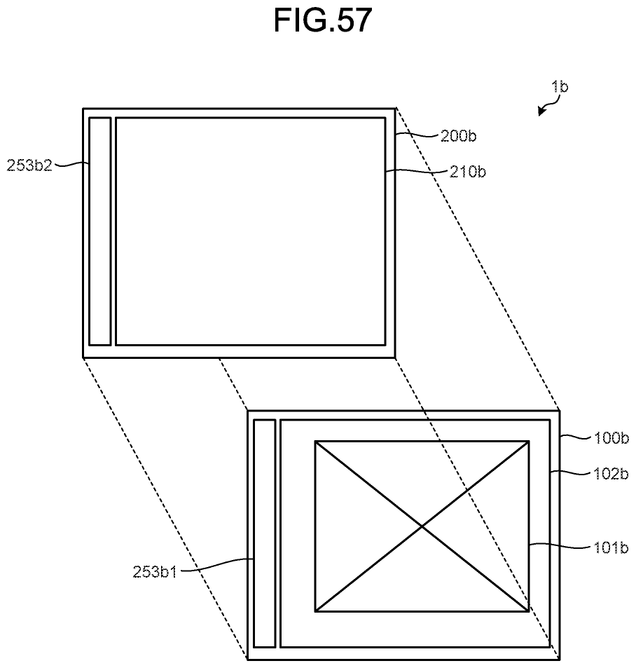

A configuration of the comparative example is compared with the configuration of the second embodiment with reference to FIGS. 56 and 57. FIG. 56 is a view illustrating an imaging device 1a according to the comparative example. The imaging device 1a illustrated in FIG. 56 is different from the configuration of the second embodiment in that an effective pixel region 101a, a dummy pixel region 102a, and a pixel circuit 210a are formed in one substrate 100a. FIG. 57 is a view illustrating an imaging device 1b according to the comparative example. The imaging device 1b illustrated in FIG. 57 is the same as the configuration of the second embodiment in that an effective pixel region 101b, a dummy pixel region 102b, and a pixel circuit 210b are formed in different substrates, but the arrangement of the PID protection elements TF and TS is different. Note that, illustration of the substrate in which a logic circuit is formed is omitted in FIGS. 56 and 57.

As illustrated in FIG. 56, in a case where the effective pixel region 101a, the dummy pixel region 102a (hereinafter, referred to as a pixel region), and the pixel circuit 210a are formed in one substrate 100a, for example, the dummy pixel region 102a is disposed around the effective pixel region 101a, and further, the pixel circuit 210a is disposed around the dummy pixel region 102a. In a case where the PID protection elements TF and TS are further provided in the substrate 100a, for example, a protection element region 253a1 for forming the PID protection element TF protecting the transfer transistor TR is disposed near the pixel region of the substrate 100a. Furthermore, a protection element region 253a2 for forming the PID protection element TS protecting each transistor of the pixel circuit 210a is disposed near the pixel circuit 210a. As described above, in a case where the PID protection elements TF and TS are formed, the PID protection elements TF and TS are generally disposed near a transistor to be protected from the viewpoint of routing the wiring and the like.

However, when the pixel 5410, the pixel circuit 210a, and the PID protection elements TF and TS are formed in one substrate 100a, the chip area of the imaging device 1a increases.

Therefore, for example, it is conceivable to reduce the chip area of the imaging device 1b by stacking a first substrate 100b forming the pixel 5410 and a second substrate 200b forming the pixel circuit 210b as in the imaging device 1b illustrated in FIG. 57.

Here, as described above, in a case where the PID protection elements TF and TS are formed, the PID protection elements TF and TS are generally disposed near a transistor to be protected from the viewpoint of routing the wiring and the like. Therefore, when the first substrate 100b that simply forms the pixel 5410 and the second substrate 200b that forms the pixel circuit 210b are separated, as illustrated in FIG. 57, the PID protection element TF protecting the transfer transistor TR is disposed in a protection element region 253b1 of the first substrate 100b, and the PID protection element TS protecting each transistor of the pixel circuit 210b is disposed in a protection element region 253b2 of the second substrate 200b.

In this case, the protection element region 253b1 of the first substrate 100b is disposed around the dummy pixel region 102b. Therefore, the protection element region 253b2 of the second substrate 200b is disposed around the pixel circuit 210b, and the chip areas are increased by the areas of the protection element regions 253b1 and 253b2. As described above, it is not possible to suppress an increase in the chip area only by stacking the substrates.

In the imaging device 1A according to the second embodiment of the present disclosure, the first substrate 100A in which the pixel 5410 is formed and the second substrate 200A in which the pixel circuit 210 is formed are stacked. At this time, focusing on the point that the pixel circuit 210 corresponding to a dummy pixel 5423 is not formed in the second substrate 200A, the PID protection elements TF and TS are formed in a region (empty region) of the second substrate 200A in which the pixel circuit 210 is not formed. In this manner, in the second substrate 200A, not only the PID protection element TS protecting each transistor of the pixel circuit 210 but also the PID protection element TF protecting the transfer transistor TR is formed in the empty region of the second substrate 200A. In other words, by forming the PID protection element TF in the second substrate 200A different from the first substrate 100A in which the transfer transistor TR to be protected is formed, the area of the first substrate 100A can be reduced, and an increase in the chip area of the imaging device 1A can be suppressed.

### 4. Modified Example

### 4.1. Modified Example 2-1

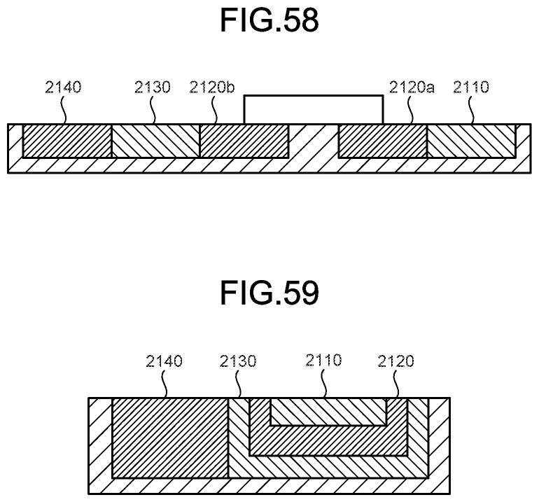

A modified example of the PID protection elements TF and TS of the imaging device 1A according to the second embodiment will be described with reference to FIG. 58. FIG. 58 is a schematic view for describing the modified example of the PID protection elements TF and TS.

The PID protection elements TF and TS of the modified example include two first N-type semiconductor regions 2120a and 2120b. Two first N-type semiconductor regions 2120a and 2120b are connected to each other by the wiring. In this point, the configurations of the PID protection elements TF and TS of the modified example are different from those of the PID protection elements TF and TS described in the second embodiment.

As described above, even when the first N-type semiconductor region 2120 is divided into two and connected by the wiring, the same effects as those described in the second embodiment can be obtained. Moreover, by dividing the semiconductor region, the PID protection elements TF and TS can be disposed in the empty space of the second substrate 200A, a degree of freedom of the element layout can be increased, and an increase in the chip area can be suppressed.

Note that, here, a case where the first N-type semiconductor region 2120 is divided into two has been described, but the present disclosure is not limited thereto. For example, the first P-type semiconductor region 2110 and the second P-type semiconductor region 2130, and the second N-type semiconductor region 2140 may be divided into two. Furthermore, the number of divisions is not limited to two, and may be three or more.

### 4.2. Modified Example 2-2

A modified example of the PID protection elements TF and TS of the imaging device 1A according to the second embodiment will be described with reference to FIG. 59. FIG. 59 is a schematic view for describing the modified example of the PID protection elements TF and TS.

The PID protection elements TF and TS of the modified example have a triple well structure of PNP junction. In the example illustrated in FIG. 59, the first N-type semiconductor region 2120 is provided in the second P-type semiconductor region 2130, and the first P-type semiconductor region 2110 is provided in the first N-type semiconductor region 2120. In this point, the configurations of the PID protection elements TF and TS of the modified example are different from those of the PID protection elements TF and TS described in the second embodiment. As described above, even when the PID protection elements TF and TS have the triple well structure of PNP junction, the same effects as those described in the second embodiment can be obtained.

Note that, here, a case where the PID protection elements TF and TS have the triple well structure of PNP junction has been described, but the present disclosure is not limited thereto. For example, the PID protection elements TF and TS may have a triple well structure of NPN junction.

### 4.3. Modified Example 2-3

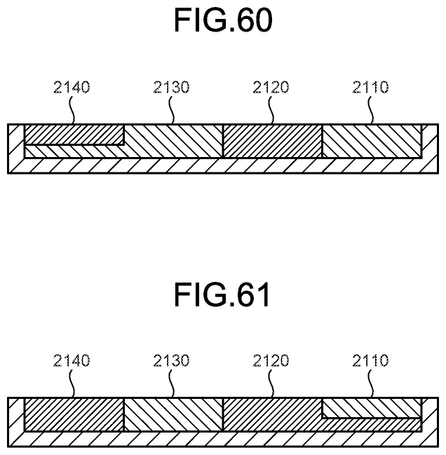

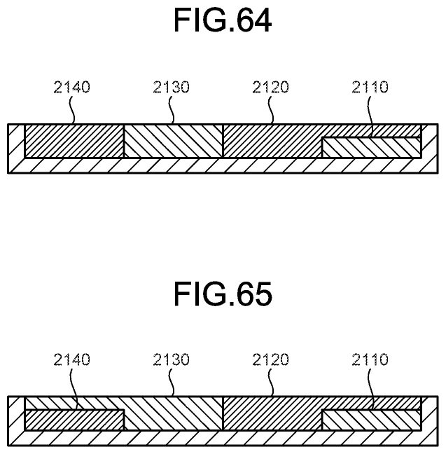

A modified example of the PID protection elements TF and TS of the imaging device 1A according to the second embodiment will be described with reference to FIGS. 60 to 65. FIGS. 60 to 65 are schematic views for describing the modified example of the PID protection elements TF and TS.

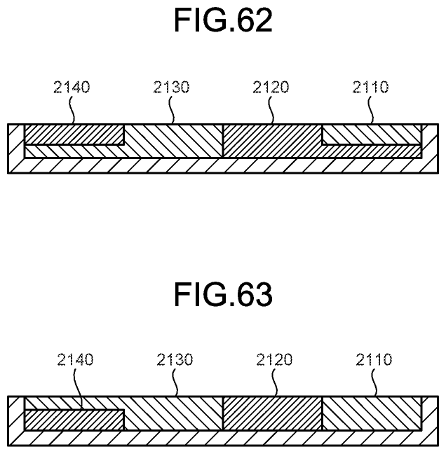

The PID protection elements TF and TS of the modified example have a double well structure of PNP junction. In the example illustrated in FIG. 60, the second N-type semiconductor region 2140 is provided on an upper layer of the second P-type semiconductor region 2130. In the example illustrated in FIG. 61, the first P-type semiconductor region 2110 is provided on an upper layer of the first N-type semiconductor region 2120. In the example illustrated in FIG. 62, the second N-type semiconductor region 2140 is provided on an upper layer of the second P-type semiconductor region 2130, and the first P-type semiconductor region 2110 is provided on an upper layer of the first N-type semiconductor region 2120.

Alternatively, as illustrated in FIGS. 63 to 65, the first P-type semiconductor region 2110 and/or the second N-type semiconductor region 2140 may be provided on a lower layer of the first N-type semiconductor region 2120 and/or the second P-type semiconductor region 2130.

As described above, the configurations of the PID protection elements TF and TS of the modified example are different from the configurations of the PID protection elements TF and TS described in the second embodiment in that the double well structure in which a second conductivity type (N type or P type) well is formed on an upper layer or a lower layer of a first conductivity type (P type or N type) well is provided. As described above, even when the PID protection elements TF and TS have the double well structure, the same effects as those described in the second embodiment can be obtained.

### 4.4. Modified Example 2-4

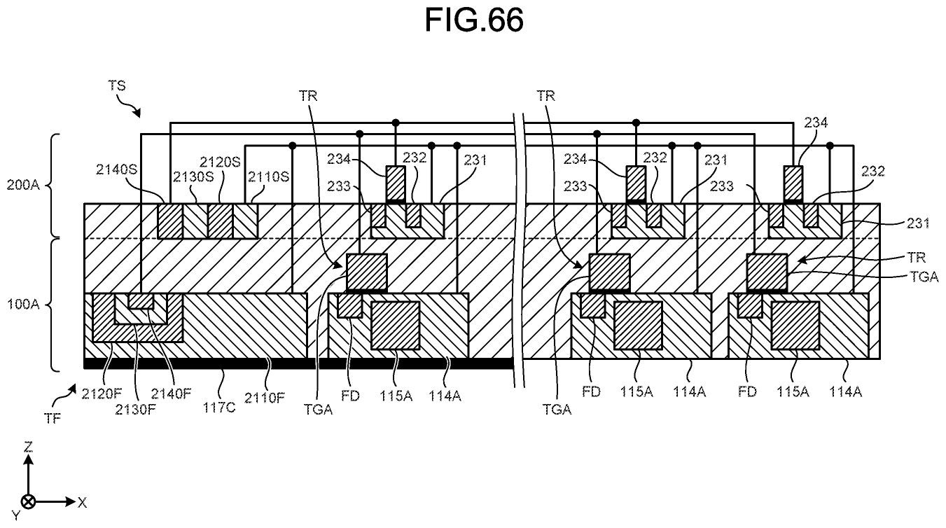

A modified example of the imaging device 1A according to the second embodiment will be described with reference to FIG. 66. FIG. 66 is a schematic view for describing the modified example of the imaging device 1A. FIG. 66 is a schematic longitudinal sectional view of the imaging device 1A, and corresponds to FIG. 48 described in the second embodiment.

In the modified example, the PID protection elements TF and TS are provided in the first substrate 100A and the second substrate 200A of the imaging device 1A. In this point, the configuration of the imaging device 1A is different from the configuration of the imaging device 1A described in the second embodiment. In FIG. 66, the PID protection element TF protecting the transfer transistor TR is formed in the first substrate 100A, and the PID protection element TS protecting each transistor of the pixel circuit 210 is formed in the second substrate 200A. Here, for example, the PID protection element TF has a triple well structure of NPN junction.

For example, it is assumed that the area of the second substrate 200A becomes larger than the area of the first substrate 100A when the number of elements formed in the second substrate 200A (for example, the number of transistors of the pixel circuit 210) is large, and the PID protection elements TF and TS are formed in the second substrate 200A. In this case, the PID protection elements TF and TS are disposed in the first substrate 100A and the second substrate 200A, respectively, so that the area of the first substrate 100A is substantially equal to the area of the second substrate 200A. Accordingly, an increase in the chip area of the imaging device 1A can be suppressed.

Note that, in FIG. 66, the PID protection element TF protecting the transfer transistor TR is formed in the first substrate 100A, and the PID protection element TS protecting each transistor of the pixel circuit 210 is formed in the second substrate 200A, but the present disclosure is not limited to this. The PID protection elements TF and TS may be disposed so that the difference between the area of the first substrate 100A and the area of the second substrate 200A decreases in accordance with the number of transistors (the number of elements) formed in the imaging device 1A or the area of the substrate necessary for element formation. For example, a part of the PID protection element TS protecting each transistor of the pixel circuit 210 may be formed in the first substrate 100A, and a part of the PID protection element TF protecting the transfer transistor TR may be formed in the second substrate 200A.

### 4.5. Modified Example 2-5

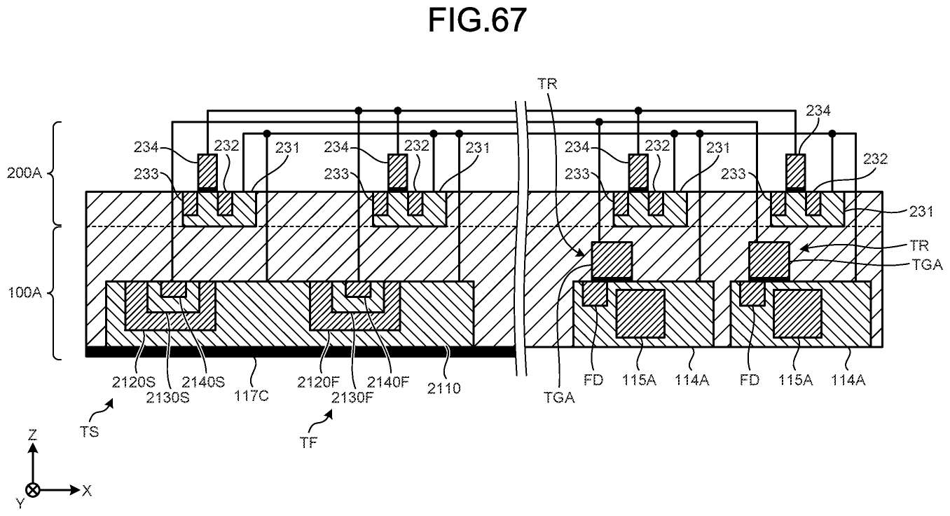

A modified example of the imaging device 1A according to the second embodiment will be described with reference to FIG. 67. FIG. 67 is a schematic view for describing the modified example of the imaging device 1A. FIG. 67 is a schematic longitudinal sectional view of the imaging device 1A, and corresponds to FIG. 48 described in the second embodiment.

In the modified example, the PID protection elements TF and TS are provided in the first substrate 100A of the imaging device 1A. In this point, the configuration of the imaging device 1A is different from the configuration of the imaging device 1A described in the second embodiment. In FIG. 67, both the PID protection element TF protecting the transfer transistor TR and the PID protection element TS protecting each transistor of the pixel circuit 210 are formed in the first substrate 100A. Here, for example, the first N-type semiconductor region 2120 is formed in the first P-type semiconductor region 2110 of the PID protection elements TF and TS, and the second P-type semiconductor region 2130 is formed in the first N-type semiconductor region 2120. The second N-type semiconductor region 2140 is formed in the second P-type semiconductor region 2130. Furthermore, the PID protection elements TF and TS share the first P-type semiconductor region 2110.

For example, it is assumed that the area of the second substrate 200A becomes larger than the area of the first substrate 100A when the number of elements formed in the second substrate 200A (for example, the number of transistors of the pixel circuit 210) is large, and the PID protection elements TF and TS are formed in the second substrate 200A. In this case, the PID protection elements TF and TS are disposed in the first substrate 100A, so that the area of the first substrate 100A is substantially equal to the area of the second substrate 200A. In this way, the PID protection elements TF and TS are disposed so that the difference between the area of the first substrate 100A and the area of the second substrate 200A decreases in accordance with the number of transistors (the number of elements) formed in the imaging device 1A or the area of the substrate necessary for element formation. Accordingly, an increase in the chip area of the imaging device 1A can be suppressed.

Note that, for example, in a case where a plurality of the semiconductor substrates are stacked instead of the second substrate 200 (refer to Modified Example 1-8), the PID protection elements TF and TS according to the above-described second embodiment and Modified Examples 2-1 to 2-5 may be provided over a plurality of the semiconductor substrates of the second substrate 200.

### 5. Applied Example

The technology according to the second embodiment and the modified examples can be applied to various products. For example, the technology can be applied to a semiconductor memory such as a dynamic random access memory (DRAM) or a static random access memory (SRAM), or a semiconductor device such as a system on chip (SoC).

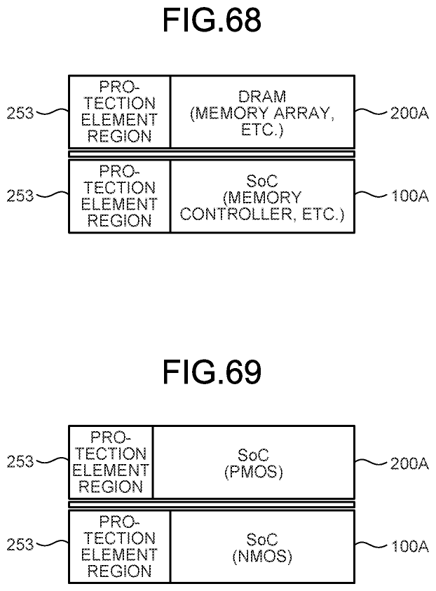

FIG. 68 is a diagram for describing an example of application to the semiconductor memory (DRAM). In the example of FIG. 68, an SoC such as a memory controller is disposed in the first substrate 100A, and the DRAM such as a memory array is disposed in the second substrate 200A. In this case, when the PID protection element protecting the transistor formed in the SoC or the DRAM from the PID is provided, as illustrated in FIG. 68, the PID protection elements TF and TS are disposed in the protection element regions 253 of the first substrate 100A and the second substrate 200A, respectively. At this time, by disposing the PID protection elements TF and TS in the first substrate 100A and the second substrate 200A so that the areas of the first substrate 100A and the second substrate 200A are substantially equal to each other, an increase in the chip area of the semiconductor memory can be suppressed.

Furthermore, as illustrated in FIG. 69, application to the SoC is also possible. FIG. 69 is a diagram for describing an example of application to the SoC. In FIG. 69, the first substrate 100A is an SoC using NMOS, and the second substrate 200A is an SoC using PMOS. As described above, in a case where a plurality of the SoCs are stacked, when the PID protection element protecting the transistors formed in the first substrate 100A and the second substrate 200A from the PID is provided, as illustrated in FIG. 69, the protection element regions 253 forming the PID protection elements TF and TS are disposed in the first substrate 100A and the second substrate 200A, respectively. At this time, by disposing the PID protection elements TF and TS in the first substrate 100A and the second substrate 200A so that the areas of the first substrate 100A and the second substrate 200A are substantially equal to each other, an increase in the chip area of the semiconductor memory can be suppressed.

Note that, here, a case where the protection element region 253 is provided on each of the first substrate 100A and the second substrate 200A has been described, but the present disclosure is not limited thereto. The protection element region 253 may be provided in at least one of the first substrate 100A and the second substrate 200A. Furthermore, here, the number of substrates to be stacked is two, but the present disclosure is not limited thereto. The number of substrates to be stacked may be three or more. In this case, the semiconductor element (for example, the transistor) having the gate electrode is formed in at least one of a plurality of the substrates, and the PID protection element protecting the semiconductor element is formed in at least one of a plurality of the substrates.

As described above, the technology according to the second embodiment and the modified examples can be applied not only to the imaging device but also to the semiconductor device such as the semiconductor memory.

### 6. Application Example

### 6.1. Example of Application to Imaging System

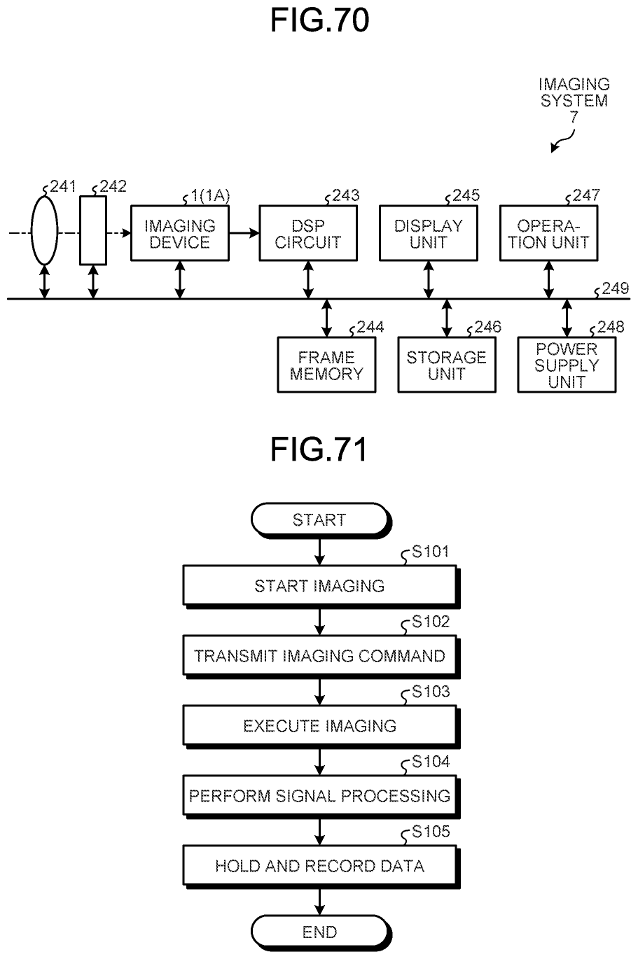

FIG. 70 illustrates an example of a schematic configuration of an imaging system 7 including an imaging device 1 (1A) according to the embodiment and the modified examples thereof.

The imaging system 7 is, for example, an electronic device, the electronic device being an imaging device such as a digital still camera or a video camera, or a portable terminal device such as a smartphone or a tablet terminal. The imaging system 7 includes, for example, the imaging device 1 according to the embodiment and the modified examples thereof, a DSP circuit 243, a frame memory 244, a display unit 245, a storage unit 246, an operation unit 247, and a power supply unit 248. In the imaging system 7, the imaging device 1 according to the embodiment and the modified examples thereof, the DSP circuit 243, the frame memory 244, the display unit 245, the storage unit 246, the operation unit 247, and the power supply unit 248 are connected to each other via a bus line 249.

The imaging device 1 (1A) according to the embodiment and the modified examples thereof outputs image data corresponding to incident light. The DSP circuit 243 is a signal processing circuit that processes a signal (image data) output from the imaging device 1 according to the embodiment and the modified examples thereof. The frame memory 244 temporarily holds the image data processed by the DSP circuit 243 in units of frames. The display unit 245 includes, for example, a panel-type display device such as a liquid crystal panel or an organic electro luminescence (EL) panel, and displays a moving image or a still image captured by the imaging device 1 according to the embodiment and the modified examples thereof. The storage unit 246 stores image data of a moving image or a still image captured by the imaging device 1 according to the embodiment and the modified examples thereof in a storage medium such as a semiconductor memory or a hard disk. The operation unit 247 issues operation commands for various functions of the imaging system 7 in accordance with an operation by a user. The power supply unit 248 appropriately supplies various power sources serving as an operation power source of the imaging device 1 according to the embodiment and the modified examples thereof, the DSP circuit 243, the frame memory 244, the display unit 245, the storage unit 246, and the operation unit 247 to these supply targets.

Next, an imaging procedure in the imaging system 7 will be described.

FIG. 71 illustrates an example of a flowchart of an imaging operation in the imaging system 7. The user gives an instruction on a start of imaging by operating the operation unit 247 (Step S101). Then, the operation unit 247 transmits an imaging command to the imaging device 1 (Step S102). When the imaging command is received, the imaging device 1 (specifically, a system control circuit 36) executes imaging by a predetermined imaging method (Step S103).

The imaging device 1 outputs image data obtained by imaging to the DSP circuit 243. Here, the image data is data for all the pixels of the pixel signal generated on the basis of the electric charge temporarily held in the floating diffusion FD. The DSP circuit 243 performs predetermined signal processing (for example, noise reduction processing or the like) on the basis of the image data input from the imaging device 1 (Step S104). The DSP circuit 243 causes the frame memory 244 to hold the image data subjected to predetermined signal processing, and the frame memory 244 causes the storage unit 246 to store the image data (Step S105). In this manner, imaging in the imaging system 7 is performed.

In the application example, the imaging device 1 according to the embodiment and the modified examples thereof is applied to the imaging system 7. Accordingly, since the imaging device 1 can be downsized or made to have high definition, it is possible to provide a small or high definition imaging system 7.

### 6.2. Example of Application to Product System

The technology according to the present disclosure (present technology) can be applied to various products. For example, the technology according to the present disclosure may be realized as a device mounted on any type of moving body such as an automobile, an electric automobile, a hybrid electric automobile, a motorcycle, a bicycle, a personal mobility, an airplane, a drone, a ship, and a robot.

[6.2.1. Moving Body Control System]

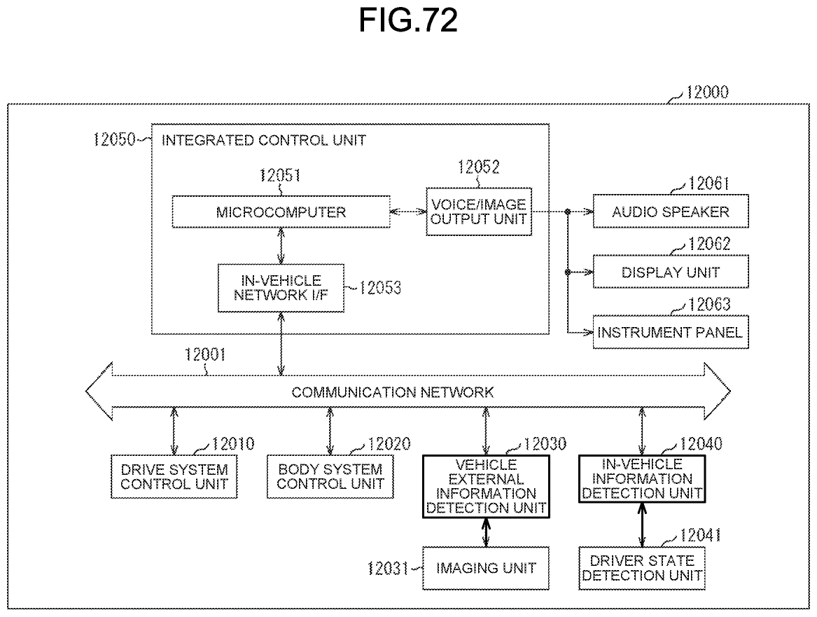

FIG. 72 is a block diagram illustrating a schematic configuration example of a vehicle control system which is an example of a moving body control system to which the technology according to the present disclosure can be applied.

A vehicle control system 12000 includes a plurality of electronic control units connected via a communication network 12001. In the example illustrated in FIG. 72, the vehicle control system 12000 includes a drive system control unit 12010, a body system control unit 12020, a vehicle external information detection unit 12030, an in-vehicle information detection unit 12040, and an integrated control unit 12050. Furthermore, as a functional configuration of the integrated control unit 12050, a microcomputer 12051, a voice/image output unit 12052, and an in-vehicle network interface I/F (interface) 12053 are illustrated.

The drive system control unit 12010 controls the operation of devices related to a drive system of a vehicle according to various programs. For example, the drive system control unit 12010 functions as a control device such as a driving force generation device for generating a driving force of a vehicle, the driving force generation device being an internal combustion engine or a driving motor, a driving force transmission mechanism for transmitting the driving force to wheels, a steering mechanism for adjusting a steering angle of the vehicle, and a braking device for generating a braking force of the vehicle.

The body system control unit 12020 controls operations of various devices mounted on the vehicle body according to various programs. For example, the body system control unit 12020 functions as a control device of a keyless entry system, a smart key system, a power window device, or various lamps such as a head lamp, a back lamp, a brake lamp, a blinker, or a fog lamp. In this case, radio waves transmitted from a portable device that substitutes for a key, or signals of various switches can be input to the body system control unit 12020. The body system control unit 12020 receives input of these radio waves or signals, and controls a door lock device, the power window device, the lamp, and the like of the vehicle.

The vehicle external information detection unit 12030 detects information outside the vehicle on which the vehicle control system 12000 is mounted. For example, an imaging unit 12031 is connected to the vehicle external information detection unit 12030. The vehicle external information detection unit 12030 causes the imaging unit 12031 to capture an image of the outside of the vehicle, and receives the captured image. The vehicle external information detection unit 12030 may perform object detection processing or distance detection processing of a person, a vehicle, an obstacle, a sign, a character on a road surface, or the like on the basis of the received image.

The imaging unit 12031 is an optical sensor that receives light and outputs an electric signal corresponding to the amount of received light. The imaging unit 12031 can output the electric signal as an image or can output the electric signal as distance measurement information. Furthermore, the light received by the imaging unit 12031 may be visible light or invisible light such as an infrared ray.

The in-vehicle information detection unit 12040 detects in-vehicle information. For example, a driver state detection unit 12041 that detects a state of a driver is connected to the in-vehicle information detection unit 12040. The driver state detection unit 12041 includes, for example, a camera that images the driver, and the in-vehicle information detection unit 12040 may calculate a fatigue degree or a concentration degree of the driver or may determine whether or not the driver is dozing, on the basis of the detection information input from the driver state detection unit 12041.

The microcomputer 12051 can calculate a control target value of the driving force generation device, the steering mechanism, or the braking device on the basis of the information inside and outside the vehicle, the information being acquired by the vehicle external information detection unit 12030 or the in-vehicle information detection unit 12040, and output a control command to the drive system control unit 12010. For example, the microcomputer 12051 can perform cooperative control for the purpose of implementing functions of an advanced driver assistance system (ADAS) including collision avoidance or impact mitigation of the vehicle, follow-up traveling based on an inter-vehicle distance, vehicle speed maintenance traveling, vehicle collision warning, and vehicle lane deviation warning.

Furthermore, the microcomputer 12051 performs cooperative control for the purpose of automatic driving or the like in which the vehicle autonomously travels without depending on the operation of the driver by controlling the driving force generation device, the steering mechanism, the braking device, or the like on the basis of information around the vehicle, the information being acquired by the vehicle external information detection unit 12030 or the in-vehicle information detection unit 12040.

Furthermore, the microcomputer 12051 can output a control command to the body system control unit 12020 on the basis of the information outside the vehicle, which is acquired by the vehicle external information detection unit 12030. For example, the microcomputer 12051 can perform cooperative control for the purpose of preventing glare, such as switching from a high beam to a low beam, by controlling the head lamp according to the position of a preceding vehicle or an oncoming vehicle, which is detected by the vehicle external information detection unit 12030.

The voice/image output unit 12052 transmits an output signal of at least one of a voice and an image to an output device capable of visually or audibly notifying an occupant of the vehicle or the outside of the vehicle of information. In the example of FIG. 72, an audio speaker 12061, a display unit 12062, and an instrument panel 12063 are illustrated as the output device. The display unit 12062 may include, for example, at least one of an on-board display and a head-up display.

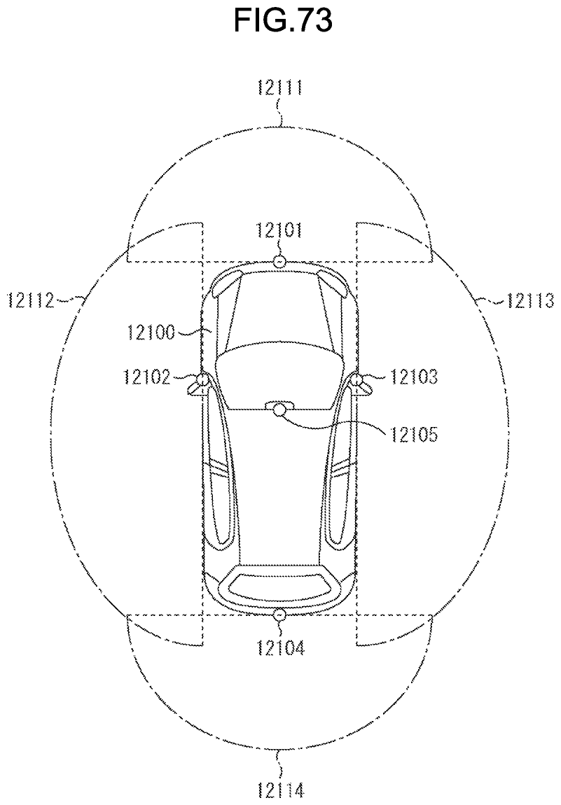

FIG. 73 is a view illustrating an example of an installation position of the imaging unit 12031.

In FIG. 73, a vehicle 12100 includes imaging units 12101, 12102, 12103, 12104, and 12105 as the imaging unit 12031.

The imaging units 12101, 12102, 12103, 12104, and 12105 are provided, for example, at positions such as a front nose, a side mirror, a rear bumper, a back door, and an upper portion of a windshield in a vehicle interior of the vehicle 12100. The imaging unit 12101 provided at the front nose and the imaging unit 12105 provided at the upper portion of the windshield in the vehicle interior mainly acquire images in front of the vehicle 12100. The imaging units 12102 and 12103 provided at the side mirrors mainly acquire images of the sides of the vehicle 12100. The imaging unit 12104 provided at the rear bumper or the back door mainly acquires image of the rear side of the vehicle 12100. The images in front of the vehicle, which are acquired by the imaging units 12101 and 12105, are mainly used for detecting a preceding vehicle, or a pedestrian, an obstacle, a traffic light, a traffic sign, a lane, or the like.

Note that, FIG. 73 illustrates an example of imaging ranges of the imaging units 12101 to 12104. An imaging range 12111 indicates an imaging range of the imaging unit 12101 provided at the front nose, imaging ranges 12112 and 12113 indicate imaging ranges of the imaging units 12102 and 12103 respectively provided at the side mirrors, and an imaging range 12114 indicates an imaging range of the imaging unit 12104 provided at the rear bumper or the back door. For example, by superimposing image data captured by the imaging units 12101 to 12104, an overhead view image of the vehicle 12100 as viewed from above is obtained.

At least one of the imaging units 12101 to 12104 may have a function of acquiring distance information. For example, at least one of the imaging units 12101 to 12104 may be a stereo camera including a plurality of imaging elements, and may be an imaging element having pixels for phase difference detection.

For example, the microcomputer 12051 extracts, as a preceding vehicle, a three-dimensional object traveling at a predetermined speed (for example, 0 km/h or more) in substantially the same direction as the vehicle 12100, in particular, the closest three-dimensional object on a traveling road of the vehicle 12100 by obtaining a distance to each three-dimensional object in the imaging ranges 12111 to 12114 and a temporal change of the distance (relative speed with respect to the vehicle 12100) on the basis of the distance information obtained from the imaging units 12101 to 12104. Moreover, the microcomputer 12051 can set an inter-vehicle distance to be secured in advance with respect to the preceding vehicle, and can perform automatic brake control (follow-up stop control is also included), automatic acceleration control (follow-up start control is also included), and the like. As described above, it is possible to perform cooperative control for the purpose of automatic driving or the like in which the vehicle autonomously travels without depending on the operation of the driver.

For example, on the basis of the distance information obtained from the imaging units 12101 to 12104, the microcomputer 12051 can classify three-dimensional object data regarding three-dimensional objects into a two-wheeled vehicle, an ordinary vehicle, a large vehicle, a pedestrian, and other three-dimensional objects such as utility poles, extract the three-dimensional object data, and use the three-dimensional object data for automatic avoidance of obstacles. For example, the microcomputer 12051 identifies obstacles around the vehicle 12100 as obstacles that can be visually recognized by the driver of the vehicle 12100 and obstacles that are difficult to visually recognize. Then, the microcomputer 12051 determines a collision risk indicating a risk of collision with each of the obstacles, and can perform driving assistance for collision avoidance by outputting an alarm to the driver via the audio speaker 12061 or the display unit 12062 or performing forced deceleration or avoidance steering via the drive system control unit 12010 when the collision risk is a set value or more and there is a possibility of collision.

At least one of the imaging units 12101 to 12104 may be an infrared camera that detects infrared rays. For example, the microcomputer 12051 can recognize a pedestrian by determining whether or not the pedestrian is present in the images captured by the imaging units 12101 to 12104. Such pedestrian recognition is performed by, for example, a procedure of extracting feature points in the images captured by the imaging units 12101 to 12104 as an infrared camera and a procedure of performing pattern matching processing on a series of feature points indicating the outline of an object to determine whether or not the object is the pedestrian. When the microcomputer 12051 determines that a pedestrian is present in the images captured by the imaging units 12101 to 12104 and recognizes the pedestrian, the voice/image output unit 12052 causes the display unit 12062 to superimpose and display a square contour line on the recognized pedestrian for emphasis. Furthermore, the voice/image output unit 12052 may cause the display unit 12062 to display an icon or the like indicating the pedestrian at a desired position.

An example of the moving body control system to which the technology according to the present disclosure can be applied has been described above. The technology according to the present disclosure can be applied to the imaging unit 12031 among the configurations described above. Specifically, the imaging device 1 according to the embodiment and the modified examples thereof can be applied to the imaging unit 12031. Since a high-definition captured image with little noise can be obtained by applying the technology according to the present disclosure to the imaging unit 12031, it is possible to perform high-accuracy control using the captured image in the moving body control system.

[6.2.2. Endoscopic Surgery System]

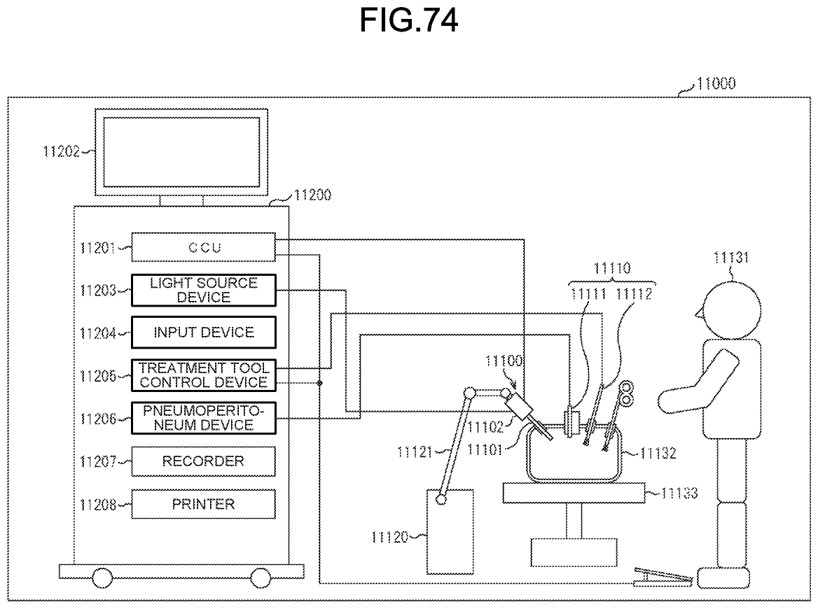

FIG. 74 is a diagram illustrating an example of a schematic configuration of an endoscopic surgery system to which the technology (present technology) according to the present disclosure can be applied.

FIG. 74 illustrates a state in which an operator (medical doctor) 11131 is performing surgery on a patient 11132 on a patient bed 11133 by using an endoscopic surgery system 11000. As illustrated in FIG. 74, the endoscopic surgery system 11000 includes an endoscope 11100, other surgical tools 11110 such as a pneumoperitoneum tube 11111 and an energy treatment tool 11112, a support arm device 11120 that supports the endoscope 11100, and a cart 11200 on which various devices for endoscopic surgery are mounted.

The endoscope 11100 includes a lens barrel 11101 of which a region having a predetermined length from a distal end is inserted into a body cavity of a patient 11132, and a camera head 11102 connected to a proximal end of the lens barrel 11101. In the illustrated example, the endoscope 11100 configured as a so-called rigid scope having the rigid lens barrel 11101 is illustrated, but the endoscope 11100 may be configured as a so-called flexible scope having a flexible lens barrel.

An opening portion into which an objective lens is fitted is provided at the distal end of the lens barrel 11101. A light source device 11203 is connected to the endoscope 11100, and light generated by the light source device 11203 is guided to the distal end of the lens barrel by a light guide extending inside the lens barrel 11101, and is emitted toward an observation target in the body cavity of the patient 11132 via the objective lens. Note that, the endoscope 11100 may be a forward-viewing endoscope, an oblique-viewing endoscope, or a side-viewing endoscope.

An optical system and an imaging element are provided inside the camera head 11102, and reflected light (observation light) from the observation target is condensed on the imaging element by the optical system. The observation light is photoelectrically converted by the imaging element, and an electric signal corresponding to the observation light, that is, an image signal corresponding to the observation image is generated. The image signal is transmitted to a camera control unit (CCU) 11201 as RAW data.

The CCU 11201 includes a central processing unit (CPU), a graphics processing unit (GPU), and the like, and integrally controls an operation of the endoscope 11100 and a display device 11202. Moreover, the CCU 11201 receives an image signal from the camera head 11102, and performs, for example, various image processing for displaying an image based on the image signal, such as development processing (demosaic processing), on the image signal.

The display device 11202 displays an image based on the image signal subjected to the image processing by the CCU 11201 under the control of the CCU 11201.

The light source device 11203 includes, for example, a light source such as a light emitting diode (LED), and supplies irradiation light for imaging a surgical site or the like to the endoscope 11100.

An input device 11204 is an input interface for the endoscopic surgery system 11000. The user can input various information and instructions to the endoscopic surgery system 11000 via the input device 11204. For example, the user inputs an instruction or the like to change imaging conditions (type, magnification, focal distance, and the like of irradiation light) by using the endoscope 11100.

A treatment tool control device 11205 controls driving of the energy treatment tool 11112 for cauterization and incision of tissue, sealing of a blood vessel, or the like. A pneumoperitoneum device 11206 feeds gas into the body cavity of the patient 11132 via the pneumoperitoneum tube 11111 in order to inflate the body cavity of the patient 11132 for the purpose of securing a visual field of the endoscope 11100 and securing a working space of the operator. A recorder 11207 is a device capable of recording various information regarding the surgery. A printer 11208 is a device capable of printing various information regarding the surgery in various formats such as text, image, or graph.

Note that, the light source device 11203 that supplies the irradiation light at the time of imaging the surgical site to the endoscope 11100 can include, for example, an LED, a laser light source, or a white light source including a combination thereof. In a case where the white light source is configured by a combination of RGB laser light sources, since output intensity and an output timing of each color (each wavelength) can be controlled with high accuracy, adjustment of white balance of the captured image can be performed in the light source device 11203. Furthermore, in this case, by irradiating the observation target with the laser light from each of the RGB laser light sources in a time-division manner and controlling the driving of the imaging element of the camera head 11102 in synchronization with the irradiation timing, it is also possible to capture an image corresponding to each of RGB in a time-division manner. According to the method, a color image can be obtained without providing a color filter to the imaging element.

Furthermore, the driving of the light source device 11203 may be controlled so as to change the intensity of light to be output at every predetermined time. By controlling the driving of the imaging element of the camera head 11102 in synchronization with the timing of changing of the intensity of the light to acquire images in a time-division manner and synthesizing the images, it is possible to generate an image of a high dynamic range without so-called blocked up shadows and blown out highlights.

Furthermore, the light source device 11203 may be configured to be capable of supplying light in a predetermined wavelength band corresponding to special light observation. In the special light observation, for example, so-called narrow band light observation (narrow band imaging) is performed in which a predetermined tissue such as a blood vessel in a mucous membrane surface layer is imaged with high contrast by radiating light in a narrower band than that of the irradiation light (that is, white light) at the time of normal observation by using wavelength dependency of light absorption in a living tissue. Alternatively, in the special light observation, fluorescence observation for obtaining an image by using fluorescence generated by radiating excitation light may be performed. In the fluorescence observation, it is possible to irradiate the living tissue with excitation light to observe the fluorescence from the living tissue (autofluorescence observation), or to locally inject a reagent such as indocyanine green (ICG) into the living tissue and irradiate the living tissue with the excitation light corresponding to a fluorescence wavelength of the reagent to obtain a fluorescent image. The light source device 11203 can be configured to be capable of supplying narrow band light and/or excitation light corresponding to such special light observation.

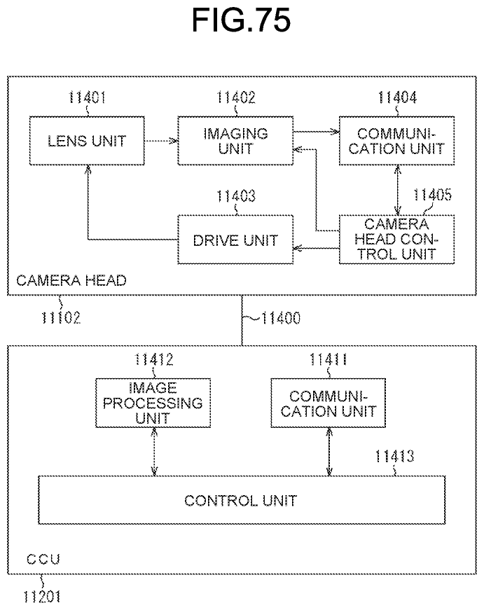

FIG. 75 is a block diagram illustrating an example of functional configurations of the camera head 11102 and the CCU 11201, which are illustrated in FIG. 74.

The camera head 11102 includes a lens unit 11401, an imaging unit 11402, a drive unit 11403, a communication unit 11404, and a camera head control unit 11405. The CCU 11201 includes a communication unit 11411, an image processing unit 11412, and a control unit 11413. The camera head 11102 and the CCU 11201 are communicably connected to each other by a transmission cable 11400.

The lens unit 11401 is an optical system provided at a connection portion with the lens barrel 11101. Observation light taken in from the distal end of the lens barrel 11101 is guided to the camera head 11102 and enters the lens unit 11401. The lens unit 11401 is configured by combining a plurality of lenses including a zoom lens and a focus lens.

The imaging unit 11402 includes an imaging element. The number of imaging elements constituting the imaging unit 11402 may be one (so-called single-plate type) or plural (so-called multi-plate type). In a case where the imaging unit 11402 is configured as the multi-plate type, for example, the image signal corresponding to each of RGB may be generated by each of the imaging elements, and a color image may be obtained by combining the image signals. Alternatively, the imaging unit 11402 may include a pair of imaging elements for acquiring right-eye and left-eye image signals corresponding to three-dimensional (3D) display. By performing the 3D display, an operator 11131 can more accurately grasp the depth of the living tissue in the surgical site. Note that, in a case where the imaging unit 11402 is configured as the multi-plate type, a plurality of lens units 11401 can be provided corresponding to each of the imaging elements.

Furthermore, the imaging unit 11402 is not necessarily provided in the camera head 11102. For example, the imaging unit 11402 may be provided immediately behind the objective lens inside the lens barrel 11101.

The drive unit 11403 includes an actuator, and moves the zoom lens and the focus lens of the lens unit 11401 by a predetermined distance along an optical axis under the control of the camera head control unit 11405. Accordingly, the magnification and focus of the image captured by the imaging unit 11402 can be appropriately adjusted.

The communication unit 11404 includes a communication device for transmitting and receiving various information to and from the CCU 11201. The communication unit 11404 transmits the image signal obtained from the imaging unit 11402 as RAW data to the CCU 11201 via the transmission cable 11400.

Furthermore, the communication unit 11404 receives a control signal for controlling driving of the camera head 11102 from the CCU 11201, and supplies the control signal to the camera head control unit 11405. The control signal includes, for example, information regarding imaging conditions such as information for specifying a frame rate of a captured image, information for specifying an exposure value at the time of imaging, and/or information for specifying a magnification and a focus of a captured image.

Note that, the imaging conditions such as the frame rate, the exposure value, the magnification, and the focus may be appropriately specified by the user, or may be automatically set by the control unit 11413 of the CCU 11201 on the basis of the acquired image signal. In the latter case, a so-called auto exposure (AE) function, an auto focus (AF) function, and an auto white balance (AWB) function are installed in the endoscope 11100.

The camera head control unit 11405 controls the driving of the camera head 11102 on the basis of the control signal received from the CCU 11201 via the communication unit 11404.

The communication unit 11411 includes a communication device for transmitting and receiving various information to and from the camera head 11102. The communication unit 11411 receives the image signal transmitted from the camera head 11102 via the transmission cable 11400.

Furthermore, the communication unit 11411 transmits the control signal for controlling the driving of the camera head 11102 to the camera head 11102. The image signal and the control signal can be transmitted by electric communication, optical communication, or the like.

The image processing unit 11412 performs various image processing on the image signal that is RAW data transmitted from the camera head 11102.

The control unit 11413 performs various control related to imaging of the surgical site or the like by using the endoscope 11100 and display of the captured image obtained by imaging the surgical site or the like. For example, the control unit 11413 generates a control signal for controlling the driving of the camera head 11102.

Furthermore, the control unit 11413 causes the display device 11202 to display the captured image of the surgical site or the like on the basis of the image signal subjected to the image processing by the image processing unit 11412. At this time, the control unit 11413 may recognize various objects in the captured image by using various image recognition technology. For example, the control unit 11413 can recognize a surgical tool such as a forceps, a specific living body part, bleeding, a mist at the time of using the energy treatment tool 11112, and the like by detecting a shape, color, and the like of an edge of the object included in the captured image. When displaying the captured image in the display device 11202, the control unit 11413 may superimpose and display various surgery support information on the image of the surgical site by using the recognition result. Since the surgery support information is superimposed and displayed, and presented to the operator 11131, the burden of the operator 11131 can be reduced and the operator 11131 can reliably perform the surgery.

The transmission cable 11400 connecting the camera head 11102 and the CCU 11201 is an electric signal cable corresponding to electric signal communication, an optical fiber corresponding to optical communication, or a composite cable thereof.

Here, in the illustrated example, communication is performed by wire using the transmission cable 11400, but communication between the camera head 11102 and the CCU 11201 may be performed wirelessly.

An example of the endoscopic surgery system to which the technology according to the present disclosure can be applied has been described above. The technology according to the present disclosure can be suitably applied to the imaging unit 11402 provided at the camera head 11102 of the endoscope 11100 among the above-described configurations. Since the imaging unit 11402 can be downsized or made to have high definition by applying the technology according to the present disclosure to the imaging unit 11402, the endoscope 11100 having a small size or high definition can be provided.

The present disclosure has been described with reference to the embodiments, the modified examples, application examples, and applied examples thereof, but the present disclosure is not limited to the embodiments and the like, and various modifications can be made. Note that, the effects described in the present specification are merely examples. The effects of the present disclosure are not limited to the effects described in the present specification. The present disclosure may have effects other than those described in the present application.

Furthermore, for example, the present disclosure can have the following configurations.

(1)

A semiconductor device comprising:

a plurality of substrates stacked on each other;

a semiconductor element formed in at least one of a plurality of the substrates; and

a protection element that is formed to have PN junction in at least one of a plurality of the substrates, and protects the semiconductor element.

(2)

The semiconductor device according to (1), wherein the protection element is disposed in at least one of a plurality of the substrates in accordance with a formation area of the semiconductor element formed in a plurality of the substrates or a number of elements.

(3)

The semiconductor device according to (1) or (2), wherein the protection element is a bipolar transistor type protection element or a thyristor type protection element.

(4)

The semiconductor device according to any one of (1) to (3), wherein the protection element has a PNPN junction structure or an NPNP junction structure in a horizontal direction of the substrate.

(5)

The semiconductor device according to any one of (1) to (4), wherein the protection element includes a plurality of first conductive type wells connected to each other by wiring.

(6)

The semiconductor device according to any one of (1) to (5), wherein the protection element has a double well structure in which a second conductive type well is formed on or under a first conductive type well.

(7)

The semiconductor device according to any one of (1) to (5), wherein the protection element has a triple well structure of PNP junction or NPN junction.

(8)

The semiconductor device according to any one of (1) to (7), wherein

the semiconductor element is an element having a gate electrode, and

the protection element is an element for discharging electric charges generated in the gate electrode to the substrate in plasma processing.

(9)

The semiconductor device according to any one of (1) to (8), wherein the protection element is formed in substrate different from the substrate in which the semiconductor element to be protected is formed.

(10)

An imaging device comprising:

a first substrate in which a photoelectric conversion element and a transfer transistor transferring an electric signal output by the photoelectric conversion element are formed;

a second substrate that is stacked on the first substrate and in which a pixel transistor outputting the electric signal is formed; and

a protection element that is formed to have PN junction in at least one of the first substrate and the second substrate and protects the transfer transistor or the pixel transistor.

(11)

The imaging device according to (10), wherein the protection element is formed in the second substrate and on a region in which a dummy pixel of the first substrate is formed.

### REFERENCE SIGNS LIST

1, 1A IMAGING DEVICE
100, 100A FIRST SUBSTRATE
200, 200A SECOND SUBSTRATE
300, 300A THIRD SUBSTRATE
541A, 541B, 541C, 541D, 5410 PIXEL
TR TRANSFER TRANSISTOR
RST RESET TRANSISTOR
AMP AMPLIFICATION TRANSISTOR
SEL SELECTION TRANSISTOR
FDG FD TRANSFER TRANSISTOR
FD FLOATING DIFFUSION

1. A semiconductor device comprising:
a plurality of substrates stacked on each other;
a semiconductor element formed in at least one of a plurality of the substrates; and
a protection element that is formed to have PN junction in at least one of a plurality of the substrates, and protects the semiconductor element.

2. The semiconductor device according to claim 1, wherein the protection element is disposed in at least one of a plurality of the substrates in accordance with a formation area of the semiconductor element formed in a plurality of the substrates or a number of elements.

3. The semiconductor device according to claim 2, wherein the protection element is a bipolar transistor type protection element or a thyristor type protection element.

4. The semiconductor device according to claim 3, wherein the protection element has a PNPN junction structure or an NPNP junction structure in a horizontal direction of the substrate.

5. The semiconductor device according to claim 4, wherein the protection element includes a plurality of first conductive type wells connected to each other by wiring.

6. The semiconductor device according to claim 4, wherein the protection element has a double well structure in which a second conductive type well is formed on or under a first conductive type well.

7. The semiconductor device according to claim 4, wherein the protection element has a triple well structure of PNP junction or NPN junction.

8. The semiconductor device according to claim 4, wherein
the semiconductor element is an element having a gate electrode, and
the protection element is an element for discharging electric charges generated in the gate electrode to the substrate in plasma processing.

9. The semiconductor device according to claim 8, wherein the protection element is formed in substrate different from the substrate in which the semiconductor element to be protected is formed.

10. An imaging device comprising:
a first substrate in which a photoelectric conversion element and a transfer transistor transferring an electric signal output by the photoelectric conversion element are formed;
a second substrate that is stacked on the first substrate and in which a pixel transistor outputting the electric signal is formed; and
a protection element that is formed to have PN junction in at least one of the first substrate and the second substrate and protects the transfer transistor or the pixel transistor.

11. The imaging device according to claim 10, wherein the protection element is formed in the second substrate and on a region in which a dummy pixel of the first substrate is formed.
